(19) United States
(12) Patent Application Publication
(10) Pub. No.: US 2026/0120628 A1
(43) Pub. Date: Apr. 30, 2026

(54) DISPLAY DEVICE

(71) Applicant: LG Display Co., Ltd., Seoul (KR)

(72) Inventors: Taeyun KIM, Paju-si (KR); DeukSu LEE, Paju-si (KR)

(73) Assignee: LG Display Co., Ltd., Seoul (KR)

(21) Appl. No.: 19/315,034

(22) Filed: Aug. 29, 2025

(30) Foreign Application Priority Data
Oct. 31, 2024 (KR) 10-2024-0152882

(51) Int. Cl. G09G 3/32; G06F 3/041; G06F 3/044; G09G 3/20

(52) U.S. Cl. CPC G09G 3/32; G06F 3/04164; G06F 3/0446; G09G 3/2096; G09G 2300/0426; G09G 2320/0233

(57) ABSTRACT

A display device can include a substrate, a plurality of light emitting devices disposed on the substrate and positioned in a display area, a plurality of column lines electrically connected to a first electrode of each of the plurality of light emitting devices, a plurality of row lines electrically connected to a second electrode of each of the plurality of light emitting devices, a touch sensor disposed in the same metal layer as the plurality of row lines, and an overcoat layer disposed on the plurality of light emitting devices, the plurality of row lines, and the touch sensor. The display device can further include a plurality of drivers disposed on the substrate and configured to drive the plurality of light emitting devices and drive or sense the touch sensor.

### CROSS-REFERENCE TO RELATED APPLICATION

This application claims priority to Korean Patent Application No. 10-2024-0152882, filed in the Republic of Korea on Oct. 31, 2024, which is hereby expressly incorporated by reference for all purposes as if fully set forth herein.

### BACKGROUND

### Technical Field

Embodiments of the present disclosure relate to a display device.

### Discussion of the Related Art

A display device is applied to various electronic devices such as televisions, mobile phones, laptops, and tablets. A display device can include a self-luminous organic light emitting display (OLED), and a liquid crystal display (LCD) with a separate light source.

Recently, a display device with light emitting diodes (LED) are attracting attention as a next-generation display device. Since the light emitting diodes are made of inorganic materials rather than organic materials, a display device with the light emitting diode has a characteristics of a faster lighting speed, superior light emitting efficiency, and can display high-luminance images compared to a liquid crystal display or an organic light emitting display.

### SUMMARY OF THE DISCLOSURE

Embodiments of the present disclosure can provide a display device having a touch sensor built into a display panel including a light emitting device in an in-cell type.

Embodiments of the present disclosure can provide a display device in which a driver for driving a light emitting device and driving or sensing a touch sensor is disposed on a substrate.

The objects of the embodiments of the present disclosure are not limited to the objects described in this disclosure, and other objects not mentioned will be clearly understood by those skilled in the art from the description below.

A display device according to embodiments of the present disclosure can include a substrate, a plurality of light emitting devices disposed on the substrate and positioned in a display area, a plurality of column lines electrically connected to a first electrode of each of the plurality of light emitting devices, a plurality of row lines electrically connected to a second electrode of each of the plurality of light emitting devices, a touch sensor disposed in the same metal layer as the plurality of row lines, an overcoat layer disposed on the plurality of light emitting devices, the plurality of row lines, and the touch sensor, and a plurality of drivers disposed on the substrate, and configured to drive the plurality of light emitting devices and drive or sense the touch sensor.

A display device according to embodiments of the present disclosure can include a plurality of unit driving areas included in a display area, a plurality of light emitting devices disposed in each of the plurality of unit driving areas, a plurality of column lines arranged in each of the plurality of unit driving areas and electrically connected to a first electrode of each of the plurality of light emitting devices, a plurality of row lines arranged in each of the plurality of unit driving areas and electrically connected to a second electrode of each of the plurality of light emitting devices, and a touch sensor including the same metal as the plurality of row lines.

According to embodiments of the present disclosure, it is possible to provide a display device having a touch sensor built into a display panel including a light emitting device in an in-cell type.

According to embodiments of the present disclosure, it is possible to provide a display device in which a driver for driving a light emitting device and driving or sensing a touch sensor is disposed on a substrate.

According to embodiments of the present disclosure, it is possible to provide a display device having a wiring structure arranged in a matrix form to effectively drive a plurality of light emitting devices.

According to embodiments of the present disclosure, it is possible to provide a display device capable of effectively driving a plurality of light emitting devices by using a plurality of column lines connecting first electrodes of two or more light emitting devices arranged in a column direction and a plurality of row lines connecting second electrodes of two or more light emitting devices arranged in a row direction.

According to embodiments of the present disclosure, it is possible to provide a display device capable of reducing the number of driving components (e.g., drivers) connected to the outside of a display panel, thereby reducing the number of assembly processes in the manufacturing process to enable the process optimization.

The effects of the embodiments of the present disclosure are not limited to the effects mentioned above, and other effects not mentioned will be clearly understood by those skilled in the art from the description of the claims.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 illustrates a display device according to embodiments of the present disclosure.

FIG. 2 is a plan view of a display device according to embodiments of the present disclosure.

FIG. 3 is a plan view of a display panel according to embodiments of the present disclosure.

FIG. 4 is a plan view of a unit driving area of a display panel according to embodiments of the present disclosure.

FIG. 5 illustrates a sub-pixel of a display panel according to embodiments of the present disclosure.

FIG. 6 is an equivalent circuit diagram of a unit driving area of a display panel according to embodiments of the present disclosure.

FIG. 7 illustrates a driving timing diagram for n row lines and one column line included in a first sub-driving area of a display panel according to embodiments of the present disclosure.

FIG. 8 and FIG. 9 illustrate circuits for driving n light emitting devices connected to one column line included in a first sub-driving area of a display panel according to embodiments of the present disclosure.

FIG. 10 is a plan view of a display panel according to embodiments of the present disclosure.

FIG. 11 illustrates a unit driving area of a display panel according to embodiments of the present disclosure.

FIG. 12 and FIG. 13 are plan views of a portion of a display panel according to embodiments of the present disclosure.

FIG. 14 is a cross-sectional view of a display panel according to embodiments of the present disclosure.

FIG. 15 is a detailed cross-sectional view of a display panel according to embodiments of the present disclosure, taken along the A-B cutting line of FIG. 10.

FIG. 16 is an enlarged cross-sectional view of a first sub-pixel of a display panel according to embodiments of the present disclosure.

FIG. 17 briefly illustrates a touch sensing structure of a display device according to embodiments of the present disclosure.

FIG. 18 illustrates a touch sensing system of a display device according to embodiments of the present disclosure.

FIG. 19 illustrates a touch driving structure of a display panel according to embodiments of the present disclosure.

FIG. 20 is a plan view of a display panel according to embodiments of the present disclosure.

FIG. 21 is a cross-sectional view of a display panel according to embodiments of the present disclosure.

FIG. 22 is a block diagram of a driver according to embodiments of the present disclosure.

FIG. 23 and FIG. 24 are plan views illustrating a touch sensor structure of a display panel according to embodiments of the present disclosure.

FIG. 25 is a cross-sectional view illustrating a touch sensor structure of a display panel according to embodiments of the present disclosure.

FIG. 26 illustrates a connection structure of drivers in a display panel according to embodiments of the present disclosure.

FIG. 27 to FIG. 29 are driving timing diagrams of a display device according to embodiments of the present disclosure.

FIG. 30 and FIG. 31 illustrate states of sub-pixels according to operation modes of a display device according to embodiments of the present disclosure.

### DETAILED DESCRIPTION OF THE EMBODIMENTS

The advantages and features of the present disclosure and the method for achieving them will become clear with reference to the embodiments described in detail below together with the accompanying drawings. However, the present disclosure is not limited to the embodiments disclosed below, but can be implemented in various different forms, and these embodiments are provided only to make the disclosure of the present disclosure complete and to fully inform a person having ordinary skill in the art to which the present disclosure belongs of the scope of the invention.

The shapes, sizes, ratios, angles, numbers, etc. disclosed in the drawings for explaining the embodiments of this disclosure are example, and therefore this disclosure is not limited to the matters illustrated. In assigning reference numerals to components of each drawing, the same components can be assigned the same numerals even when they are shown on different drawings. When determined to make the subject matter of the disclosure unclear, the detailed of the known art or functions can be skipped. As used herein, when a component “includes,” “has,” or “is composed of” another component, other components can be added unless “only” is used. When a component is expressed in the singular, it includes cases where the plural is included unless otherwise explicitly stated.

In interpreting a component, even if there is no separate explicit description of the error range, it is interpreted as including the error range.

In the case of a description of a positional relationship, for example, if the positional relationship between two parts is described as “on,” “over,” “below,” “next to,” or “adjacent,” one or more other parts can be located between the two parts unless “directly,” “directly,” or “nearly,” are used.

Although the terms first, second, etc. are used to describe various elements, these components are not limited by these terms. These terms are only used to distinguish one component from another. Therefore, the first element mentioned below can also be the second element within the technical scope of this disclosure.

In describing the components of this disclosure, terms such as first, second, A, B, (a), or (b) can be used. These terms are only intended to distinguish the components from other components, and the nature, order, sequence, or number of the components are not limited by the terms.

If a component is described as being “connected,” “coupled,” “linked,” or “attached,” to another component, it should be understood that the component can be directly connected, coupled, linked, or attached to the other component, but that other components can be interposed between each component that can be indirectly connected, coupled, linked, or attached without any specific explicit description.

When a component or layer is described as being “contacted,” or “overlapping,” to another component or layer, it should be understood that the component or layer can directly contact or overlap the other component or layer, but that other components can be interposed between each component that can be indirectly contacted or overlapped without any specific explicit description.

Further, the phrase “at least one” should be understood to include any combination of one or more of the associated components. For example, “at least one of the first, second, and third components” can be interpreted to include not only the first, second, or third components, but also any combination of two or more of the first, second, and third components.

Further, terms such as “first direction,” “second direction,” “third direction,” “X-axis direction,” “Y-axis direction,” and “Z-axis direction” should not be interpreted as merely geometric relationships in which the relationship between them is perpendicular to each other, but can mean a wider directionality within the range in which the configuration of the present disclosure can function functionally. In addition, the term “can” fully encompasses all the meanings and coverages of the term “may” and vice versa.

Each feature of the various embodiments of the present disclosure can be partially or wholly combined or combined with each other, and various technical connections and operations are possible, and each embodiment can be implemented independently of each other or can be implemented together in a related relationship.

Hereinafter, various embodiments of the disclosure are described in detail with reference to the accompanying drawings. All the components of each display device/apparatus according to all embodiments of the present disclosure are operatively coupled and configured.

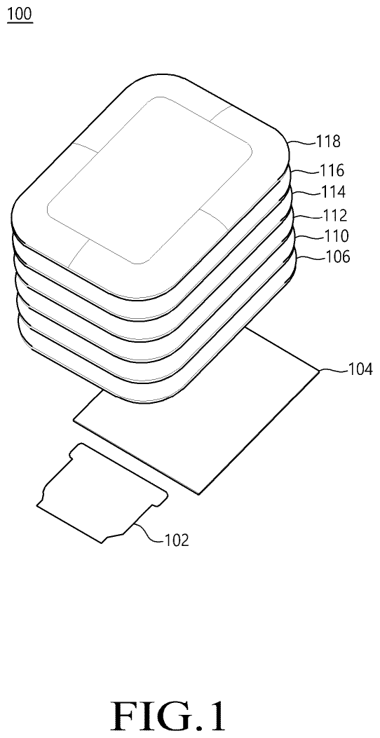

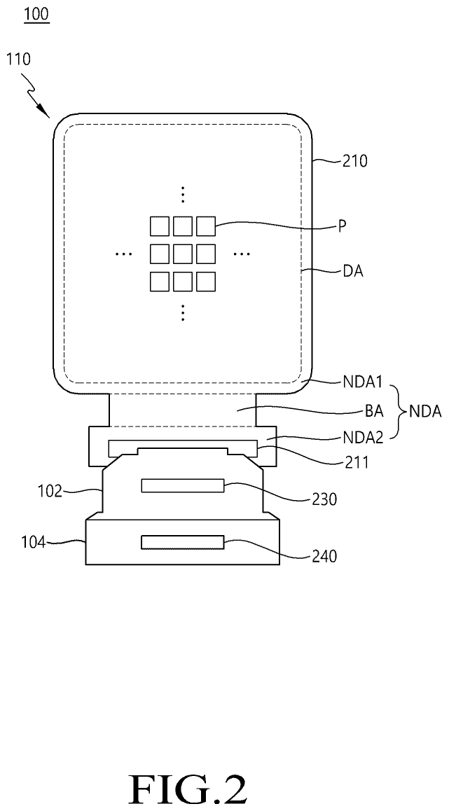

FIG. 1 illustrates a display device 100 according to embodiments of the present disclosure, and FIG. 2 is a plan view of the display device 100 according to embodiments of the present disclosure.

Referring to FIGS. 1 and 2, the display device 100 according to the embodiments of the present disclosure can include a display panel 110, a cover member 118 disposed on the display panel 110, a flexible printed circuit 102 connected to the display panel 110, and a printed circuit board 104 connected to the flexible printed circuit 102.

The display device 100 according to the embodiments of the present disclosure can further include a support substrate 106 disposed under the display panel 110 and supporting the lower portion of the display panel 110, a polarizing layer 114 disposed on the display panel 110, a first adhesive layer 112 disposed between the display panel 110 and the polarizing layer 114, and a second adhesive layer 116 disposed between the polarizing layer 114 and the cover member 118.

The display panel 110 can include a substrate 210. The substrate 210 can be a member on which various components such as a plurality of metal layers and a plurality of insulating material layers are formed. The substrate 210 can be made of an insulating material. For example, the substrate 210 can be made of glass or resin. In addition, the substrate 210 can be made of a flexible material. For example, the substrate 210 can be made of a flexible plastic material such as polyimide (PI). However, the embodiments of the present disclosure are not limited thereto.

The display panel 110 can display information, images, and/or images provided to a user. For example, the display panel 110 can include a display area DA and a non-display area NDA. For example, the substrate 210 can include a display area DA and a non-display area NDA. The display area DA and the non-display area NDA are not limited to the substrate 210, but can be described throughout the entire display device 100.

The display area DA can be an area where an image is displayed. The display area DA can include a plurality of pixels P. Each of the plurality of pixels P can be composed of a plurality of sub-pixels. At least one light emitting device can be arranged in each of the plurality of sub-pixels. The light emitting device can be configured differently depending on the type of the display device 100. For example, if the display device 100 is an inorganic light emitting display device, the light emitting device can be an inorganic-based light emitting device, such as a light emitting diode (LED), a micro LED, or a mini LED.

The non-display area NDA can be an area where an image is not displayed. In the non-display area NDA, various wirings, and circuits for driving a plurality of pixels P of the display area DA can be arranged. For example, various driving circuits and various wirings can be arranged in the non-display area NDA, and a pad section 211 to which an integrated circuit and a printed circuit are connected can be arranged.

For example, the driving circuit can include a data driving circuit and/or a gate driving circuit. Wires or lines supplied with a control signal for controlling the driving circuit can be arranged on the substrate 210. For example, the control signal can include various timing signals including a clock signal, an input data enable signal, and synchronization signals. The control signal can be supplied to the substrate 210 from the outside of the substrate 210 through the pad section 211. For example, circuit components such as a flexible printed circuit 102 and a printed circuit board 104 can be connected to the pad section 211.

According to the present embodiments, the non-display area NDA can include a first non-display area NDA1, a bending area BA, and a second non-display area NDA2. For example, the first non-display area NDA1 can be an area surrounding at least a portion of the display area DA. The bending area BA can be an area extending from at least one of a plurality of sides of the first non-display area NDA1 and can be a bendable area. The second non-display area NDA2 can be an area extending from the bending area BA and can include a pad section 211. For example, the bending area BA can be in a bent state, and the remaining area of the substrate 210 excluding the bending area BA can be in a flat state. In this case, as the bending area BA is bent, the second non-display area NDA2 can be located on the back surface of the display area DA. However, the embodiments of the present disclosure are not limited thereto.

The display area DA of the substrate 210 or the display device 100 can be configured in various shapes according to the design of the display device 100. For example, the display area DA can be configured in a rectangular shape with four corners formed in a round shape. For another example, the display area DA can be configured in a rectangular shape with four corners formed in a right angle shape, or a circular shape.

A width of the second non-display area NDA2 where the pad section 211 is disposed can be greater than a width of the bending area BA. In addition, a width of the display area DA can be wider than the width of the bending area BA. In the drawing, the width of the bending area BA is depicted as being narrower than the width of other areas of the substrate 210, but the shape of the substrate 210 including the bending area BA is example, and the embodiments of the present disclosure are not limited thereto.

The flexible printed circuit 102 and a printed circuit board 104 can be disposed at a lower portion of the display panel 110. The flexible printed circuit 102 and the printed circuit board 104 can be arranged at one edge of the display panel 100. One side of the flexible printed circuit 102 can be connected to the display panel 110, and the other side can be connected to the printed circuit board 104. The flexible printed circuit 102 can be a flexible film.

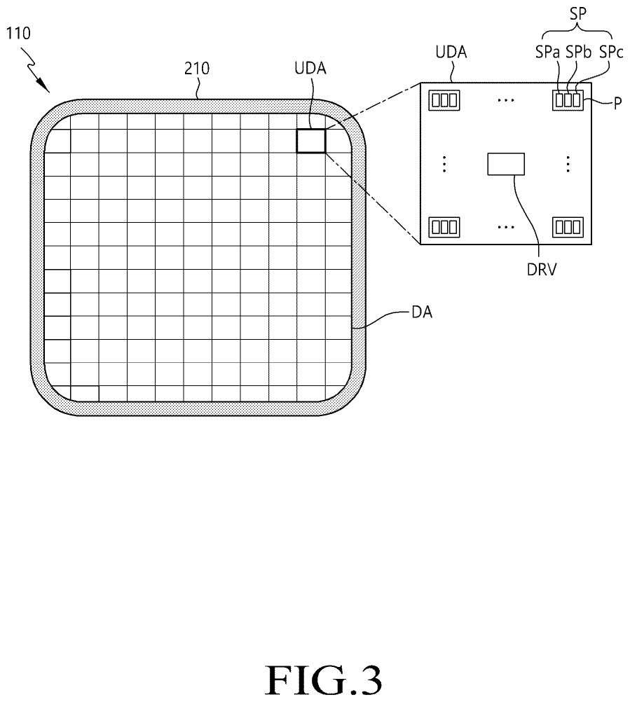

The pad section 211 disposed in the second non-display area NDA2 includes a plurality of pads, and a driving component including one or more flexible printed circuits 102 and a printed circuit board 104 can be attached or bonded. The plurality of pads included in the pad section 211 are electrically connected to one or more flexible printed circuits 102, and can transmit various signals (or power) from the printed circuit board 104 and one or more flexible printed circuits 102 to a driving circuit (for example, a driver DRV of FIG. 3) arranged in the display area DA.

The flexible printed circuit 102 can be a film in which various components are arranged on a flexible base film. For example, a first circuit component 230, such as a gate drive integrated circuit and/or a data drive integrated circuit, can be arranged on one or more flexible printed circuits 102. The first circuit component 230 can be a component that processes data and a driving signal for displaying an image. The first circuit component 230 can be arranged in a manner such as a chip-on-glass (COG), a chip-on-film (COF), or a tape carrier package (TCP) depending on the mounting method. The flexible printed circuit 102 can be attached or bonded to a plurality of pads through a conductive adhesive layer.

The printed circuit board 104 can be a component that is electrically connected to the flexible printed circuit 102 and supplies a signal to the first circuit component 230. The printed circuit board 104 can be arranged on one side of the flexible printed circuit 102 and can be electrically connected to the flexible printed circuit 102. Various components for supplying various signals to the first circuit component 230 can be arranged on the printed circuit board 104. For example, various second circuit components 240, such as a timing controller, a power supply, a memory, or a processor, can be arranged on the printed circuit board 104. For example, the second circuit components 240 arranged on the printed circuit board 104 can include a timing controller and/or a power management integrated circuit (PMIC).

The printed circuit board 104 can include at least one hole. An internal component detecting ambient light or temperature, such as a plurality of sensors, can be arranged in an area corresponding to at least one hole. For example, the internal component can include an ambient light sensor (ALS) or a temperature sensor. For example, the hole can be a transmission hole.

The polarizing layer 114 can be arranged on a display panel 110 and can prevent or reduce light generated from an external light source from entering the display panel 110 and affecting a light emitting device.

A cover member 118 can be arranged on a polarizing layer 114 and can be a member for protecting the display panel 110.

A second adhesive layer 116 can be disposed between the polarizing layer 114 and the cover member 118. The second adhesive layer 116 can attach the cover member 118 to the display panel 110 or the polarizing layer 114.

A first adhesive layer 112 can be disposed between the display panel 110 and the polarizing layer 114. The first adhesive layer 112 can attach the polarizing layer 114 to the display panel 110. The first adhesive layer 112 can be omitted.

Each of the first adhesive layer 112 and the second adhesive layer 116 can include an optically clear adhesive (OCA), an optically clear resin (OCR), or a pressure sensitive adhesive (PSA).

The support substrate 106 is disposed between the display panel 110 and the printed circuit board 104 to reinforce the rigidity of the display panel 110. The support substrate 106 can be a back plate.

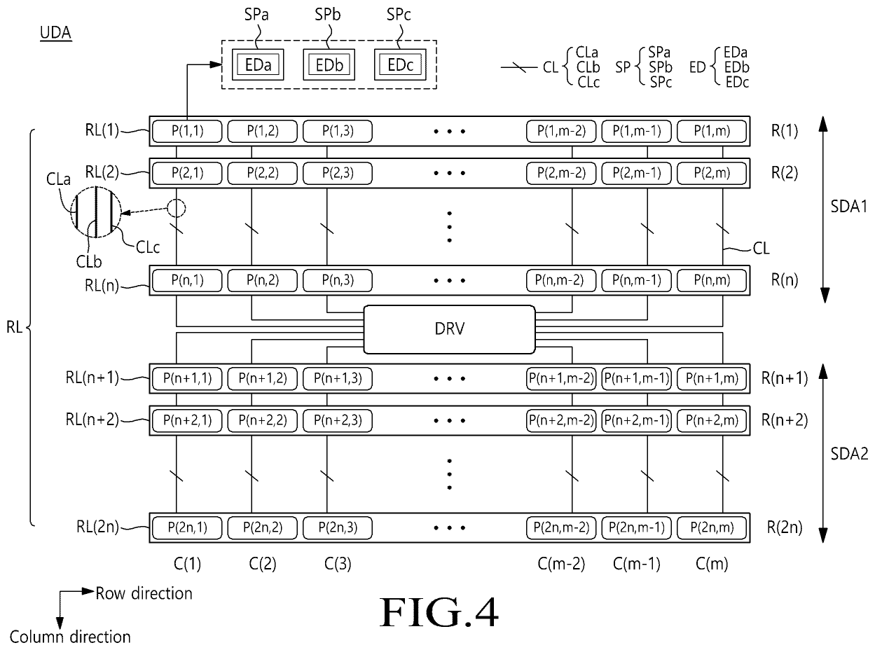

FIG. 3 is a plan view of a display panel 110 according to embodiments of the present disclosure, and FIG. 4 is a plan view of a unit driving area UDA of the display panel 110 according to embodiments of the present disclosure.

Referring to FIG. 3, the display area DA of the display panel 110 according to the embodiments of the present disclosure can include a plurality of unit driving areas UDA.

The display panel 110 according to the embodiments of the present disclosure can include a driver DRV arranged in each of the plurality of unit driving areas UDA. For example, the driver DRV can be a driving chip manufactured using a MOSFET (Metal-oxide-semiconductor field effect transistor) manufacturing process on a semiconductor substrate.

Each of the plurality of unit driving areas UDA can be a driving area driven by one driver DRV. For example, the plurality of unit driving areas UDA can be independent driving areas driven by different drivers DRV.

The display panel 110 according to the embodiments of the present disclosure can include a substrate 210 including a display area DA, and a plurality of pixels P arranged in a matrix form in the display area DA.

A plurality of pixels P can be arranged in each of the plurality of unit driving areas UDA. Each of the plurality of pixels P can include a plurality of sub-pixels SP. Each of the plurality of sub-pixels SP can include at least one light emitting device.

For example, the plurality of sub-pixels SP can include a first sub-pixel SPa, a second sub-pixel SPb, and a third sub-pixel SPc, but is not limited thereto. The first sub-pixel SPa can include a first light emitting device that emits a first color light, the second sub-pixel SPb can include a second light emitting device that emits a second color light, and the third sub-pixel SPc can include a third light emitting device that emits a third color light. For example, the first color light, the second color light, and the third color light can be red light, green light, and blue light, respectively, but are not limited thereto.

The display panel 110 according to the embodiments of the present disclosure can include a plurality of light emitting devices ED. Each of the plurality of sub-pixels SP can include a light emitting device ED.

For example, the first sub-pixel SPa can include a first light emitting device EDa, the second sub-pixel SPb can include a second light emitting device EDb, and the third sub-pixel SPc can include a third light emitting device EDc.

The display panel 110 according to the embodiments of the present disclosure can include a plurality of row lines RL and a plurality of column lines CL.

Each of the plurality of row lines RL can be arranged to extend in a row direction. The plurality of row lines RL can be electrically connected to a first electrode of each of a plurality of light emitting devices ED.

Each of the plurality of column lines CL can be arranged to extend in a column direction. The plurality of column lines CL can be electrically connected to a second electrode of each of the plurality of light emitting device ED.

For example, the first electrode of each of the plurality of light emitting device ED can be an anode electrode, and the second electrode of each of the plurality of light emitting device ED can be a cathode electrode. For another example, the first electrode of each of the plurality of light emitting device ED can be a cathode electrode, and the second electrode of each of the plurality of light emitting device ED can be an anode electrode.

Each of the plurality of row lines RL can be electrically connected to the second electrode of each of the plurality of light emitting device ED. For example, the second electrodes of each of the plurality of light emitting device ED can be commonly connected to one row line RL.

Each of the plurality of column lines CL can be electrically connected to the first electrode of each of the plurality of light emitting device ED. For example, the first electrode of each of the plurality of light emitting device ED can be commonly connected to one column line CL.

The line width of each of the plurality of row lines RL can be greater than the line width of each of the plurality of column lines CL.

The display panel 110 according to the embodiments of the present disclosure can include a plurality of drivers DRV. The plurality of drivers DRV can drive the plurality of light emitting device ED, the plurality of column lines CL, and the plurality of row lines RL.

The plurality of drivers DRV can be built into the display panel 110. The plurality of drivers DRV can be arranged in the display area DA, and can be arranged on the substrate 210. The plurality of drivers DRV can be arranged to correspond to a plurality of unit driving areas UDA. For example, one driver DRV can be arranged in one unit driving area UDA.

Each of the plurality of drivers DRV can drive a plurality of row lines RL and a plurality of column lines CL arranged in a corresponding unit driving area UDA among the plurality of unit driving areas UDA, thereby emitting light from a plurality of light emitting device ED arranged in the corresponding unit driving area UDA.

The plurality of drivers DRV are disposed in the display area DA, and can be positioned closer to the substrate 210 than the plurality of light emitting device ED.

For example, the plurality of row lines RL can be driven sequentially. For another example, the plurality of row lines RL can be driven simultaneously. For another example, two or more row lines RL among the plurality of row lines RL can be driven simultaneously.

For example, during a specific display driving period, among the plurality of row lines RL arranged in the unit driving area UDA, at least one row line RL can be driven, and the remaining row lines RL may not be driven.

According to the embodiments of the present disclosure, a voltage applied to the row line RL can be referred to as a low-potential voltage, and the low-potential voltage can also be referred to as a row line voltage or a cathode voltage. The low-potential voltage can have various voltage values depending on the driving type or driving state. For example, the low-potential voltage can include a first low-potential voltage, a second low-potential voltage, and a third low-potential voltage.

Driving the row line RL can mean that the first low-potential voltage is supplied to the row line RL. Not driving the row line RL can mean that the second low-potential voltage higher than the first low-potential voltage is supplied to the row line RL. Accordingly, the light emitting device ED overlapping with the driven row line RL can emit light, and the light emitting device ED overlapping with the non-driven row line RL may not emit light.

For example, any first row line RL among the plurality of row lines RL can be supplied with a first low-potential voltage during a first period, and can be supplied with a second low-potential voltage higher than the first low-potential voltage during a second period different from the first period. Accordingly, the light emitting devices ED overlapping with the first row line RL can emit light during the first period, and may not emit light during the second period different from the first period. For example, the first period and the second period can be included in one display driving period. For another example, the first period and the second period can be included in different display driving periods.

The structure of one unit driving area UDA will be described in more detail with reference to FIG. 4.

Referring to FIG. 4, as an example, one unit driving area UDA can be divided into a first sub-driving area SDA1 and a second sub-driving area SDA2. As another example, one unit driving area UDA can be divided into three or more sub-driving areas. As another example, one unit driving area UDA may not be divided into two or more sub-driving areas.

One unit driving area UDA can include one driver DRV and (2n×m) pixels P(1, 1), . . . , P(1, m), P(2, 1), . . . , P(2, m), . . . , P(2n, 1), . . . , P(2n, m) driven by one driver DRV. Here, n and m can be real numbers.

In the embodiments of the present disclosure, n can be a sequence number of a row, or the number of rows in each of the first sub-driving area SDA1 and the second sub-driving area SDA2, or the number of row lines RL in each of the first sub-driving area SDA1 and the second sub-driving area SDA2, or the number of pixel rows in each of the first sub-driving area SDA1 and the second sub-driving area SDA2. m can be a sequence number of a column, or the number of columns in each of the first sub-driving area SDA1 and the second sub-driving area SDA2, or the number of column lines CL in each of the first sub-driving area SDA1 and the second sub-driving area SDA2, or the number of pixel columns in each of the first sub-driving area SDA1 and the second sub-driving area SDA2.

In the examples of the present disclosure, n can be a natural number greater than or equal to 1, and m can be a natural number greater than or equal to 1.

Further, (2n×m) pixels P(1, 1), . . . , P(1, m), P(2, 1), . . . , P(2, m), . . . , P(2n, 1), . . . , P(2n, m) can be arranged in 2n rows R(1), . . . , R(2n) and m columns C(1), . . . , C(m).

Among (2n×m) pixels P(1, 1), . . . , P(1, m), P(2, 1), . . . , P(2, m), . . . , P(2n, 1), . . . , P(2n, m), (n×m) pixels P(1, 1), . . . , P(1, m), P(2, 1), . . . , P(2, m), . . . , P(n, 1), . . . , P(n, m) arranged in the first to n-th rows R(1), . . . , R(n) can be arranged in the first sub-driving area SDA1.

Among (2n×m) pixels P(1, 1), . . . , P(1, m), P(2, 1), . . . , P(2, m), . . . , P(2n, 1), . . . , P(2n, m), (n×m) pixels P(n+1, 1), . . . , P(n+1, m), P(n+2, 1), . . . , P(n+2, m), . . . , P(2n, 1), . . . , P(2n, m) arranged in the (n+1)-th to the 2n-th row R(n+1), . . . , R(2n) can be arranged in the second sub-driving area SDA2.

One unit driving area UDA can include 2n row lines RL(1), . . . , RL(2n) to drive (2n×m) pixels P(1, 1), . . . , P(1, m), P(2, 1), . . . , P(2, m), . . . , P(2n, 1), . . . , P(2n, m).

Among the 2n row lines RL(1), . . . , RL(2n), the first to n-th row lines R(1), . . . , RL(n) can be arranged in the first sub-driving area SDA1. Among the 2n row lines RL(1), . . . , RL(2n), the (n+1)-th to the 2n-th row lines R(n+1), . . . , R(2n) can be arranged in the second sub-driving area SDA2.

Each of the 2n row lines RL(1), . . . , RL(2n) can overlap with m pixels. For example, the first row line RL(1) can overlap with m pixels P(1, 1), . . . , P(1, m) arranged in the first row R(1). The n-th row line RL(n) can overlap with m pixels P(n, 1), . . . , P(n, m) arranged in the n-th row R(n). The (n+1)-th row line RL(n+1) can overlap with the m pixels P(n+1, 1), . . . , P(n+1, m) arranged in the (n+1)-th row R(n+1). The 2n-th row line RL(2n) can overlap with the m pixels P(2n, 1), . . . P(2n, m) arranged in the 2nth row R(2n).

For example, the first row line RL(1) can be connected to the k sub-pixels SPa, SPb and SPc included in each of the m pixels P(1, 1), . . . , P(1, m) arranged in the first row R(1). More specifically, the first row line RL(1) can be connected to the second electrodes of the k light emitting devices EDa, EDb and EDc included in each of the m pixels P(1, 1), . . . , P(1, m) arranged in the first row R(1).

For example, the n-th row line RL(n) can be connected to the k sub-pixels SPa, SP and SPc included in each of the m pixels P(n, 1), . . . , P(n, m) arranged in the n-th row R(n). More specifically, the n-th row line RL(n) can be connected to the first electrodes of the k light emitting devices EDa, EDb and EDc included in each of the m pixels P(n, 1), . . . , P(n, m) arranged in the n-th row R(n).

For example, the (n+1)-th row line RL(n+1) can be connected to k sub-pixels SPa, SPb and SPc included in each of m pixels P(n+1, 1), . . . , P(n+1, m) arranged in the (n+1)-th row R(n+1). More specifically, the (n+1)-th row line RL(n+1) can be connected to first electrodes of k light emitting devices EDa, EDb and EDc included in each of m pixels P(n+1, 1), . . . , P(n+1, m) arranged in the (n+1)-th row R(n+1).

For example, the 2n-th row line RL(2n) can be connected to k sub-pixels SPa, SPb and SPc included in each of m pixels P(2n, 1), . . . P(2n, m) arranged in the 2n-th row R(2n). More specifically, the 2n-th row line RL(2n) can be connected to first electrodes of k light emitting devices EDa, EDb and EDc included in each of m pixels P(2n, 1), . . . P(2n, m) arranged in the 2n-th row R(2n).

One unit driving area UDA can include (m×k×2) column lines CL to drive (2n×m) pixels P(1, 1), . . . , P(1, m), P(2, 1), . . . , P(2, m), . . . , P(2n, 1), . . . , P(2n, m). Here, k is the number of sub-pixels SP included in one pixel P. In the example of FIG. 4, k is 3. For example, one pixel P can include three sub-pixels SPa, SPb and SPc.

The first sub-driving area SDA1 can include (m×k) column lines CL to drive (n×m) pixels P(1, 1), . . . , P(1, m), . . . , P(n, 1), . . . , P(n, m) arranged in the first sub-driving area SDA1. In the example of FIG. 4, since k is 3, the first sub-driving area SDA1 can include 3m column lines CL.

In the first sub-driving area SDA1, k column lines CLa, CLb and CLc can be arranged in each of the m columns C(1), . . . , C(m). In the example of FIG. 4, since k is 3, in the first sub-driving area SDA1, each of the m columns C(1), . . . , C(m) can include three column lines CLa, CLb and CLc.

In each of the m columns C(1), . . . , C(m), each of the k column lines CL can be commonly connected to n pixels arranged in the corresponding column. In each of the m columns C(1), . . . , C(m), each of the k column lines CL can be commonly connected to first electrodes of n light emitting devices ED arranged in the corresponding column. In the example of FIG. 4, since k is 3, in each of the m columns C(1), . . . , C(m), three column lines CLa, CLb and CLc can be connected to the first electrodes of the 3n light emitting devices ED included in the n pixels arranged in the corresponding column. For example, in each of the m columns C(1), . . . , C(m), a first column line CLa can be commonly connected to the first electrodes of the n first light emitting devices EDa arranged in the corresponding column. In each of the m columns C(1), . . . , C(m), a second column line CLb can be commonly connected to the first electrodes of the n second light emitting devices EDb arranged in the corresponding column. In each of the m columns C(1), . . . , C(m), a third column line CLc can be commonly connected to the first electrodes of the n third light emitting devices EDc arranged in the corresponding column.

The second sub-driving area SDA2 can include (m×k) column lines CL to drive (n×m) pixels P(n+1, 1), . . . , P(n+1, m), . . . , P(2n, 1), . . . , P(2n, m) arranged in the second sub-driving area SDA2. In the example of FIG. 4, since k is 3, the second sub-driving area SDA2 can include 3m column lines CL.

In the second sub-driving area SDA2, k column lines CL can be arranged in each of the m columns C(1), . . . , C(m). In the example of FIG. 4, since k is 3, in the second sub-driving area SDA2, each of the m columns C(1), . . . , C(m) can include three column lines CLa, CLb and CLc.

In each of the m columns C(1), . . . , C(m), each of the k column lines CL can be commonly connected to n pixels arranged in the corresponding column. In each of the m columns C(1), . . . , C(m), each of the k column lines CL can be commonly connected to first electrodes of n light emitting devices ED arranged in the corresponding column. In the example of FIG. 4, since k is 3, in each of the m columns C(1), . . . , C(m), three column lines CLa, CLb and CLc can be connected to the first electrodes of the 3n light emitting devices ED included in the n pixels arranged in the corresponding column. For example, in each of the m columns C(1), . . . , C(m), a first column line CLa can be commonly connected to the first electrodes of the n first light emitting devices EDa arranged in the corresponding column. In each of the m columns C(1), . . . , C(m), the second column line CLb can be commonly connected to the first electrodes of the n second light emitting devices EDb arranged in the corresponding column. In each of the m columns C(1), . . . , C(m), the third column line CLc can be commonly connected to the first electrodes of the n third light emitting devices EDc arranged in the corresponding column.

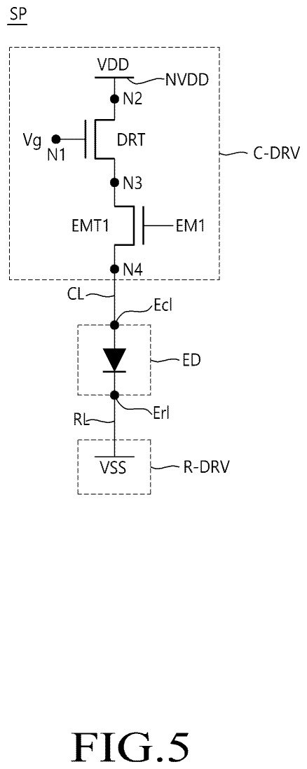

FIG. 5 illustrates a sub-pixel SP of a display panel 110 according to embodiments of the present disclosure.

Referring to FIG. 5, the sub-pixel SP according to embodiments of the present disclosure can include a light emitting device ED including a first electrode Ecl and a second electrode Erl, a column driver C-DRV for driving a column line CL electrically connected to the first electrode Ecl of the light emitting device ED, and a row driver R-DRV for driving a row line RL electrically connected to the second electrode Erl of the light emitting device ED.

The light emitting device ED can include a first electrode Ecl and a second electrode Erl. The first electrode Ecl can be electrically connected to a column line CL, and the second electrode Erl can be electrically connected to a row line RL. For example, the first electrode Ecl can be an anode electrode, and the second electrode Erl can be a cathode electrode. For another example, the first electrode Ecl can be a cathode electrode, and the second electrode Erl can be an anode electrode.

A column driver C-DRV included in a unit driving area UDA can be connected to a plurality of column lines CL included in the unit driving area UDA, and can drive a plurality of column lines CL included in the unit driving area UDA. Each of the plurality of column lines CL can be commonly connected to the first electrode Ecl of each of the plurality of light emitting devices ED included in the plurality of sub-pixels SP arranged in the corresponding column.

A row driver R-DRV included in a unit driving area UDA can be connected to a plurality of row lines RL included in the unit driving area UDA and can drive a plurality of row lines RL included in the unit driving area UDA. Each of the plurality of row lines RL can be commonly connected to a second electrode Erl of each of a plurality of light emitting devices ED included in a plurality of sub-pixels SP arranged in the corresponding row.

The column driver C-DRV can include main nodes including a first node N1, a second node N2, a third node N3, and a fourth node N4. The column driver C-DRV can include a driving transistor DRT and a first emission control transistor EMT1.

The first node N1 can be a node to which a voltage Vg for controlling the on-off of the driving transistor DRT is applied. The second node N2 can be a node electrically connected to a high-potential voltage node NVDD to which a high-potential voltage VDD is applied. The third node N3 can be a node to which the driving transistor DRT and the first emission control transistor EMT1 are connected. The fourth node N4 can be a node to which the first emission control transistor EMT1 and the light emitting device ED are electrically connected, and can be a node to which the column line CL is electrically connected. Here, a source electrode or a drain electrode of the first emission control transistor EMT1 and the first electrode Ecl of the light emitting device ED can be commonly connected to the column line CL.

The driving transistor DRT supplies a driving current to make the light emitting device ED emit light, is connected between the second node N2 and the third node N3, and can control the connection between the second node N2 and the third node N3 according to the voltage of the first node N1.

The gate electrode of the driving transistor DRT is electrically connected to the first node N1, and a gate voltage Vg can be applied thereto. The drain electrode or the source electrode of the driving transistor DRT can be electrically connected to the second node N2. The source electrode or the drain electrode of the driving transistor DRT can be electrically connected to the third node N3.

The first emission control transistor EMT1 can control a connection of a path through which the driving current flows, and can play a role in controlling an emission of the light emitting device ED.

If the driving transistor DRT and the first emission control transistor EMT1 are turned on between a high-potential voltage VDD and a low-potential voltage VSS, the driving current can be supplied to the light emitting device ED through the driving transistor DRT and the first emission control transistor EMT1. Accordingly, the light emitting device ED can emit light.

The first emission control transistor EMT1 is connected between the third node N3 and the fourth node N4, and can control the connection between the third node N3 and the fourth node N4 according to a first emission control signal EM1. The first emission control signal EM1 can be applied to the gate electrode of the first emission control transistor EMT1. The drain electrode or the source electrode of the first emission control transistor EMT1 can be electrically connected to the third node N3. The source electrode or drain electrode of the first emission control transistor EMT1 can be electrically connected to the fourth node N4.

The first emission control signal EM1 can be a pulse width modulation signal that varies at a predefined time (for example, each frame, or each sub-frame included in one frame).

The first emission control signal EM1 can be generated by the driver DRV, or can be supplied to the driver DRV from a driving-related circuit such as a timing controller. For example, if the first emission control signal EM1 is a pulse width modulation signal, the first emission control signal EM1 can have a pulse width corresponding to an image signal (e.g., data voltage, data signal). For example, if the pulse width of the first emission control signal EM1 is large, the light emission brightness of the light emitting device ED can be high. If the pulse width of the first emission control signal EM1 is small, the light emission brightness of the light emitting device ED can be low.

The row driver R-DRV can drive at least one row line RL by supplying a low-potential voltage VSS to at least one row line RL.

The row driver R-DRV can perform display-on driving or display-off driving for one row line RL.

The row driver R-DRV can supply a low-potential voltage for display-on driving to one row line RL in order to perform display-on driving for one row line RL. The row driver R-DRV can supply a low-potential voltage for display-off driving to one row line RL in order to perform display-off driving for one row line RL.

A low-potential voltage for display-on driving and a low-potential voltage for display-off driving can be different. For example, the low-potential voltage for display-on driving can be lower than the low-potential voltage for display-off driving. In the embodiments of the present disclosure, the “low-potential voltage for display-on driving” is also referred to as the “first low-potential voltage,” and the “low-potential voltage for display-off driving” is also referred to as the “second low-potential voltage.”

The column driver C-DRV can further include at least one switching element and/or at least one transistor in addition to the driving transistor DRT and the first emission control transistor EMT1. Each of the transistors included in the column driver C-DRV can be an n-type transistor or a p-type transistor.

The column driver C-DRV can further include at least one capacitor.

The column driver C-DRV can further include at least one circuit element. For example, the at least one circuit element can include a power output buffer.

Referring to FIG. 5, the row driver R-DRV can include at least one switching element and/or at least one transistor. Each of the transistors included in the row driver R-DRV can be an n-type transistor or a p-type transistor.

The row driver R-DRV can further include at least one circuit element. For example, at least one circuit element can include a power output buffer.

Referring to FIG. 5, all or a part of the column driver C-DRV and the row driver R-DRV can be internal circuits included in the driver DRV. As another example, all or a part of the column driver C-DRV and the row driver R-DRV may not be included in the driver DRV and can be circuits formed on the substrate 210 of the display panel 110.

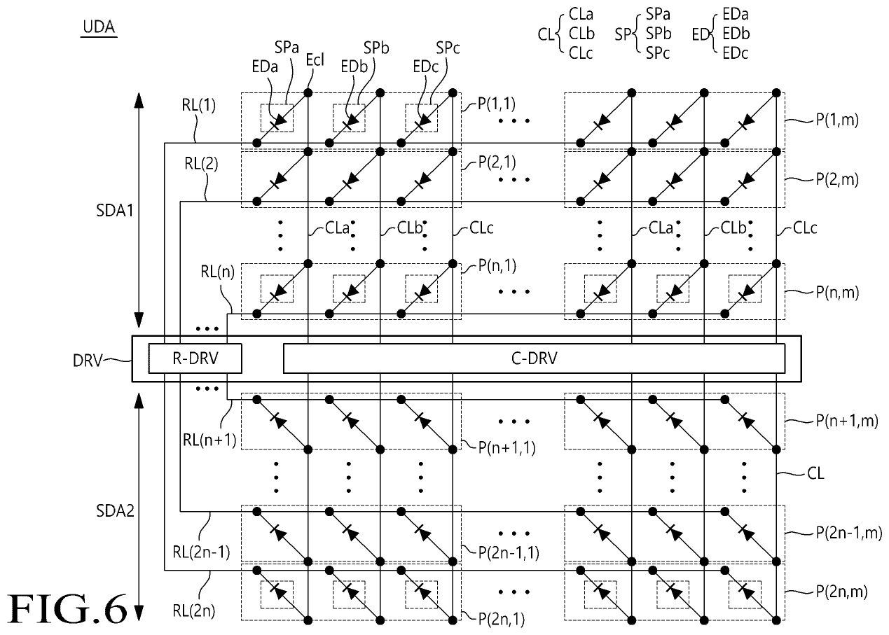

FIG. 6 is an equivalent circuit diagram of a unit driving area UDA of a display panel 110 according to embodiments of the present disclosure. Here, FIG. 4 and FIG. 5 are also referred to in the following description.

Each of the plurality of unit driving areas UDA can correspond to one driver DRV among the plurality of drivers DRV. For example, one driver DRV among the plurality of drivers DRV can be arranged in each of the plurality of unit driving areas UDA.

Each of the plurality of unit driving areas UDA can include two or more row lines RL(1) to RL(2n) among all row lines RL arranged in the display panel 110 and two or more column lines CL among all column lines CL arranged in the display panel 110.

Referring to FIG. 6, each of the plurality of unit driving areas UDA can include a first sub-driving area SDA1 and a second sub-driving area SDA2. Some of the two or more row lines RL(1) to RL(2n) can be arranged in the first sub-driving area SDA1), and the rest can be arranged in the second sub-driving area SDA2. Some of the two or more column lines CL can be arranged in the first sub-driving area SDA1, and the rest can be arranged in the second sub-driving area SDA2.

Each of the plurality of unit driving areas UDA can include a plurality of pixels P(1, 1), . . . , P(1, m), P(2, 1), . . . , P(2, m), . . . , P(2n, 1), . . . , P(2n, m) arranged in a matrix form.

Each of the plurality of pixels P(1, 1), . . . , P(1, m), P(2, 1), . . . , P(2, m), . . . , P(2n, 1), . . . , P(2n, m) can include k sub-pixels SPa, SPb and SPc. The k sub-pixels SPa, SPb and SPc can include k light emitting devices EDa, EDb and EDc.

Some of the plurality of pixels P(1, 1), . . . , P(1, m), P(2, 1), . . . , P(2, m), . . . , P(2n, 1), . . . , P(2n, m) can be arranged in the first sub-driving area SDA1, and the rest can be arranged in the second sub-driving area SDA2.

The k is the number of sub-pixels included in one pixel. In the example of FIG. 6, k is 3. For example, one pixel can include three sub-pixels SPa, SPb and SPc. Hereinafter, it will be described the structure of the unit driving area UDA is example explained based on an example where k is 3.

The unit driving area UDA can include (2n×m) pixels P(1, 1), . . . , P(1, m), P(2, 1), . . . , P(2, m), . . . , P(2n, 1), . . . , P(2n, m). The (2n×m) pixels P(1, 1), . . . , P(1, m), P(2, 1), . . . , P(2, m), . . . , P(2n, 1), . . . , P(2n, m) can be arranged in 2n rows and m columns.

According to the example of FIG. 6, each of the (2n×m) pixels P(1, 1), . . . , P(1, m), P(2, 1), . . . , P(2, m), . . . , P(2n, 1), . . . , P(2n, m) can include three sub-pixels SPa, SPb and SPc.

According to the example of FIG. 6, three sub-pixels can include a first sub-pixel SPa including a first light emitting device EDa, a second sub-pixel SPb including a second light emitting device EDb, and a third sub-pixel SPc including a third light emitting device EDc.

Half of the (2n×m) pixels P(1, 1), . . . , P(1, m), P(2, 1), . . . , P(2, m), . . . , P(2n, 1), . . . , P(2n, m), which are (n×m) pixels P(1, 1), . . . , P(1, m), . . . , P(n, 1), . . . , P(n, m), can be arranged in the first sub-driving area SDA1.

Among the (2n×m) pixels P(1, 1), . . . , P(1, m), P(2, 1), . . . , P(2, m), . . . , P(2n, 1), . . . , P(2n, m), the remaining half (n×m) pixels P(n+1, 1), . . . , P(n+1, m), . . . , P(2n, 1), . . . , P(2n, m) can be arranged in the second sub-driving area SDA2.

According to the example of FIG. 6, the unit driving area UDA can include 2n row lines RL(1) to RL(2n) and (m×3×2) column lines CL.

Further, n row lines RL(1) to RL(n), which are half of 2n row lines RL(1) to RL(2n), can be arranged in the first sub-driving area SDA1, and n row lines RL(n+1) to RL(2n), which are the remaining half of 2n row lines RL(1) to RL(2n), can be arranged in the second sub-driving area SDA2.

The n row lines RL(1) to RL(n) arranged in the first sub-driving area SDA1 can correspond to (n×m) pixels P(1, 1), . . . , P(1, m), . . . , P(n, 1), . . . , P(n, m) arranged in the first sub-driving area SDA1 by row (i.e., pixel row).

For example, among the n row lines RL(1) to RL(n) arranged in the first sub-driving area SDA1, the first row line RL(1) arranged in the first row (i.e., the first pixel row) can correspond to m pixels P(1, 1), . . . , P(1, m) included in the first pixel row. The first row line RL(1) can be electrically connected to all of the second electrodes Erl of each of the 3m light emitting devices ED included in the first pixel row.

For another example, among the n row lines RL(1) to RL(n) arranged in the first sub-driving area SDA1, the second row line RL(2) arranged in the second row (i.e., the second pixel row) can correspond to m pixels P(2, 1), . . . , P(2, m) included in the second pixel row. The second row line RL(2) can be electrically connected to all of the second electrodes Erl of each of the 3m light emitting devices ED included in the second pixel row.

For another example, among the n row lines RL(1) to RL(n) arranged in the first sub-driving area SDA1, the n-th row line RL(n) arranged in the n-th row (i.e., the n-th pixel row) can correspond to the m pixels P(n, 1), . . . , P(n, m) included in the n-th pixel row. The n-th row line RL(n) can be electrically connected to all of the second electrodes Erl of each of the 3m light emitting devices ED included in the n-th pixel row.

The n row lines RL(n+1) to RL(2n) arranged in the second sub-driving area SDA2 can correspond to the (n×m) pixels P(n+1, 1), . . . , P(n+1, m), . . . , P(2n, 1), . . . , P(2n, m) arranged in the second sub-driving area SDA2 by row (i.e., pixel row).

For example, among the n row lines RL(n+1) to RL(2n) arranged in the second sub-driving area SDA2, the (n+1)-th row line RL(n+1) arranged in the (n+1)-th row (i.e., the (n+1)-th pixel row) can correspond to the m pixels P(n+1, 1), . . . , P(n+1, m) included in the (n+1)-th pixel row. The (n+1)-th row line RL(n+1) can be electrically connected to all of the second electrodes Er of each of the 3m light emitting devices ED included in the (n+1)-th pixel row.

For another example, among the n row lines RL(n+1) to RL(2n) arranged in the second sub-driving area SDA2, the (2n−1)-th row line RL(2n−1) arranged in the (2n−1)-th row (i.e., the (2n−1)-th pixel row) can correspond to the m pixels P(2n−1, 1), . . . , P(2n−1, m) included in the (2n−1)-th pixel row. The (2n−1)-th row line RL(2n−1) can be electrically connected to all of the second electrodes Erl of each of the 3m light emitting devices ED included in the (2n−1)-th pixel row.

For another example, among the n row lines RL(n+1) to RL(2n) arranged in the second sub-driving area SDA2, the 2n-th row line RL(2n) arranged in the 2n-th row (i.e., 2n-th pixel row) can correspond to the m pixels P(2n, 1), . . . , P(2n, m) included in the 2n-th pixel row. The 2n-th row line RL(2n) can be electrically connected to all of the second electrodes Erl of each of the 3m light emitting devices ED included in the 2n-th pixel row.

In addition, 3m column lines CL, which are half of the (m×3×2) column lines CL, can be arranged in the first sub-driving area SDA1, and the remaining half of the (m×3×2) column lines CL, which are 3m column lines CL, can be arranged in the second sub-driving area SDA2.

The 3m column lines CL arranged in the first sub-driving area SDA1 can correspond to (n×m) pixels P(1, 1), . . . , P(1, m), . . . , P(n, 1), . . . , P(n, m) placed in the first sub-driving area SDA1 by column (i.e., pixel column).

For example, among the 3m column lines CL arranged in the first sub-driving area SDA1, three first column lines CLa, CLb and CLc arranged in a first column (i.e., the first pixel column) can correspond to n pixels P(1, 1), P(2, 1), . . . , P(n, 1) arranged in the first pixel column.

In the first sub-driving area SDA1, three first column lines CLa, CLb and CLc arranged in the first pixel column can be connected to three sub-pixels SPa, SPb and SPc included in each of n pixels P(1, 1), P(2, 1), . . . , P(n, 1) arranged in the first pixel column.

In the first sub-driving area SDA1, three first column lines CLa, CLb and CLc arranged in the first pixel column can be electrically connected to all of the first electrodes Ecl of three light emitting devices EDa, EDb and EDc included in each of n pixels P(1, 1), P(2, 1), . . . , P(n, 1) arranged in the first pixel column.

For example, among the 3m column lines CL arranged in the first sub-driving area SDA1, three m-th column lines CLa, CLb and CLc arranged in a m-th column (i.e., m-th pixel column) can correspond to n pixels P(1, m), P(2, m), . . . , P(n, m) arranged in the m-th pixel column.

In the first sub-driving area SDA1, three m-th column lines CLa, CLb and CLc arranged in the m-th pixel column can be connected to three sub-pixels SPa, SPb and SPc included in each of n pixels P(1, m), P(2, m), . . . , P(n, m) arranged in the m-th pixel column.

In the first sub-driving area SDA1, three m-th column lines CLa, CLb and CLc arranged in the m-th pixel column can be electrically connected to all of the first electrodes Ecl of three light emitting devices EDa, EDb and EDc included in each of n pixels P(1, m), P(2, m), . . . , P(n, m) arranged in the m-th pixel column.

The 3m column lines CL arranged in the second sub-driving area SDA2 can correspond to (n×m) pixels P(n+1, 1), . . . , P(n+1, m), . . . , P(2n, 1), . . . , P(2n, m) arranged in the second sub-driving area SDA2 by column (i.e., pixel column).

For example, among the 3m column lines CL arranged in the second sub-driving area SDA2, three first column lines CLa, CLb and CLc arranged in the first column (i.e., the first pixel column) can correspond to n pixels P(n+1, 1), . . . , P(2n−1, 1), P(2n, 1) arranged in the first pixel column.

In the second sub-driving area SDA2, three first column lines CLa, CLb and CLc arranged in the first pixel column can be connected to three sub-pixels SPa, SPb and SPc included in each of n pixels P(n+1, 1), . . . , P(2n−1, 1), P(2n, 1) arranged in the first pixel column.

In the second sub-driving area SDA2, the three first column lines CLa, CLb and CLc arranged in the first pixel column can be electrically connected to all of the first electrodes Ecl of the three light emitting devices EDa, EDb and EDc included in each of the n pixels P(n+1, 1), . . . , P(2n−1, 1), P(2n, 1) arranged in the first pixel column.

For example, among the 3m column lines CL arranged in the second sub-driving area SDA2, the three m-th column lines CLa, CLb and CLc arranged in the m-th column (i.e., the m-th pixel column) can correspond to the n pixels P(n+1, m), . . . , P(2n−1, m), P(2n, m) arranged in the m-th pixel column.

In the second sub-driving area SDA2, three m-th column lines CLa, CLb and CLc arranged in the m-th pixel column can be connected to three sub-pixels SPa, SPb and SPc included in each of n pixels P(n+1, m), . . . , P(2n−1, m), P(2n, m) arranged in the m-th pixel column.

In the second sub-driving area SDA2, three m-th column lines CLa, CLb and CLc arranged in the m-th pixel column can be electrically connected to all of the first electrodes Ecl of three light emitting devices EDa, EDb and EDc included in each of n pixels P(n+1, m), . . . , P(2n−1, m), P(2n, m) arranged in the m-th pixel column.

Two or more row lines RL(1) to RL(2n) arranged in the unit driving area UDA can be electrically connected to the row driver R-DRV included in the driver DRV of the unit driving area UDA. Two or more column lines CL arranged in the unit driving area UDA can be electrically connected to the column driver C-DRV included in the driver DRV of the unit driving area UDA.

The driver DRV can be arranged between the first sub-driving area SDA1 and the second sub-driving area SDA2.

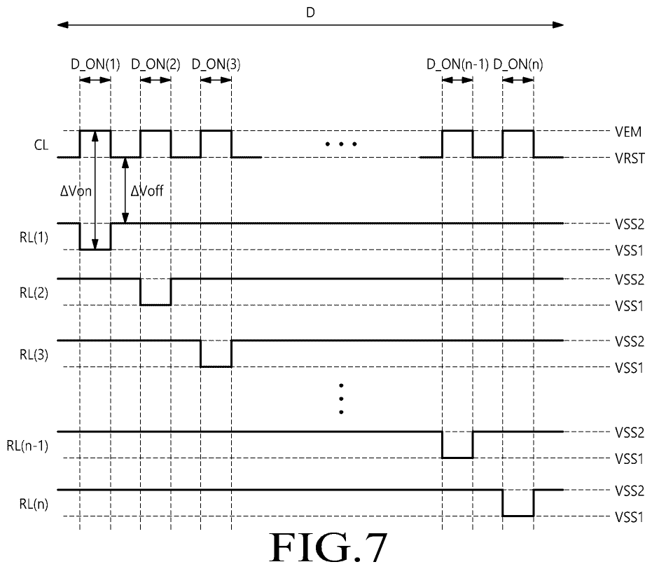

FIG. 7 illustrates a driving timing diagram for n row lines RL(1) to RL(n) and one column line CL included in a first sub-driving area SDA1 of a display panel 110 according to embodiments of the present disclosure. However, FIG. 6 is also referred to in the following description.

Referring to FIG. 7, the row driver R-DRV of the driver DRV can drive n row lines RL(1) to RL(n) arranged in the first sub-driving area SDA1.

The driving for each of the n row lines RL(1) to RL(n) arranged in the first sub-driving area SDA1 can include display-on driving for emitting light emitting devices ED arranged in each of the n row lines RL(1) to RL(n) and display-off driving for not emitting light emitting devices EDs arranged in each of the n row lines RL(1) to RL(n).

Hereinafter, it will be exemplified the driving sequence for each of the n row lines RL(1) to RL(n) arranged in the first sub-driving area SDA1.

For example, display-on driving for each of the plurality of row lines RL can be performed sequentially. As another example, display-on driving for each of the plurality of row lines RL can be performed simultaneously. As another example, display-on driving for each of two or more row lines RL among the plurality of row lines RL can be performed simultaneously. Hereinafter, for convenience of explanation, it will be described as an example a case in which display-on driving for each of the plurality of row lines RL is performed sequentially. However, it is not limited thereto.

The row driver R-DRV of the driver DRV can sequentially drive n row lines RL(1) to RL(n) arranged in the first sub-driving area SDA1. For example, display-on driving periods D_ON(1) to D_ON(n) for n row lines RL(1) to RL(n) arranged in the first sub-driving area SDA1 can be sequential.

Among the n row lines RL(1) to RL(n) arranged in the first sub-driving area SDA1, for any one row line RL, during the display driving period D, the display-on driving period D_ON(1) for the corresponding row line RL can exist at least once. During the display driving period D, all remaining times except the display-on driving period D_ON(1) for the corresponding row line RL can be display-off driving periods.

During any one display driving period D, among the n row lines RL(1) to RL(n) arranged in the unit driving area UDA, the display-on driving can be performed for at least one row line RL, and the display-on driving may not be performed for the remaining row lines RL, but the display-off driving can be performed.

For example, during any one display driving period D, among the n row lines RL(1) to RL(n) arranged in the unit driving area UDA, display-on driving can be performed for a first row line RL(1), and display-off driving can be performed for the second to n-th row lines RL(2) to RL(n).

For another example, during any one display driving period D, among the n row lines RL(1) to RL(n) arranged in the unit driving area UDA, display-on driving can be performed for the second row line RL(2), and display-on driving may not be performed for the first row line RL(1) and a third to n-th row lines RL(3) to RL(n).

For another example, during any one display driving period D, among the n row lines RL(1) to RL(n) arranged in the unit driving area UDA, display-on driving can be performed for the third row line RL(3), and display-off driving can be performed instead of display-on driving for the first and second row lines RL(1), RL(2) and the fourth to n-th row lines RL(4) to RL(n).

For another example, during any one display driving period D, among the n row lines RL(1) to RL(n) arranged in the unit driving area UDA, display-on driving can be performed for the (n−1)-th row line RL(n−1), and display-off driving can be performed instead of display-on driving for the first to (n−2)-th row lines RL(1) to RL(n−2) and the n-th row line RL(n).

For another example, during any one display driving period D, among the n row lines RL(1) to RL(n) arranged in the unit driving area UDA, display-on driving can be performed for the n-th row line RL(n), and display-off driving can be performed instead of display-on driving for the first to (n−1)-th row lines RL(1) to RL(n−1).

If display-on driving is performed for any row line RL among the n row lines RL(1) to RL(n) arranged in the unit driving area UDA, it can mean that a first low-potential voltage VSS1 of a predefined level is supplied to the corresponding row line RL. When display-on driving is performed for any row line RL, the light emitting devices ED arranged corresponding to the corresponding row line RL can emit light.

If display-off driving is performed for any row line RL among the n row lines RL(1) to RL(n) arranged in the unit driving area UDA without display-on driving, it can mean that a second low-potential voltage VSS2 of a predefined level is supplied to the corresponding row line RL. When display-off driving is performed for a specific row line RL, the light emitting devices ED arranged corresponding to the corresponding row line RL may not emit light.

The first low-potential voltage VSS1 can be a low-potential voltage VSS for display-on driving, and the second low-potential voltage VSS2 can be a low-potential voltage VSS for display-off driving. The second low-potential voltage VSS2 can be a voltage higher than the first low-potential voltage VSS1.

Any one row line RL among the n row lines RL(1) to RL(n) arranged in the unit driving area UDA can be supplied with the first low-potential voltage VSS1 during a first period, and can be supplied with the second low-potential voltage VSS2 higher than the first low-potential voltage VSS1 during a second period different from the first period. For example, the first period and the second period can be included in one display driving period D. For another example, the first period and the second period can be included in different display driving periods D.

For example, among the n row lines RL(1) to RL(n) arranged in the unit driving area UDA, the first row line RL(1) can be supplied with a first low-potential voltage VSS1 during a first display-on driving period D_ON(1), and can be supplied with a second low-potential voltage VSS2 higher than the first low-potential voltage VSS1 during a second to n-th display-on driving period D_ON(2) to D_ON(n) different from the first display-on driving period D_ON(1).

For example, during the first display-on driving period D_ON(1), the first row line RL(1) can be supplied with a first low-potential voltage VSS1, and the second to n-th row lines RL(2) to RL(n) can be supplied with a second low-potential voltage VSS2. During the second display-on driving period D_ON(2), the second row line RL(2) can be supplied with a first low-potential voltage VSS1, and the first row line RL(1) and the third to n-th row lines RL(3) to RL(n) can be supplied with a second low-potential voltage VSS2.

For example, during the first display-on driving period D_ON(1), a plurality of light emitting devices ED overlapping with the first row line RL(1) and arranged in the first row can emit light, and a plurality of light emitting devices ED overlapping with the second to n-th row lines RL(2) to RL(n) and arranged in the second to n-th rows may not emit light. During the second display-on driving period D_ON(2), a plurality of light emitting devices ED overlapping with the second row line RL(2) and arranged in the second row can emit light, and a plurality of light emitting devices ED overlapping with the first row line RL(1) and the third to n-th row lines RL(3) to RL(n) and arranged in the first row and the third to n-th rows may not emit light.

For example, the first display-on driving period D_ON(1) and the second to n-th display-on driving period D_ON(2) to D_ON(n) can be included in one display driving period D. For another example, the first display-on driving period D_ON(1) and the second to n-th display-on driving period D_ON(2) to D_ON(n) can be included in different display driving periods D.

Referring to FIG. 7, (m×k) column lines CL can be arranged in a unit driving area UDA. In the unit driving area UDA, the (m×k) column lines CL can intersect with n row lines RL(1) to RL(n). The column line CL illustrated in FIG. 7 can be one of the (m×k) column lines CL.

During the display driving period D, each of the (m×k) column lines CL intersecting the n row lines RL(1) to RL(n) can be supplied with a display voltage VEM required to emit light from the corresponding light emitting device ED in synchronization with the display-on driving period D_ON(1) to D_ON(n) of each of the n row lines RL(1) to RL(n). Here, the display voltage VEM can also be referred to as a light emitting driving voltage or an emission driving voltage.

During the display driving period D, during all remaining times except for the display-on driving period D_ON(1) to D_ON(n) of each of the n row lines RL(1) to RL(n), a reset voltage VRST can be applied to each of the (m×k) column lines CL intersecting the n row lines RL(1) to RL(n).

The display voltage VEM can be a constant voltage or a voltage that varies depending on the image signal. The reset voltage VRST can be a voltage that is lower than the display voltage VEM, and can be a constant voltage or a variable voltage.

During the display driving period D, during the display-on driving period D_ON(1) to D_ON(n) of each of the n row lines RL(1) to RL(n), the voltage difference VEM−VSS1 between the display voltage VEM applied to the corresponding column line CL and the first low-potential voltage VSS1 applied to the corresponding row line RL can be a display-on voltage ΔVon.

A light emitting device ED can be connected between the corresponding column line CL and the corresponding row line RL. A display voltage VEM and a first low-potential voltage VSS1 can be applied to each of the first electrode Ecl and the second electrode Erl of the light emitting device ED.

The display-on voltage ΔVon is a voltage difference between the first electrode Ecl and the second electrode Erl of the light emitting device ED, and can be a voltage that can cause the light emitting device ED to emit light. For example, the display-on voltage ΔVon can be equal to or higher than a threshold voltage, which is a unique characteristic value of the light emitting device ED.

During the display driving period D, during all the remaining time except for the display-on driving period D_ON(1) to D_ON(n) of each of the n row lines RL(1) to RL(n), the voltage difference VRST−VSS2 between the reset voltage VRST applied to the corresponding column line CL and the second low-potential voltage VSS2 applied to the corresponding row line RL can be a display-off voltage ΔVoff.

A light emitting device ED can be connected between the corresponding column line CL and the corresponding row line RL. A reset voltage VRST and a second low-potential voltage VSS2 can be applied to each of the first electrode Ecl and the second electrode Erl of the light emitting device ED.

The display-off voltage ΔVoff is a voltage difference between the first electrode Ecl and the second electrode Erl of the corresponding light emitting device ED, and can be a voltage that does not allow the corresponding light emitting device ED to emit light. For example, the display-off voltage ΔVoff can be less than the threshold voltage, which is a unique characteristic value of the corresponding light emitting device ED. For example, the display-on voltage ΔVon can be greater than or equal to the display-off voltage ΔVoff.

Hereinafter, it will be described in more detail a circuit for driving n light emitting devices ED(1) to ED(n) connected to one column line CL in the display panel 110 according to embodiments of the present disclosure.

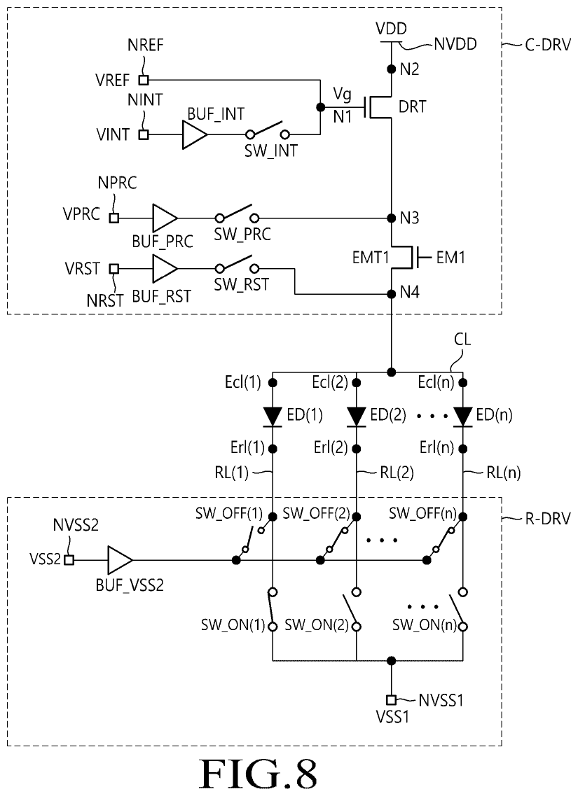

FIG. 8 illustrates a circuit for driving n light emitting devices ED(1) to ED(n) connected to one column line CL included in a first sub-driving area SDA1 of a display panel 110 according to embodiments of the present disclosure. FIG. 4 and FIG. 6 can also be referred to in the following description.

Referring to FIG. 8, n light emitting devices ED(1) to ED(n) connected to one column line CL can be arranged in the same column. The n light emitting devices ED(1) to ED(n) arranged in the same column can be connected to one column line CL. The n light emitting devices ED(1) to ED(n) connected to one column line CL can be arranged in one of the first sub-driving area SDA1 and the second sub-driving area SDA2 included in the unit driving area UDA.

The n light emitting devices ED(1) to ED(n) connected to one column line CL can be light emitting devices emitting the same color light. The n light emitting devices ED(1) to ED(n) arranged in the same column can be light emitting devices emitting the same color light.

For example, the n light emitting devices ED(1) to ED(n) arranged in the same column can emit light sequentially. As another example, the n light emitting devices ED(1) to ED(n) arranged in the same column can emit light simultaneously. As another example, two or more of n light emitting devices ED(1) to ED(n) arranged in the same column can emit light simultaneously.

The n light emitting devices ED(1) to ED(n) arranged in the same column can include first electrodes Ecl(1) to Ecl(n) and second electrodes Erl(1) to Erl(n).

All first electrodes Ecl(1) to Ecl(n) of n light emitting devices ED(1) to ED(n) arranged in the same column can be connected to one column line CL. The second electrodes Erl(1) to Erl(n) of the n light emitting devices ED(1) to ED(n) arranged in the same column can be respectively connected to the n row lines RL(1) to RL(n).

A circuit for driving the n light emitting devices ED(1) to ED(n) arranged in the same column can include a column driver C-DRV and a row driver R-DRV.

The column driver C-DRV can be configured to drive the column line CL connected to all of the first electrodes Ecl(1) to Ecl(n) of the n light emitting devices ED(1) to ED(n) arranged in the same column.

The row driver R-DRV can be configured to drive n row lines RL(1) to RL(n) which are respectively connected to the second electrodes Erl(1) to Erl(n) of n light emitting devices ED(1) to ED(n) arranged in the same column.

The column driver C-DRV can include first to fourth nodes N1 to N4, and can include a driving transistor DRT and a first emission control transistor EMT1.

The first node N1 can be a node to which a voltage Vg for controlling the on-off of the driving transistor DRT is applied. The second node N2 can be a node electrically connected to a high-potential voltage node NVDD to which a high-potential voltage VDD is applied. The third node N3 can be a node to which the driving transistor DRT and the first emission control transistor EMT1 are connected. The fourth node N4 can be a node to which the first emission control transistor EMT1 and the n light emitting devices ED(1) to ED(n) are electrically connected, and can be a node to which the column line CL is electrically connected. Here, the source electrode or the drain electrode of the first emission control transistor EMT1 and the first electrodes Ecl(1) to Ecl(n) of the n light emitting devices ED(1) to ED(n) can be commonly connected to the column line CL.

The driving transistor DRT supplies a driving current to emit light to n light emitting devices ED(1) to ED(n), is connected between the second node N2 and the third node N3, and can control the connection between the second node N2 and the third node N3 according to the voltage of the first node N1.

The gate electrode of the driving transistor DRT is electrically connected to the first node N1, and is supplied with a gate voltage Vg. The drain electrode or the source electrode of the driving transistor DRT can be electrically connected to the second node N2. The source electrode or the drain electrode of the driving transistor DRT can be electrically connected to the third node N3.

The first emission control transistor EMT1 can control the connection of a path through which the driving current flows, and can play a role in controlling an emission of the light emitting device ED.

The first emission control transistor EMT1 is connected between the third node N3 and the fourth node N4, and can control the connection between the third node N3 and the fourth node N4 according to the first emission control signal EM1. The first emission control signal EM1 can be applied to the gate electrode of the first emission control transistor EMT1. The drain electrode or the source electrode of the first emission control transistor EMT1 can be electrically connected to the third node N3. The source electrode or the drain electrode of the first emission control transistor EMT1 can be electrically connected to the fourth node N4.

The first emission control signal EM1 can be a pulse width modulation signal that varies at a predefined time (for example, each frame, or each sub-frame included in one frame).

The first emission control signal EM1 can be generated from the driver DRV or supplied to the driver DRV from a driving-related circuit such as a timing controller.

Referring to FIG. 8, the column driver C-DRV can further include a reference voltage node NREF electrically connected to the first node N1. A reference voltage VREF can be applied to the reference voltage node NREF. Here, the reference voltage VREF can be a gate voltage Vg of the driving transistor DRT.

For example, the reference voltage VREF can have a constant voltage value.

For another example, the reference voltage VREF can have a different voltage value depending on the color of light emitted from the light emitting device ED in which the display-on operation is performed. For example, the reference voltage VREF applied to the first node N1 during the driving period for emitting light of the light emitting device EDa emitting a first color light, the reference voltage VREF applied to the first node N1 during the driving period for emitting light of the light emitting device EDb emitting a second color light, and the reference voltage VREF applied to the first node N1 during the driving period for emitting light of the light emitting device EDc emitting a third color light can have different voltage values.

The column driver C-DRV can further include an initialization voltage node NINT electrically connected to the first node N1 through an initialization switch SW_INT. An initialization voltage VINT can be applied to the initialization voltage node NINT. Here, the initialization voltage VINT can be a gate voltage Vg of the driving transistor DRT.

The column driver C-DRV can further include an initialization buffer BUF_INT connected between the initialization switch SW_INT and the initialization voltage node NINT. The initialization buffer BUF_INT can amplify the initialization voltage VINT applied to the initialization voltage node NINT and supply an amplified initialization voltage to the first node N1.

The column driver C-DRV can further include a pre-charge voltage node NPRC electrically connected to a third node N3 through a pre-charge switch SW_PRC. A pre-charge voltage VPRC can be applied to the pre-charge voltage node NPRC.

The column driver C-DRV can further include a pre-charge buffer BUF_PRC connected between the pre-charge switch SW_PRC and the pre-charge voltage node NPRC. The pre-charge buffer BUF_PRC can amplify the pre-charge voltage VPRC applied to the pre-charge voltage node NPRC and supply the amplified pre-charge voltage to the third node N3.

The column driver C-DRV can further include a reset voltage node NRST electrically connected to a fourth node N4 through a reset switch SW_RST. A reset voltage VRST can be applied to the reset voltage node NRST.

The column driver C-DRV can further include a reset buffer BUF_RST connected between the reset switch SW_RST and the reset voltage node NRST. The reset buffer BUF_RST can amplify the reset voltage VRST applied to the reset voltage node NRST and supply the amplified reset voltage to the fourth node N4. Here, the fourth node N4 can be electrically connected to the corresponding column line CL.

The row driver R-DRV can be configured to drive n row lines RL(1) to RL(n) each connected to the second electrodes Erl(1) to Erl(n) of n light emitting devices ED(1) to ED(n) arranged in the same column.

The row driver R-DRV can include n display-on switches SW_ON(1) to SW_ON(n) that electrically connect each of n row lines RL(1) to RL(n) to a first low-potential voltage node NVSS1. A first low-potential voltage VSS1 can be applied to the first low-potential voltage node NVSS1.

The turn-on timing of each of the n display-on switches SW_ON(1) to SW_ON(n) can be different from each other. Accordingly, display-on driving for the n row lines RL(1) to RL(n) can be sequentially performed.

The row driver R-DRV can include n display-off switches SW_OFF(1) to SW_OFF(n) that electrically connect each of the n row lines RL(1) to RL(n) to a second low-potential voltage node NVSS2 to which a second low-potential voltage VSS2 is applied. The second low-potential voltage VSS2 can be a low-potential voltage higher than the first low-potential voltage VSS1. The row driver R-DRV can further include a second low-potential buffer BUF_VSS2 connected between the n display-off switches SW_OFF(1) to SW_OFF(n) and the second low-potential voltage node NVSS2.

The turn-on timing of each of the n display-off switches SW_OFF(1) to SW_OFF(n) can be different from each other. Accordingly, the display-off driving for the n display-off switches SW_OFF(1) to SW_OFF(n) can be performed at different timings.

According to the example of FIG. 8, the row driver R-DRV can perform display-on driving for the first row line RL(1) among the n row lines RL(1) to RL(n), and perform display-off driving for the second to n-th row lines RL(2) to RL(n).

To this end, among the n display-on switches SW_ON(1) to SW_ON(n), a first display-on switch SW_ON(1) can be in a turn-on state, and a second to n-th display-on switches SW_ON(2) to SW_ON(n) can be in a turn-off state. In addition, among the n display-off switches SW_OFF(1) to SW_OFF(n), the first display-off switch SW_OFF(1) can be in a turn-off state, and the second to n-th display-off switches SW_OFF(2) to SW_OFF(n) can be in a turn-on state.

Accordingly, among the n row lines RL(1) to RL(n), a first low-potential voltage VSS1) can be applied to the first row line RL(1), and a second low-potential voltage VSS2 can be applied to the second to n-th row lines RL(2) to RL(n). Here, the first low-potential voltage VSS1 can have a lower voltage value than the second low-potential voltage VSS2.

Each of the transistors DRT and EMT1 included in the column driver C-DRV can be an n-type transistor or a p-type transistor. The switches SW_ON(1) to SW_ON(n), SW_OFF(1) to SW_OFF(n) included in the row driver R-DRV can be implemented as an n-type transistor or a p-type transistor. The column driver C-DRV can further include at least one capacitor.

All or part of the column driver C-DRV and the row driver R-DRV can be internal circuits included in the driver DRV. As another example, all or part of the column driver C-DRV and the row driver R-DRV can be circuits formed on the substrate 210 of the display panel 110 and not included in the driver DRV.

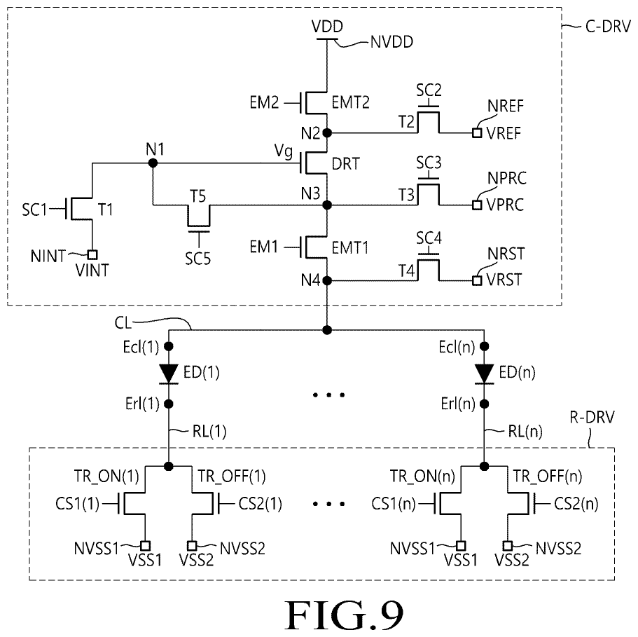

Hereinafter, it will be described the different circuit structures of the column driver C-DRV and the row driver R-DRV with reference to FIG. 9.

FIG. 9 illustrates another circuit for driving n light emitting devices ED(1) to ED(n) connected to one column line CL included in the first sub-driving area SDA1 of the display panel 110 according to the embodiments of the present disclosure. In the following description, the description of the same content as in the circuit of FIG. 8 can be omitted or may be briefly provided.

Referring to FIG. 9, the n light emitting devices ED(1) to ED(n) connected to one column line CL can be arranged in the same column. The n light emitting devices ED(1) to ED(n) arranged in the same column can be connected to one column line CL. The n light emitting devices ED(1) to ED(n) connected to one column line CL can be arranged in one of the first sub-driving area SDA1 and the second sub-driving area SDA2 included in the unit driving area UDA.

The n light emitting devices ED(1) to ED(n) connected to one column line CL can be light emitting devices emitting the same color light. The n light emitting devices ED(1) to ED(n) arranged in the same column can be light emitting devices emitting the same color light.

The n light emitting devices ED(1) to ED(n) arranged in the same column can include first electrodes Ecl(1) to Ecl(n) and second electrodes Erl(1) to Erl(n).

The first electrodes Ecl(1) to Ecl(n) of the n light emitting devices ED(1) to ED(n) arranged in the same column can all be connected to one column line CL. The second electrodes Erl(1) to Erl(n) of the n light emitting devices ED(1) to ED(n) arranged in the same column can be respectively connected to the n row lines RL(1) to RL(n).

A circuit for driving the n light emitting devices ED(1) to ED(n) arranged in the same column can include a column driver C-DRV and a row driver R-DRV.

The column driver C-DRV can include first to fourth nodes N1 to N4, and can include a driving transistor DRT, a first emission control transistor EMT1, and a second emission control transistor EMT2.

The first node N1 can be a node to which a voltage Vg for controlling on-off of the driving transistor DRT is applied. The second node N2 can be a node to which the second emission control transistor EMT2 and the driving transistor DRT are connected. The third node N3 can be a node to which the driving transistor DR and the first emission control transistor EMT1 are connected. The fourth node N4 can be a node to which the first emission control transistor EMT1 and the n light emitting devices ED(1) to ED(n) are electrically connected, and can be a node to which the column line CL is electrically connected. Here, the source electrode or the drain electrode of the first emission control transistor EMT1 and the first electrodes Ecl(1) to Ecl(n) of the n light emitting devices ED(1) to ED(n) can be commonly connected to the column line CL.

The driving transistor DRT supplies a driving current to emit light to n light emitting devices ED(1) to ED(n), is connected between the second node N2 and the third node N3, and can control the connection between the second node N2 and the third node N3 according to the voltage of the first node N1.

The gate electrode of the driving transistor DRT is electrically connected to the first node N1, and can be supplied with a gate voltage Vg. The drain electrode or the source electrode of the driving transistor DRT can be electrically connected to the second node N2. The source electrode or the drain electrode of the driving transistor DRT can be electrically connected to the third node N3.

The first emission control transistor EMT1 and the second emission control transistor EMT2 can control the connection of a path through which a driving current flows, and can play a role in controlling an emission of a light emitting device ED.

The first emission control transistor EMT1 is connected between the third node N3 and the fourth node N4, and can control the connection between the third node N3 and the fourth node N4 according to a first emission control signal EM1. The first emission control signal EM1 can be applied to the gate electrode of the first emission control transistor EMT1. The drain electrode or the source electrode of the first emission control transistor EMT1 can be electrically connected to the third node N3. The source electrode or the drain electrode of the first emission control transistor EMT1 can be electrically connected to the fourth node N4.

The first emission control signal EM1 can be a pulse width modulation signal that varies at a predefined time (for example, each frame, or each sub-frame included in a frame). The first emission control signal EM1 can be generated by the driver DRV, or can be supplied to the driver DRV from a driving-related circuit such as a timing controller.

The second emission control transistor EMT2 is connected between the high-potential voltage node NVDD and the second node N2, and can control the connection between the high-potential voltage node NVDD and the second node N2 according to a second emission control signal EM2. The second emission control signal EM2 can be applied to the gate electrode of the second emission control transistor EMT2. The drain electrode or the source electrode of the second emission control transistor EMT2 can be electrically connected to the high-potential voltage node NVDD. The source electrode or drain electrode of the second emission control transistor EMT2 can be electrically connected to the second node N2. Here, the second emission control signal EM2 can be the same as or different from the first emission control signal EM1.

The column driver DRV can further include a first transistor T1 whose on-off is controlled according to a first scan signal SC1 and controls the connection between the first node N and the initialization voltage node NINT. Here, the initialization voltage VINT can be applied to the initialization voltage node NINT.

The column driver DRV can further include a second transistor T2 whose on-off is controlled according to a second scan signal SC2 and controls the connection between the second node N2 and the reference voltage node NREF. Here, a reference voltage VREF can be applied to the reference voltage node NREF.

The column driver DRV can further include a third transistor T3 whose on-off is controlled according to a third scan signal SC3 and controls the connection between the third node N3 and the pre-charge voltage node NPRC. Here, a pre-charge voltage VPRC can be applied to the pre-charge voltage node NPRC.

The column driver DRV can further include a fourth transistor T4 whose on-off is controlled according to a fourth scan signal SC4 and controls the connection between the fourth node N4 and the reset voltage node NRST. Here, a reset voltage VRST can be applied to the reset voltage node NRST.

The column driver DRV can further include a fifth transistor T5 that controls the connection between the first node N1 and the third node N3 by controlling the on-off according to a fifth scan signal SC5. If the fifth transistor T5 is turned on, the first node N1 and the third node N3 are electrically connected, so that the driving transistor DRT can be in a diode-connected state. Here, for example, the fifth scan signal SC5 can be a scan signal that is different from or the same as the second scan signal SC2.

The row driver R-DRV can be configured to drive n row lines RL(1) to RL(n) that are respectively connected to the second electrodes Erl(1) to Erl(n) of n light emitting devices ED(1) to ED(n) arranged in the same column.

The row driver R-DRV can include n display-on transistors TR_ON(1) to TR_ON(n) that electrically connect each of n row lines RL(1) to RL(n) to a first low-potential voltage node NVSS1. A first low-potential voltage VSS1 can be applied to the first low-potential voltage node NVSS1. The n display-on transistors TR_ON(1) to TR_ON(n) can be turned on and off by n display-on control signals CS1(1) to CS1(n).

The turn-on timing of each of the n display-on transistors TR_ON(1) to TR_ON(n) can be different from each other. Accordingly, display-on driving for the n row lines RL(1) to RL(n) can be sequentially performed.

The row driver R-DRV can include n display-off transistors TR_OFF(1) to TR_OFF(n) that electrically connect each of n row lines RL(1) to RL(n) to a second low-potential voltage node NVSS2 to which a second low-potential voltage VSS2 is applied. The second low-potential voltage VSS2 can be a low-potential voltage higher than the first low-potential voltage VSS1. The n display-off transistors TR_OFF(1) to TR_OFF(n) can be turned on and off by n display-off control signals CS2(1) to CS2(n).

The turn-on timing of each of the n display-off transistors TR_OFF(1) to TR_OFF(n) can be different from each other. Accordingly, display-off driving for n display-off transistors TR_OFF(1) to TR_OFF(n) can be performed at different timings.

For example, one display-on transistor among n display-on transistors TR_ON(1) to TR_ON(n) and one display-off transistor among n display-off transistors TR_OFF(1) to TR_OFF(n) can be connected to each of n row lines RL(1) to RL(n).

Only one of the display-on transistors and display-off transistors connected to each of n row lines RL(1) to RL(n) can be selectively turned on.

For example, if a display-on driving is performed for the first row line RL(1) among the n row lines RL(1) to RL(n), among the first display-on transistor TR_ON(1) and the first display-off transistor TR_OFF(1) connected to the first row line RL(1), the first display-on transistor TR_ON(1) can be turned on and the first display-off transistor TR_OFF(1) can be turned off. At this time, display-off driving is performed for the second to n-th row lines RL(2) to RL(n), that is, among the display-on transistors and display-off transistors connected to each of the second to n-th row lines RL(2) to RL(n), the display-on transistor can be turned off and the display-off transistor can be turned on. Accordingly, a first low-potential voltage VSS1, which is a low-potential voltage for driving the display-on, can be applied only to the first row line RL(1) among the n row lines RL(1) to RL(n), and a second low-potential voltage VSS2, which is a low-potential voltage for driving the display-off, can be applied to the remaining second to n-th row lines RL(2) to RL(n). Referring to FIG. 9, the driving timing of the sub-pixel SP is as follows.

During a first driving period, the first transistor T1 among the first to fifth transistors T1 to T5 can be turned on, and the initialization voltage VINT can be applied to the first node N1. The driving transistor DRT can be turned on by the initialization voltage VINT applied to the first node N1.

Thereafter, during a second driving period, the second transistor T2 can be turned on, and the reference voltage VREF can be applied to the second node N2. In this case, the fifth transistor T5 can also be turned on.

Thereafter, during a third driving period, the third transistor T3 can be turned on, so that the pre-charge voltage VPRC can be applied to the third node N3.

Then, during a fourth driving period, one of the n light emitting devices ED(1) to ED(n) can emit light. During the fourth driving period, the light emitting devices in an emission state connected to a corresponding row line among the n row lines RL(1) to RL(n) can be supplied with the first low-potential voltage VSS1, which is a low-potential voltage for display-on driving, and the light emitting devices in a non-emission state can be supplied with the second low-potential voltage VSS2, which is a low-potential voltage for display-off driving.

To this end, among the n row lines RL(1) to RL(n), the row line on which display-on driving is performed can be supplied with the first low-potential voltage VSS1, and the remaining row lines on which display-off driving is performed can be supplied with the second low-potential voltage VSS2.

Therefore, among the display-on transistor and the display-off transistor connected to the row line where the display-on driving is performed, the display-on transistor can be in a turn-on state and the display-off transistor can be in a turn-off state.

Among the display-on transistor and the display-off transistor connected to the row line where the display-off driving is performed, the display-on transistor can be in a turn-off state and the display-off transistor can be in a turn-on state.

Thereafter, during a fifth driving period, the fourth transistor T4 can be turned on, so that the reset voltage VRST can be applied to the fourth node N4. Accordingly, the column line CL can be reset to the reset voltage VRST. In addition, all of the first electrodes Ecl(1) to Ecl(n) of the n light emitting devices ED(1) to ED(n) connected to the column line CL can be reset to the reset voltage VRST.

The first to fourth scan signals SC1 to SC4 and the first and second emission control signals EM1 and EM2 can be generated by the corresponding driver DRV, or can be supplied to the corresponding driver DRV from a driving-related circuit such as a timing controller.

Each of the transistors DRT and T1 to T5 included in the column driver C-DRV can be an n-type transistor or a p-type transistor. Each of the transistors TR_ON(1) to TR_ON(n), TR_OFF(1) to TR_OFF(n) included in the row driver R-DRV can be an n-type transistor or a p-type transistor. The column driver C-DRV can further include at least one capacitor.

Referring to FIG. 9, all or part of the column driver C-DRV and the row driver R-DRV can be internal circuits included in the driver DRV. As another example, all or part of the column driver C-DRV and the row driver R-DRV can be circuits formed on the substrate 210 of the display panel 110 and not included in the driver DRV.

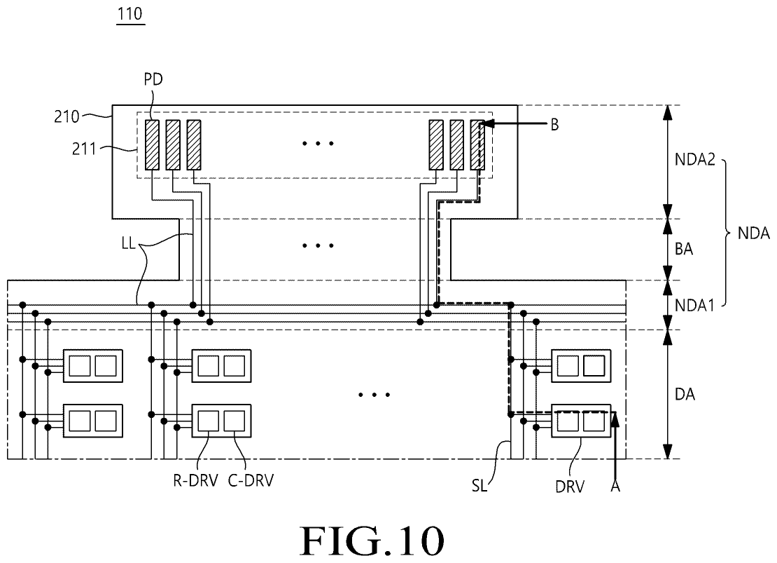

In order for the plurality of drivers DRV included in the display device 100 according to the embodiments of the present disclosure to perform a driving operation, the plurality of drivers DRV are required to be supplied with power required for the driving operation. Accordingly, hereinafter, it will be described a power supply structure for supplying power required for the driving operation to the plurality of drivers DRV with reference to FIG. 10.

FIG. 10 is a plan view of the display panel 110 according to the embodiments of the present disclosure.

Referring to FIG. 10, a substrate 210 of the display panel 110 according to the embodiments of the present disclosure can include a display area DA and a non-display area NDA, and the non-display area NDA can include a first non-display area NDA1, a bending area BA, and a second non-display area NDA2.

A plurality of drivers DRV can be arranged in the display area DA. Each of the plurality of drivers DRV can be a circuit for driving light emitting devices of a plurality of sub-pixels included in a corresponding unit driving area (UDA of FIGS. 4 and 6). Each of the plurality of drivers DRV can include a row driver R-DRV for driving a plurality of row lines and a column driver C-DRV for driving a plurality of column lines, in order to drive a plurality of light emitting devices ED included in a corresponding unit driving area (UDA of FIGS. 4 and 6).

A pad section 211 including a plurality of pads PD can be arranged in the second non-display area NDA2.

A plurality of signal lines SL and a plurality of link lines LL for signal transmission between a plurality of drivers DRV arranged in the display area DA and the pad section 211 can be arranged on the substrate 210. The plurality of signal lines SL can be electrically connected between the plurality of link lines LL and the plurality of drivers DRV. The plurality of link lines LL can electrically connect the plurality of pads PD and the plurality of signal lines SL.

The plurality of link lines LL can be arranged in the non-display area NDA, and all or part of each of the plurality of signal lines SL can be arranged in the display area DA.

Each of the plurality of drivers DRV can receive various signals to perform a driving operation through the plurality of link lines LL and the plurality of signal lines SL. Here, the various signals can include various power voltages and various signals required for the driving operation of each of the plurality of drivers DRV.

As the bending area BA is bent, a portion of the plurality of link lines LL can also be bent. Stress can be concentrated on a portion of the bent link line LL, and thus cracks can occur in the link line LL. Accordingly, the plurality of link lines LL can be formed of a conductive material having excellent ductility to reduce cracks when the bending area BA is bent. For example, the plurality of link lines LL can be formed of a conductive material having excellent ductility, such as gold (Au), silver (Ag), aluminum (Al). In addition, the plurality of link lines LL can be composed of one of various conductive materials used in the display area DA. For example, the plurality of link lines LL can be composed of molybdenum (Mo), chromium (Cr), titanium (Ti), nickel (Ni), neodymium (Nd), copper (Cu), silver (Ag), magnesium (Mg), or an alloy thereof. The plurality of link lines LL can be composed of a multilayer structure including various conductive materials. For example, the plurality of link lines LL can be composed of a triple layer structure of titanium (Ti)/aluminum (Al)/titanium (Ti).

The plurality of link lines LL can be composed of various shapes to reduce stress. At least a portion of the plurality of link lines LL arranged on the bending area BA can extend in the same direction as the extension direction of the bending area BA, or can extend in a direction different from the extension direction of the bending area BA to reduce stress. For example, if the bending area BA extends in one direction from the first non-display area NDA1 toward the second non-display area NDA2, at least a portion of the link lines LL arranged on the bending area BA can extend in a direction oblique to the one direction. As another example, at least a portion of the plurality of link lines LL can be configured as patterns of various shapes. For example, at least a portion of the plurality of link lines LL arranged on the bending area BA can be a pattern in which conductive patterns having at least one shape among a diamond shape, a rhombus shape, a trapezoidal wave shape, a triangular wave shape, a sawtooth wave shape, a sine wave shape, a circular shape, and an omega (Ω) shape are repeatedly arranged. Therefore, in order to minimize the stress concentrated on the plurality of link lines LL and the resulting cracks, the shapes of the plurality of link lines LL can be formed in various shapes including the shapes described above.

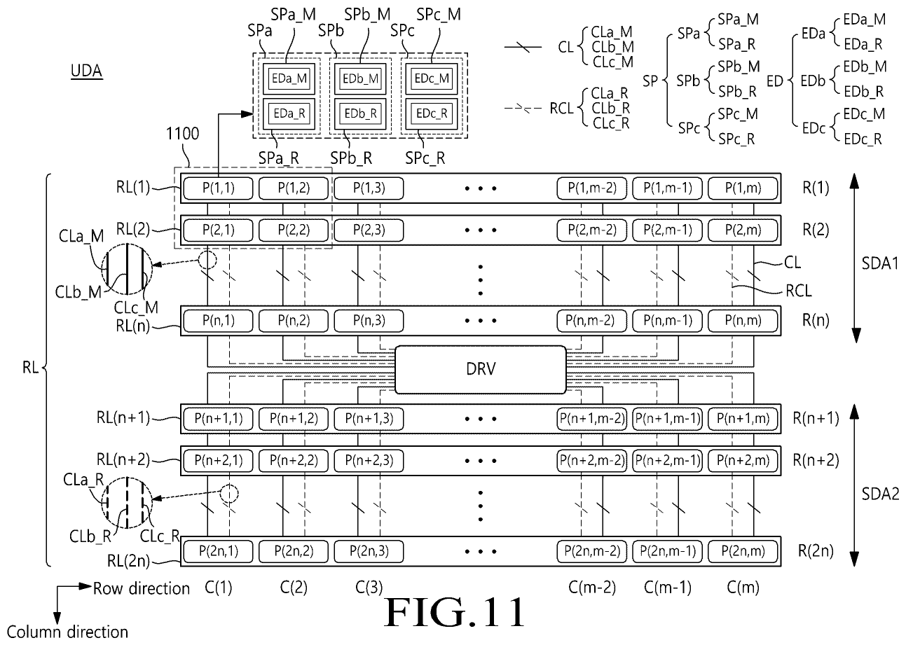

FIG. 11 illustrates a unit driving area UDA of a display panel 110 according to embodiments of the present disclosure. Here, FIG. 3 and FIG. 4 are also referred to in the following description, and the same contents described with reference to FIG. 3 and FIG. 4 can be omitted.

The display panel 110 according to embodiments of the present disclosure can include a plurality of pixels P, a plurality of row lines RL, and a plurality of column lines CL.

According to the example of FIG. 11, the plurality of pixels P can include pixels P(1, 1), . . . , P(1, m), P(2, 1), . . . , P(2, m), . . . , P(2n, 1), . . . , P(2n, m) of (2n×m) pixels arranged in the unit driving area UDA. The plurality of row lines RL can include 2n row lines RL(1) to RL(2n) arranged in the unit driving area UDA.

The display panel 110 according to the embodiments of the present disclosure can include a redundancy structure.

According to the redundancy structure, each of the plurality of pixels P can include k main sub-pixels and k redundancy sub-pixels. Each of the k main sub-pixels can include a main light emitting device, and each of the k redundancy sub-pixels can include a redundancy light emitting device. In other words, each of the plurality of pixels P can include k main light emitting devices EDa_M, EDb_M and EDc_M and k redundancy light emitting devices EDa_R, EDb_R and EDc_R.

Each of the plurality of pixels P(1, 1), . . . , P(1, m), P(2, 1), . . . , P(2, m), . . . , P(2n, 1), . . . , P(2n, m) can include a first sub-pixel SPa, a second sub-pixel SPb, and a third sub-pixel SPc.

The first sub-pixel SPa can include a first main sub-pixel SPa_M and a first redundancy sub-pixel SPa_R. The first main sub-pixel SPa_M can include a first main light emitting device EDa_M, and the first redundancy sub-pixel SPa_R can include a first redundancy light emitting device EDa_R.

The first sub-pixel SPa can include a first light emitting device EDa that emits a first color light, and the first light emitting device EDa can include a first main light emitting device EDa_M and a first redundancy light emitting device EDa_R.

The second sub-pixel SPb can include a second main sub-pixel SPb_M and a second redundancy sub-pixel SPb_R. The second main sub-pixel SPb_M can include a second main light emitting device EDb_M, and the second redundancy sub-pixel SPb_R can include a second redundancy light emitting device EDb_R.

The second sub-pixel SPb can include a second light emitting device EDb that emits second color light, and the second light emitting device EDb can include a second main light emitting device EDb_M and a second redundancy light emitting device EDb_R.

The third sub-pixel SPc can include a third main sub-pixel SPc_M and a third redundancy sub-pixel SPc_R. The third main sub-pixel SPc_M can include a third main light emitting device EDc_M, and the third redundancy sub-pixel SPc_R can include a third redundancy light emitting device EDc_R.

The third sub-pixel SPc can include a third light emitting device EDc that emits a third color light, and the third light emitting device EDc can include a third main light emitting device EDc_M and a third redundancy light emitting device EDc_R.

Referring to FIG. 11, the plurality of column lines CL can include a plurality of main column lines CLa_M, CLb_M and CLc_M and a plurality of redundancy column lines CLa_R, CLb_R and CLc_R.

In each of the plurality of columns (i.e., a plurality of pixel columns) included in each of the first sub-driving area SDA1 and the second sub-driving area SDA2, k main column lines CL (CLa_M, CLb_M and CLc_M), and k redundancy column lines RCL (CLa_R, CLb_R and CLc_R) can be arranged.

In each column (i.e., each pixel column), k main column lines CLa_M, CLb_M and CLc_M) can be connected to the first electrodes Ecl of k main light emitting devices EDa_M, EDb_M and EDc_M.

In each column (i.e., each pixel column), k redundancy column lines CLa_R, CLb_R and CLc_R can be connected to the first electrodes Ecl of k redundancy light emitting devices EDa_R, EDb_R and EDc_R.

Hereinafter, in order to examine the planar structure of the display panel 110 according to the embodiments of the present disclosure in more detail, it will be described the planar structure of a portion 1100 of the planar view of FIG. 11 in more detail as an example.

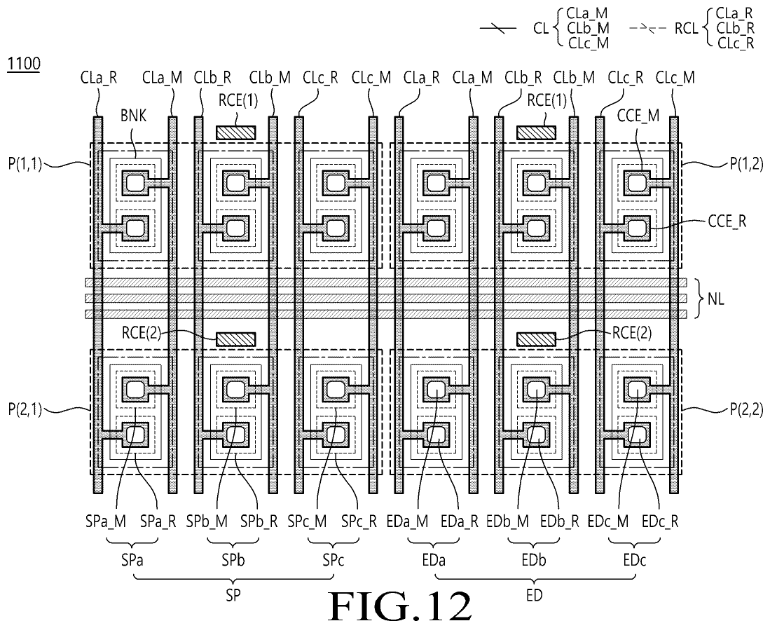

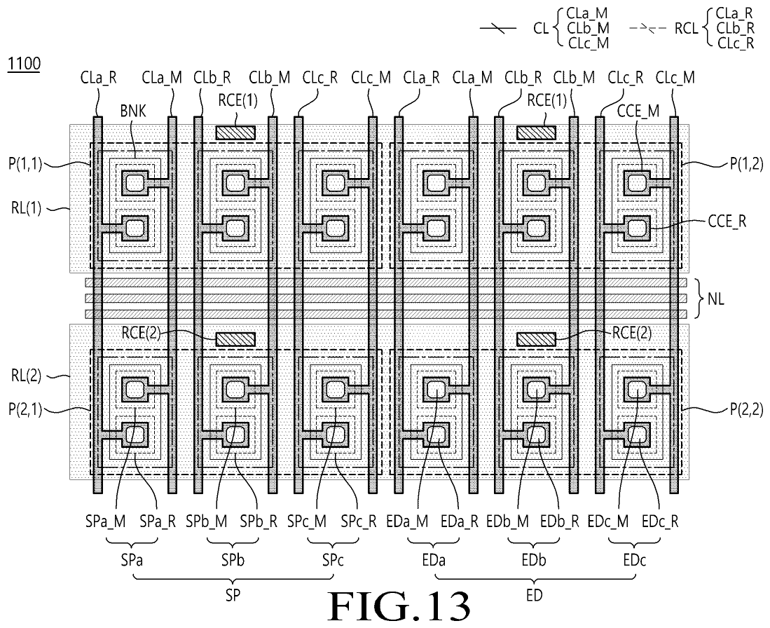

FIG. 12 and FIG. 13 are plan views of a portion 1100 of a display panel 110 according to embodiments of the present disclosure. Particularly, FIG. 12 and FIG. 13 are enlarged plan views of a portion 1100 of the plan view of FIG. 11, and are enlarged plan views of a two-row, two-column area 1100.

For example, FIG. 12 is a plan view that does not represent two row lines RL(1) and RL(2) arranged in a two-row, two-column area 1100, and FIG. 13 is a plan view that adds two row lines RL(1) and RL(2) arranged in a two-row, two-column area 1100 to the plan view of FIG. 12.

Referring to FIG. 12 and FIG. 13, in the two-row, two-column area 1100, four pixels P(1,1), P(1,2), P(2,1), P(2,2) can be arranged in two rows and two columns. For example, in the two-row, two-column area 1100, two pixels P(1,1) and P(1,2) can be arranged in a first row (e.g., a first pixel row), and two pixels P(2,1) and P(2,2) can be arranged in a second row (e.g., a second pixel row). In addition, two pixels P(1,1) and P(2,1) can be arranged in a first column (e.g., a first pixel column), and two pixels P(1,2) and P(2,2) can be arranged in a second column (e.g., a second pixel column).

In the two-row, two-column area 1100, each of the four pixels P(1,1), P(1,2), P(2,1) and P(2,2) arranged in two rows and two columns can include k sub-pixels. Here, k is the number of sub-pixels included in one pixel.

It is exemplified a case where k is 3 is as an example. Accordingly, in the two-row, two-column area 1100, each of the four pixels P(1,1), P(1,2), P(2,1) and P(2,2) arranged in two rows and two columns can include three sub-pixels SPa, SPb and SPc. In the following description, it can be explained assuming the case where k is 3.

The three sub-pixels can include a first sub-pixel SPa including a first light emitting device EDa that emits a first color light, a second sub-pixel SPb including a second light emitting device EDb that emits a second color light, and a third sub-pixel SPc including a third light emitting device EDc that emits a third color light.

If the display panel 110 according to the embodiments of the present disclosure has a redundancy structure, the sub-pixel redundancy structure is as follows.

The first sub-pixel SPa can include a first main sub-pixel SPa_M including a first main light emitting device EDa_M and a first redundancy sub-pixel SPa_R including a first redundancy light emitting device EDa_R, the second sub-pixel SPb can include a second main sub-pixel SPb_M including a second main light emitting device EDb_M and a second redundancy sub-pixel SPb_R including a second redundancy light emitting device EDb_R, and the third sub-pixel SPc can include a third main sub-pixel SPc_M including a third main light emitting device EDc_M and a third redundancy sub-pixel SPc_R including a third redundancy light emitting device EDc_R.

If the display panel 110 according to the embodiments of the present disclosure has a redundancy structure, the light emitting device redundancy structure is as follows.

The first light emitting device EDa can include a first main light emitting device EDa_M that emits a first color light and a first redundancy light emitting device EDa_R that emits a first color light, the second light emitting device EDb can include a second main light emitting device EDb_M that emits a second color light and a second redundancy light emitting device EDb_R that emits a second color light, and the third light emitting device EDb can include a third main light emitting device EDc_M that emits a third color light and a third redundancy light emitting device EDc_R that emits a third color light.

In the two-row, two-column area 1100, a first row line RL(1) and a second row line RL(2) can be arranged. The first row line RL(1) can be arranged in the first row (i.e., the first pixel row), and the second row line RL(2) can be arranged in the second row (i.e., the second pixel row).

The first row line RL(1) can correspond to two pixels P(1,1) and P(1,2) arranged in the first row (or the first pixel row), and can correspond to three sub-pixels SPa, SPb and SPc included in each of the two pixels P(1,1) and P(1,2) arranged in the first row (or the first pixel row).

In terms of the sub-pixel redundancy structure, the first row line RL(1) can be connected to the first main sub-pixel SPa_M, the first redundancy sub-pixel SPa_R, the second main sub-pixel SPb_M, the second redundancy sub-pixel SPb_R, the third main sub-pixel SPc_M, and the third redundancy sub-pixel SPc_R arranged in the first row (or the first pixel row).

At least a portion of the first row line RL(1) can overlap with the first main sub-pixel SPa_M, the first redundancy sub-pixel SPa_R, the second main sub-pixel SPb_M, the second redundancy sub-pixel SPb_R, the third main sub-pixel SPc_M, and the third redundancy sub-pixel SPc_R arranged in the first row (or the first pixel row).

From the perspective of the light emitting device redundancy structure, the first row line RL(1) can be connected to the second electrode Erl of each of the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the first row (or the first pixel row).

At least a part of the first row line RL(1) can overlap with the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the first row (or the first pixel row).

The second row line RL(2) can correspond to two pixels P(2,1) and P(2,2) arranged in a second row (or the second pixel row), and can correspond to three sub-pixels SPa, SPb and SPc included in each of the two pixels P(2,1) and P(2,2) arranged in the second row (or the second pixel row).

In terms of the sub-pixel redundancy structure, the second row line RL(2) can be connected to the first main sub-pixel SPa_M, the first redundancy sub-pixel SPa_R, the second main sub-pixel SPb_M, the second redundancy sub-pixel SPb_R, the third main sub-pixel SPc_M, and the third redundancy sub-pixel SPc_R arranged in the second row (or the second pixel row).

At least a portion of the second row line RL(2) can overlap with the first main sub-pixel SPa_M, the first redundancy sub-pixel SPa_R, the second main sub-pixel SPb_M, the second redundancy sub-pixel SPb_R, the third main sub-pixel SPc_M, and the third redundancy sub-pixel SPc_R arranged in the second row (or the second pixel row).

In terms of the light emitting device redundancy structure, the second row line RL(2) can be connected to the second electrode Erl of each of the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the second row (or the second pixel row).

At least a portion of the second row line RL(2) can overlap with the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the second row (or the second pixel row).

A plurality of column lines CL can be arranged in the two-row two-column area 1100. A plurality of column lines CL arranged in a two-row two-column area 1100 can include a plurality of first column lines CL connected to two pixels P(1,1) and P(2,1) arranged in a first column (or a first pixel column), and a plurality of second column lines CL connected to two pixels P(1,2) and P(2,2) arranged in a second column (or a second pixel column).

From the perspective of sub-pixel redundancy structure, a plurality of first column lines CL arranged in a first column (or first pixel column) can include a first main column line CLa_M that is commonly connected to a first main sub-pixel SPa_M included in each of two pixels P(1,1) and P(2,1) arranged in the first column (or first pixel column), and a first redundancy column line CLa_R that is commonly connected to a first redundancy sub-pixel SPa_R included in each of two pixels P(1,1) and P(2,1) arranged in the first column (or first pixel column).

The first main sub-pixel SPa_M included in each of the two pixels P(1,1) and P(2,1) arranged in the first column (or the first pixel column) can include a first main light emitting device EDa_M, and the first redundancy sub-pixel SPa_R included in each of the two pixels P(1,1) and P(2,1) arranged in the first column (or the first pixel column) can include a first redundancy light emitting device EDa_R.

The first main column line CLa_M arranged in the first column (or the first pixel column) can be commonly connected to the first electrodes Ecl of the two first main light emitting devices EDa_M arranged in the first column (or the first pixel column).

The first redundancy column line CLa_R arranged in the first column (or the first pixel column) can be commonly connected to the first electrodes Ecl of two first redundancy light emitting devices EDa_R arranged in the first column (or the first pixel column).

In addition, the plurality of first column lines CL arranged in the first column (or the first pixel column) can further include a second main column line CLb_M commonly connected to a second main sub-pixel SPb_M included in each of the two pixels P(1,1) and P(2,1) arranged in the first column (or the first pixel column), and a second redundancy column line CLb_R commonly connected to a second redundancy sub-pixel SPb_R included in each of the two pixels P(1,1) and P(2,1) arranged in the first column (or the first pixel column).

The second main sub-pixel SPb_M included in each of the two pixels P(1,1) and P(2,1) arranged in the first column (or the first pixel column) can include a second main light emitting device EDb_M, and the second redundancy sub-pixel SPb_R included in each of the two pixels P(1,1) and P(2,1) arranged in the first column (or the first pixel column) can include a second redundancy light emitting device EDb_R.

The second main column line CLb_M arranged in the first column (or the first pixel column) can be commonly connected to the first electrodes Ecl of the two second main light emitting devices EDb_M arranged in the first column (or the first pixel column).

The second redundancy column line CLb_R arranged in the first column (or the first pixel column) can be commonly connected to the first electrodes Ecl of the two second redundancy light emitting devices EDb_R arranged in the first column (or the first pixel column).

In addition, the plurality of first column lines CL arranged in the first column (or the first pixel column) can further include a third main column line CLc_M commonly connected to the third main sub-pixel SPc_M included in each of the two pixels P(1,1) and P(2,1) arranged in the first column (or the first pixel column), and a third redundancy column line CLc_R commonly connected to the third redundancy sub-pixel SPc_R included in each of the two pixels P(1,1) and P(2,1) arranged in the first column (or the first pixel column).

The third main sub-pixel SPc_M included in each of the two pixels P(1,1) and P(2,1) arranged in the first column (or the first pixel column) can include a third main light emitting device EDc_M, and the third redundancy sub-pixel SPc_R included in each of the two pixels P(1,1) and P(2,1) arranged in the first column (or the first pixel column) can include a third redundancy light emitting device EDc_R.

The third main column line CLc_M arranged in the first column (or the first pixel column) can be commonly connected to the first electrodes Ecl of the two third main light emitting devices EDc_M arranged in the first column (or the first pixel column).

The third redundancy column line CLc_R arranged in the first column (or the first pixel column) can be commonly connected to the first electrodes Ecl of two third redundancy light emitting devices EDc_R arranged in the first column (or the first pixel column).

From the perspective of sub-pixel redundancy structure, a plurality of second column lines CL arranged in a second column (or second pixel column) can include a first main column line CLa_M that is commonly connected to a first main sub-pixel SPa_M included in each of two pixels P(1,2) and P(2,2) arranged in the second column (or second pixel column), and a first redundancy column line CLa_R that is commonly connected to a first redundancy sub-pixel SPa_R included in each of two pixels P(1,2) and P(2,2) arranged in the second column (or second pixel column).

The first main sub-pixel SPa_M included in each of the two pixels P(1,2) and P(2,2) arranged in the second column (or the second pixel column) can include a first main light emitting device EDa_M, and the first redundancy sub-pixel SPa_R included in each of the two pixels P(1,2) and P(2,2) arranged in the second column (or the second pixel column) can include a first redundancy light emitting device EDa_R.

The first main column line CLa_M arranged in the second column (or the second pixel column) can be commonly connected to the first electrodes Ecl of the two first main light emitting devices EDa_M arranged in the second column (or the second pixel column).

The first redundancy column line CLa_R arranged in the second column (or the second pixel column) can be commonly connected to the first electrodes Ecl of the two first redundancy light emitting devices EDa_R arranged in the second column (or the second pixel column).

In addition, the plurality of second column lines CL arranged in the second column (second pixel column) can further include a second main column line CLb_M commonly connected to a second main sub-pixel SPb_M included in each of two pixels P(1,2) and P(2,2) arranged in the second column (or second pixel column), and a second redundancy column line CLb_R commonly connected to a second redundancy sub-pixel SPb_R included in each of two pixels P(1,2) and P(2,2) arranged in the second column (or second pixel column).

The second main sub-pixel SPb_M included in each of the two pixels P(1,2) and P(2,2) arranged in the second column (or the second pixel column) can include a second main light emitting device EDb_M, and the second redundancy sub-pixel SPb_R included in each of the two pixels P(1,2) and P(2,2) arranged in the second column (or the second pixel column) can include a second redundancy light emitting device EDb_R.

The second main column line CLb_M arranged in the second column (or the second pixel column) can be commonly connected to the first electrodes Ecl of the two second main light emitting devices EDb_M arranged in the second column (or the second pixel column).

The second redundancy column line CLb_R arranged in the second column (or the second pixel column) can be commonly connected to the first electrodes Ecl of two second redundancy light emitting devices EDb_R arranged in the second column (or the second pixel column).

In addition, the plurality of second column lines CL arranged in the second column (or the second pixel column) can further include a third main column line CLc_M commonly connected to a third main sub-pixel SPc_M included in each of two pixels P(1,2) and P(2,2) arranged in the second column (or the second pixel column), and a third redundancy column line CLc_R commonly connected to a third redundancy sub-pixel SPc_R included in each of two pixels P(1,2) and P(2,2) arranged in the second column (or the second pixel column).

The third main sub-pixel SPc_M included in each of the two pixels P(1,2) and P(2,2) arranged in the second column (or the second pixel column) can include a third main light emitting device EDc_M, and the third redundancy sub-pixel SPc_R included in each of the two pixels P(1,2) and P(2,2) arranged in the second column (or the second pixel column) can include a third redundancy light emitting device EDc_R.

The third main column line CLc_M arranged in the second column (or the second pixel column) can be commonly connected to the first electrodes Ecl of the two third main light emitting devices EDc_M arranged in the second column (or the second pixel column).

The third redundancy column line CLc_R arranged in the second column (or the second pixel column) can be commonly connected to the first electrodes Ecl of two third redundancy light emitting devices EDc_R arranged in the second column (or the second pixel column).

In each of the first column (or the first pixel column) and the second column (or the second pixel column), each of the plurality of column lines CL can include at least one column connection electrode having a shape protruding above a bank BNK. For example, the at least one column connection electrode can be an electrode electrically connected to each of the plurality of column lines CL or a portion protruding from each of the plurality of column lines CL.

Each of the first main column line CLa_M, the second main column line CLb_M, and the third main column line CLc_M can include a main column connection electrode CCE_M protruding above the bank BNK and extending above the bank BNK.

The first main light emitting devices EDa_M, the second main light emitting devices EDb_M, and the third main light emitting devices EDc_M can be arranged on the main column connection electrodes CCE_M arranged to extend above the bank BNK.

In each of the first column (or first pixel column) and the second column (or second pixel column), each of the first redundancy column line CLa_R, the second redundancy column line CLb_R, and the third redundancy column line CLc_R can include a redundancy column connection electrode CCE_R that protrudes toward the bank BNK and extends above the bank BNK.

On the redundancy column connection electrodes CCE_R arranged to extend above the bank BNK, the first redundancy light emitting devices EDa_R, the second redundancy light emitting devices EDb_R, and the third redundancy light emitting devices EDc_R can be arranged.

The main column connection electrodes CCE_M and the redundancy column connection electrodes CCE_R arranged in the first column (or the first pixel column) can be disposed between the first main column line CLa_M and the first redundancy column line CLa_R.

The main column connection electrodes CCE_M and the redundancy column connection electrodes CCE_R arranged in the second column (or the second pixel column) can be disposed between the second main column line CLb_M and the second redundancy column line CLb_R.

The main column connection electrodes CCE_M and the redundancy column connection electrodes CCE_R arranged in the third column (or the third pixel column) can be disposed between the third main column line CLc_M and the third redundancy column line CLc_R.

The display panel 110 according to the embodiments of the present disclosure can further include at least one row connection electrode for electrically connecting each of the plurality of row lines RL to the driver DRV.

The display panel 110 according to the embodiments of the present disclosure can further include at least one first row connection electrode RCE(1) connected to a first row line RL(1) arranged in a first row (or a first pixel row), and at least one second row connection electrode RCE(2) connected to a second row line RL(2) arranged in a second row (or a second pixel row).

The first row line RL(1) can be vertically overlapped with at least one first row connection electrode RCE(1), and the second row line RL(2) can be vertically overlapped with at least one second row connection electrode RCE(2).

The first row line RL(1) can be electrically connected to the row driver R-DRV of the corresponding driver DRV through at least one first row connection electrode RCE(1). The second row line RL(2) can be electrically connected to the row driver R-DRV of the corresponding driver DRV through at least one second row connection electrode RCE(2).

According to embodiments of the present disclosure, a bank BNK can be arranged in each of a plurality of sub-pixels SP. The plurality of banks BNK can be structures on which a plurality of light emitting devices ED are mounted. When manufacturing a panel, in a transfer process for transferring a plurality of light emitting devices ED to a display device 100, a plurality of banks BNK can guide the positions of the plurality of light emitting devices ED. For example, when manufacturing a panel, a plurality of light emitting devices ED can be transferred onto a plurality of banks BNK in a transfer process of the plurality of light emitting devices ED. The plurality of banks BNK can be an organic insulating layer, a bank pattern, or a structure.

The banks BNK of each of the plurality of sub-pixels SP can be arranged to be spaced apart from each other. The banks BNK of each of the plurality of sub-pixels SP can be configured to be separated from each other. Accordingly, the banks BNK of the first sub-pixel SPa, the second sub-pixel SPb, and the third sub-pixel SPc to which different types of light emitting devices ED are transferred can be easily identified.

The bank BNK of the first main sub-pixel SPa_M and the bank BNK of the first redundancy sub-pixel SPa_R can be connected to each other, or can be formed spaced apart from each other or separately. For example, considering the design of the transfer process requirements, the bank BNK of the first main sub-pixel SPa_M and the bank BNK of the first redundancy sub-pixel SPa_R, in which light emitting devices EDa_M, EDa_R of the same type (for example, types that emit the same color light) are arranged, can be connected to each other, or can be formed spaced apart from each other or separately. In addition, the bank BNK of the second main sub-pixel SPb_M and the bank BNK of the second redundancy sub-pixel SPb_R can be connected to each other, or can be formed spaced apart from each other or separately. The bank BNK of the third main sub-pixel SPc_M and the bank BNK of the third redundancy sub-pixel SPc_R can be connected to each other, or can be formed to be spaced apart from each other or separated from each other.

The bank BNK of the first main sub-pixel SPa_M and the first redundancy sub-pixel SPa_R, the bank BNK of the second main sub-pixel SPb_M and the second redundancy sub-pixel SPb_R, and the bank BNK of the third main sub-pixel SPc_M and the third redundancy sub-pixel SPc_R can be formed in various ways, and the embodiments of the present disclosure are not limited thereto.

For example, the plurality of banks BNK can be formed of an organic insulating material. The plurality of banks BNK can be formed of a single layer or multiple layers of an organic insulating material. For example, the plurality of banks BNK can be composed of a photo resist, a polyimide (PI), or an acrylic material.

The plurality of row lines RL can be formed of a transparent conductive material. The plurality of row lines RL can be composed of a transparent conductive material so that light emitted from the light emitting devices ED can be directed upward through the row lines RL. For example, the plurality of row lines RL can be composed of a transparent conductive material such as indium tin oxide (ITO), indium zinc oxide (IZO), indium gallium zinc oxide (IGZO), and the like.

The plurality of column lines CL can be made of a conductive material. For example, the plurality of column lines CL can be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO). For another example, the plurality of column lines CL can have a multilayer structure of conductive materials. For example, the plurality of column lines CL can be made of a multilayer structure of titanium (Ti)/aluminum (Al)/titanium (Ti)/indium tin oxide (ITO).

For example, if the light emitting device ED is a device manufactured through a semiconductor process, such as a micro LED, a plurality of light emitting devices ED can be formed on a wafer and the light emitting devices ED can be transferred to a substrate 210 of the display panel 110 to manufacture the display panel 110. In the process of transferring a plurality of light emitting devices ED having a microscopic size from the wafer to the substrate 210, various defects can occur. For example, a non-transfer defect can occur in which the light emitting device ED is not transferred in some sub-pixels SP, and a misalignment defect can occur in which the light emitting device ED is transferred out of its proper position due to an alignment error in other sub-pixels SP. In addition, the transfer process can proceed normally, but the transferred light emitting device ED itself can have a defect. Therefore, considering the defects (including non-transfer defects) that occur during the transfer process of the light emitting devices ED, the main light emitting device and the redundancy light emitting device, which are light emitting devices of the same type (e.g., light emitting devices that emit light of the same color), can be transferred to one sub-pixel SP. A lighting test can be performed on the main light emitting device and the redundancy light emitting device of the same type, and it is possible to utilize only one of the main light emitting device and the redundancy light emitting device that is finally determined to be normal.

For example, the first main light emitting device EDa_M and the first redundancy light emitting device EDa_R can be transferred together to one first sub-pixel SPa, and the first main light emitting device EDa_M and the first redundancy light emitting device EDa_R can be inspected for defects. If, as a result of the inspection, both the first main light emitting device EDa_M and the first redundancy light emitting device EDa_R are determined to be normal, only the first main light emitting device EDa_M can be used, and the first redundancy light emitting device EDa_R can be not used. If, as a result of the inspection, only the first redundancy light emitting device EDa_R among the first main light emitting device EDa_M and the first redundancy light emitting device EDa_R is normal, the first main light emitting device EDa_M is not used, and only the first redundancy light emitting device EDa_R can be used. Accordingly, even if the same first main light emitting device EDa_M and the first redundancy light emitting device EDa_R are transferred to one first sub-pixel SPa, only one of the first main light emitting device EDa_M and the first redundancy light emitting device EDa_R can be used finally.

Accordingly, among the main light emitting device and the redundancy light emitting device arranged in one sub-pixel SP, the redundancy light emitting device can be a spare light emitting device transferred in preparation for a failure of the main light emitting device. In the event of a failure of the main light emitting device, the redundancy light emitting device can be used as a replacement. Therefore, by transferring the main light emitting device and the redundancy light emitting device together to one sub-pixel SP, it is possible to minimize the deterioration of display quality due to a defect in one of the main light emitting device and the redundancy light emitting device.

In the embodiments of the present disclosure, the first main sub-pixel SPa_M and the first redundancy sub-pixel SPa_R can also be referred to as a 1-1 sub-pixel and a 1-2 sub-pixel, respectively, the second main sub-pixel SPb_M and the second redundancy sub-pixel SPb_R can also be referred to as a 2-1 sub-pixel and a 2-2 sub-pixel, and the third main sub-pixel SPc_M and the third redundancy sub-pixel SPc_R can also be referred to as a 3-1 sub-pixel and a 3-2 sub-pixel, respectively.

In the embodiments of the present disclosure, the first main light emitting device EDa_M and the first redundancy light emitting device EDa_R can also be referred to as a 1-1 light emitting device and a 1-2 light emitting device, the second main light emitting device EDb_M and the second redundancy light emitting device EDb_R can also be referred to as a 2-1 light emitting device and a 2-2 light emitting device, and the third main light emitting device EDc_M and the third redundancy light emitting device EDc_R can also be referred to as a 3-1 light emitting device and a 3-2 light emitting device.

The display panel 110 according to the embodiments of the present disclosure can further include a plurality of communication lines NL. The plurality of communication lines NL can be arranged so as not to overlap with the metal layer in a vertical direction. For example, a plurality of communication lines NL can be arranged between a first row line RL(1) and a second row line RL(2).

For example, the plurality of communication lines NL can be wires for short-range communication such as NFC (Near Field Communication) and Bluetooth. The plurality of communication lines NL can serve as signal transmission wires and/or antennas.

The first row line RL(1) can be arranged above a plurality of light emitting devices arranged in the first row (or the first pixel row) and can be arranged in a bar shape overlapping with all of the plurality of light emitting devices arranged in the first row (or the first pixel row).

The second row line RL(2) can be arranged above the plurality of light emitting devices arranged in the second row (or the second pixel row), and can be arranged in a bar shape overlapping with all of the plurality of light emitting devices arranged in the second row (or the second pixel row).

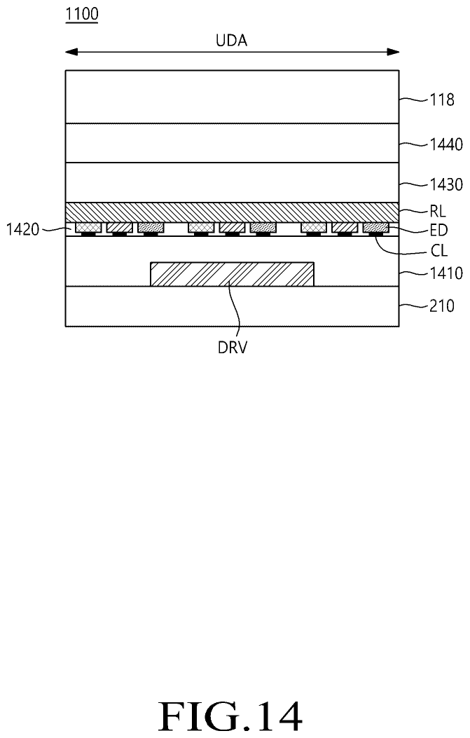

FIG. 14 is a cross-sectional view of a display panel 110 according to embodiments of the present disclosure. However, FIG. 14 is a cross-sectional view of a portion of a unit driving area UDA in which one driver DRV is arranged.

Referring to FIG. 14, a display panel 110 according to embodiments of the present disclosure can include a substrate 210, a driver DRV on the substrate 210, a layer stack 1410 on the driver DRV, a plurality of light emitting devices ED disposed on the layer stack 1410, an optical layer 1420 disposed on the layer stack 1410 and between the plurality of light emitting devices ED, an overcoat layer 1430 disposed on the plurality of light emitting devices ED and the optical layer 1420, an adhesive layer 1440 disposed on the overcoat layer 1430, and a cover member 118 disposed on the adhesive layer 1440.

A plurality of column lines CL can be arranged on a layer stack 1410. Each of the plurality of column lines CL can be arranged between the layer stack 1410 and a light emitting device ED. A plurality of row lines RL can be arranged on a plurality of light emitting devices ED and an optical layer 1420.

A display panel 110 according to embodiments of the present disclosure can include a substrate 210 including a display area DA, a plurality of light emitting devices ED arranged in the display area DA, a plurality of column lines CL electrically connected to first electrodes Ecl of each of the plurality of light emitting devices ED, a plurality of row lines RL electrically connected to second electrodes Erl of each of the plurality of light emitting devices ED, and a plurality of drivers DRV configured to drive the plurality of light emitting devices ED, the plurality of column lines CL, and the plurality of row lines RL.

A plurality of drivers DRV can be arranged in the display area DA, and can be positioned closer to the substrate 210 than the plurality of light emitting devices ED.

The layer stack 1410 can include a plurality of insulating layers. The plurality of insulating layers can include a plurality of organic layers. At least one of the plurality of organic layers can be arranged on a side of the driver DRV. For example, two or more organic layers can be arranged on a side of the driver DRV.

The layer stack 1410 can further include at least one metal layer connecting the driver DRV and the column line CL, and at least one metal layer connecting the driver DRV and the row line RL.

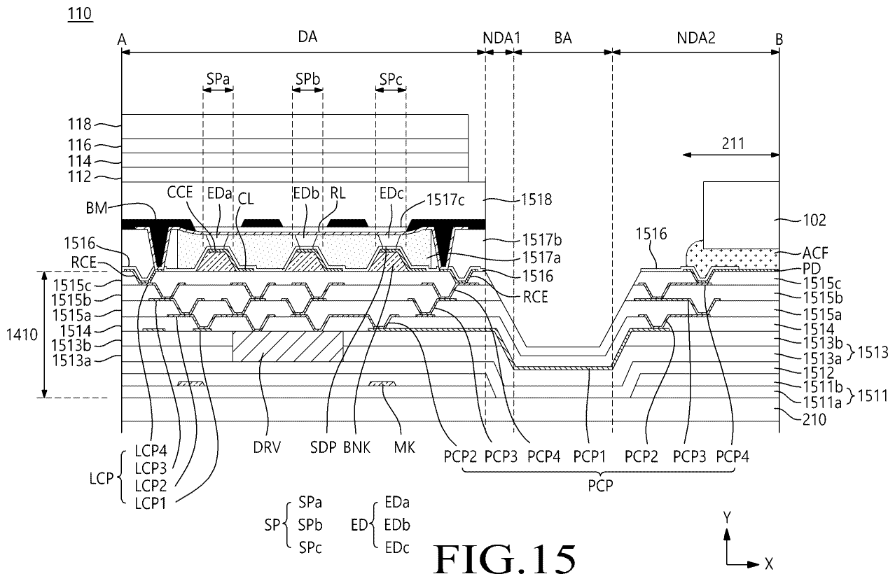

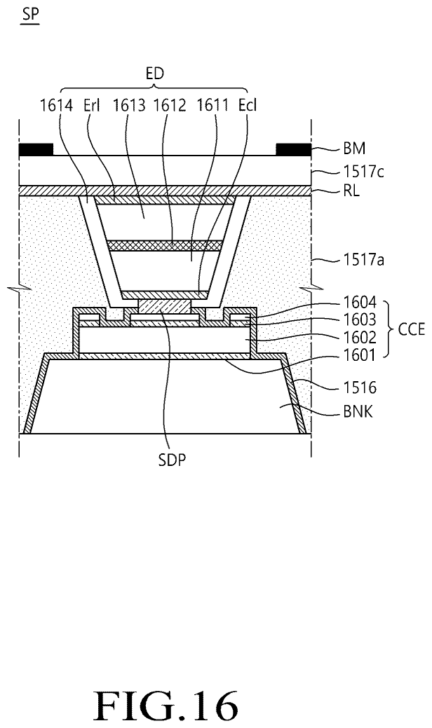

FIG. 15 is a detailed cross-sectional view of a display panel 110 according to embodiments of the present disclosure taken along the A-B cutting line of FIG. 10, and FIG. 16 is an enlarged cross-sectional view of a sub-pixel SP of a display panel 110 according to embodiments of the present disclosure. However, FIG. 15 is a cross-sectional view of a display area DA, a first non-display area NDA, a bending area BA, and a second non-display area NDA.

Meanwhile, for convenience of illustration, the A-B cutting line in FIG. 10 is illustrated as not overlapping with a signal line SL and a link line LL, but the A-B cutting line in FIG. 10 is intended to indicate the same position as the adjacent signal line SL and the link line LL.

Referring to FIG. 15, a buffer layer 1511 can be included on the substrate 210. The buffer layer 1511 can include a first buffer layer 1511a and a second buffer layer 1511b. The first buffer layer 1511a and the second buffer layer 1511b can be arranged in the display area DA, the first non-display area NDA1, and the second non-display area NDA, and may not be arranged in the entirety or part of the bending area BA. However, the present disclosure is not limited thereto.

The first buffer layer 1511a and the second buffer layer 1511b can reduce the penetration of moisture or impurities through the substrate 210. The first buffer layer 1511a and the second buffer layer 1511b can be made of an inorganic insulating material. For example, the first buffer layer 1511a and the second buffer layer 1511b can be composed of a single layer or multiple layers of silicon oxide (SiOx) or silicon nitride (SiNx).

For example, a portion of the first buffer layer 1511a and the second buffer layer 1511b on the bending area BA can be removed. The upper surface of the substrate 210 located on the bending area BA can be exposed by the area (e.g., opening) where the first buffer layer 1511a and the second buffer layer 1511b are removed.

By removing the first buffer layer 1511a and the second buffer layer 1511b from the bending area BA, it is possible to minimize an occurrence of cracks in the first buffer layer 1511a and the second buffer layer 1511b that can occur during bending.

A plurality of alignment keys MK can be arranged between the first buffer layer 1511a and the second buffer layer 1511b. The plurality of alignment keys MK can be configured to identify the position of the driver DRV during the manufacturing process of the display panel 110. For example, the plurality of alignment keys MK can be configured to align the position of the driver DRV transferred on the adhesive layer 1512. In another example, the plurality of alignment keys MK can be omitted.

An adhesive layer 1512 can be disposed on the second buffer layer 1511b. The adhesive layer 1512 can be disposed in the display area DA, the first non-display area NDA1, the bending area BA, and the second non-display area NDA2. For another example, at least a portion of the adhesive layer 1512 can be removed in the non-display area NDA including the bending area BA. For example, the adhesive layer 1512 can be made of any one of an adhesive polymer, an epoxy resin, a UV-curable resin, a polyimide series, an acrylate series, a urethane series, and a polydimethylsiloxane (PDMS).

A driver DRV can be disposed on the adhesive layer 1512 in the display area DA. If the driver DRV is implemented as a driving chip (e.g., driver integrated circuit), the driving driver can be mounted on the adhesive layer 1512 by a transfer process.

The display panel 110 can further include a side protection layer 1513 disposed on the side of the plurality of drivers DRV, and an upper protection layer 1514 disposed on the plurality of drivers DRV and the side protection layer 1513. For example, the side protection layer 1513 can include at least one of a first protection layer 1513a and a second protection layer 1513b disposed on the side of the plurality of drivers DRV, and in some cases, can further include at least one additional protection layer. The first protection layer 1513a and the second protection layer 1513b can be disposed on the adhesive layer 1512. The first protection layer 1513a and the second protection layer 1513b can be arranged to surround the side surface of the driver DRV. For example, the second protection layer 1513b can be arranged to cover at least a portion of the upper surface of the driver DRV. For example, at least one of the first protection layer 1513a and the second protection layer 1513b arranged on the bending area BA can be omitted. For example, the first protection layer 1513a can be arranged entirely on the display area DA and the non-display area NDA, and the second protection layer 1513b can be partially arranged on the display area DA, the first non-display area NDA1, and the second non-display area NDA2. For example, at least a portion of the second protection layer 1513b can be removed in all or part of the bending area BA. However, the embodiments of the present disclosure are not limited thereto.

For example, the side protection layer 1513 including at least one of the first protection layer 1513a and the second protection layer 1513b can be composed of an organic insulating material (i.e., organic layer). For example, the first protection layer 1513a and the second protection layer 1513b can be composed of a photo resist, a polyimide (PI), or a photo acryl-based material. For example, the first protection layer 1513a and the second protection layer 1513b can be an overcoating layer or an insulating layer.

According to embodiments of the present disclosure, in the display area DA, a plurality of line connection patterns LCP can be arranged on the second protection layer 1513b. The plurality of line connection patterns LCP can be wiring for electrically connecting the driver DRV to other components. For example, the driver DRV can be electrically connected to a plurality of column lines CL, a plurality of row lines RL, and a plurality of row connection electrodes RCE through the plurality of line connection patterns LCP.

For example, the plurality of line connection patterns LCP can include a first line connection pattern LCP1, a second line connection pattern LCP2, a third line connection pattern LCP3, and a fourth line connection pattern LCP4. For example, the first line connection pattern LCP1, the second line connection pattern LCP2, the third line connection pattern LCP3, and the fourth line connection pattern LCP4 can be arranged in different metal layers.

For example, a plurality of first line connection patterns LCP1 can be arranged on the second protection layer 1513b. The plurality of first line connection patterns LCP1 can be electrically connected to the driver DRV. The plurality of first line connection patterns LCP1 can transmit the voltage output from the driver DRV to the column line CL or the row line RL.

The display panel 110 can further include a side protection layer 1513 including at least one of the first protection layer 1513a and the second protection layer 1513b, and an upper protection layer 1514 arranged on the plurality of drivers DRV. For example, the upper protection layer 1514 can include a third protection layer 1514, and in some cases, can further include at least one additional protection layer. The third protection layer 1514 can be disposed on the second protection layer 1513b and the plurality of first line connection patterns LCP1. The third protection layer 1514 can be disposed entirely in the display area DA and the non-display area NDA. In the bending area BA, the third protection layer 1514 can cover or enclose the side surface of the second protection layer 1513b and the upper surface of the first protection layer 1513a.

For example, the third protection layer 1514 can be composed of an organic insulating material. For example, the third protection layer 1514 can be composed of a photo resist, a polyimide (PI), or a photo acryl-based material. For example, the first protection layer 1513a, the second protection layer 1513b, and the third protection layer 1514 can be composed of the same insulating material, or at least one of the first protection layer 1513a, the second protection layer 1513, and the third protection layer 1514 can be composed of a different insulating material from the rest.

A plurality of second line connection patterns LCP2 can be arranged on the third protection layer 1514. The plurality of second line connection patterns LCP2 can be electrically connected or directly connected to the driver DRV. For example, some of the second line connection patterns LCP2 can be directly or indirectly connected to the driver DRV through contact holes of the third protection layer 1514. Other parts of the second line connection patterns LCP2 can be electrically connected to the first line connection pattern LCP1 through contact holes of the third protection layer 1514. However, the embodiments of the present disclosure are not limited thereto. The voltage output from the driver DRV can be transmitted to the column line CL or the row line RL through the plurality of second line connection patterns LCP2 and other connection patterns.

A first insulating layer 1515a can be disposed on the plurality of second line connection patterns LCP2. The first insulating layer 1515a can be disposed entirely over the display area DA and the non-display area NDA. The first insulating layer 1515a can be composed of an organic insulating material. For example, the first insulating layer 1515a can be composed of a photo resist, a polyimide (PI), or a photo acryl-based material.

A plurality of third line connection patterns LCP3 can be disposed on the first insulating layer 1515a. The plurality of third line connection patterns LCP3 can be electrically connected to the plurality of second line connection patterns LCP2. For example, the third line connection pattern LCP3 can be electrically connected to the second line connection pattern LCP2 through a contact hole of the first insulating layer 1515a.

A second insulating layer 1515b can be disposed on a plurality of third line connection patterns LCP3. The second insulating layer 1515b can be disposed in the display area DA, the first non-display area NDA1, and the second non-display area NDA2, and may not be disposed in the entirety or part of the bending area BA. For example, the second insulating layer 1515b can be removed from the entirety or part of the bending area BA. The second insulating layer 1515b can be composed of an organic insulating material. For example, the second insulating layer 1515b can be composed of a photo resist, a polyimide (PI), or a photo acryl-based material.

A plurality of fourth line connection patterns LCP4 can be arranged on the second insulating layer 1515b. The plurality of fourth line connection patterns LCP4 can be electrically connected to a plurality of third line connection patterns LCP3. For example, the fourth line connection patterns LCP4 can be electrically connected to the third line connection patterns LCP3 through a contact hole of the second insulating layer 1515b.

Referring to FIG. 15, according to the embodiments of the present disclosure, in the non-display area NDA, a plurality of pad connection patterns PCP can be arranged on the second protection layer 1513b. A plurality of pad connection patterns PCP can be wiring for transmitting a signal transmitted from a flexible printed circuit 102 to a pad section 211 to a driver DRV of a display area DA. For example, a plurality of pad connection patterns PCP can be electrically connected to a plurality of pads PD and can receive signals from the flexible printed circuit 102 through the plurality of pads PD. The flexible printed circuit 102 can be connected to a printed circuit board 104 (see FIGS. 1 and 2).

For example, a plurality of pad connection patterns PCP can extend from the pad section 211 toward the display area DA and transmit signals to the wiring of the display area DA. In this case, a plurality of pad connection patterns PCP can function as link line LL (see FIG. 10). The plurality of pad connection patterns PCP can include a first pad connection pattern PCP1, a second pad connection pattern PCP2, a third pad connection pattern PCP3, and a fourth pad connection pattern PCP4.

The plurality of first pad connection patterns PCP1 can be arranged on the second protection layer 1513b. Each of the plurality of first pad connection patterns PCP1 can be arranged across the second non-display area NDA2, the bending area BA, and the first non-display area NDA1. Each of the plurality of first pad connection patterns PCP1 can include a first portion arranged in the bending area BA, a second portion extending from the first portion to the first non-display area NDA1, and a third portion extending from the first portion to the second non-display area NDA2. Each of the plurality of first pad connection patterns PCP1 can extend from the first non-display area NDA1 to a portion of the display area DA. The plurality of first pad connection patterns PCP1 can transmit a signal transmitted from the flexible printed circuit 102 to the pad portion 211 to the driver DRV of the display area DA.

Each of the plurality of first pad connection patterns PCP1 can be electrically connected to the pad PD of the pad section 211 through connection patterns arranged in the second non-display area NDA2. Here, the connection patterns electrically connecting each of the plurality of first pad connection patterns PCP1 to the pad PD can include at least one of the second pad connection pattern PCP2, the third pad connection pattern PCP3, and the fourth pad connection pattern PCP4 arranged in the second non-display area NDA2.

Each of the plurality of first pad connection patterns PCP1 can be electrically connected to the driver DRV through connection patterns arranged in the display area DA. Here, the connection patterns electrically connecting each of the plurality of first pad connection patterns PCP1 to the driver DRV can include at least one of the second pad connection pattern PCP2, the third pad connection pattern PCP3, and the fourth pad connection pattern PCP4 arranged in the display area DA.

The plurality of second pad connection patterns PCP2 can be arranged on the third protection layer 1514. The plurality of second pad connection patterns PCP2 can be arranged in the second non-display area NDA2. The second pad connection pattern PCP2 can be electrically connected to the first pad connection pattern PCP1 through a contact hole of the third protection layer 1514. Therefore, the signal supplied from the flexible printed circuit 102 can be transmitted to the first pad connection pattern PCP1 through the second pad connection pattern PCP2.

The third pad connection pattern PCP3 can be arranged on the first insulating layer 1515a. The third pad connection pattern PCP3 can be arranged in the second non-display area NDA2. The third pad connection pattern PCP3 can be electrically connected to the second pad connection pattern PCP2 through a contact hole of the first insulating layer 1515a. Therefore, the signal supplied from the flexible printed circuit 102 can be transmitted to the second pad connection pattern PCP2 through the third pad connection pattern PCP3, and the signal transmitted to the second pad connection pattern PCP2 can be transmitted again to the first pad connection pattern PCP1.

The fourth pad connection pattern PCP4 can be arranged on the second insulating layer 1515b. The fourth pad connection patternPCP4 can be arranged in the second non-display area NDA2. The fourth pad connection pattern PCP4 can be electrically connected to the third pad connection pattern PCP3 through a contact hole of the second insulating layer 1515b. The pad PD of the pad section 211 can be electrically connected to the fourth pad connection pattern PCP4 through a contact hole of the third insulating layer 1515c.

A signal supplied from a flexible printed circuit 102 is input to a pad PD of a pad section 211, and a signal input to the pad PD is transmitted to a third pad connection pattern PCP3 through a fourth pad connection pattern PCP4, and a signal transmitted to the third pad connection pattern PCP3 can be transmitted again to a first pad connection pattern PCP1 through a second pad connection pattern PCP2. A signal transmitted to the first pad connection pattern PCP1 can be transmitted to a driver DRV through connection patterns arranged in a display area DA.

Referring to FIG. 15, a plurality of line connection patterns LCP and a plurality of pad connection patterns PCP can be arranged in various metal layers. The plurality of line connection patterns LCP and the plurality of pad connection patterns PCP can be formed of a conductive material having excellent ductility or any one of various conductive materials used in a display area DA.

For example, a metal pattern such as a first pad connection pattern PCP1 at least partially disposed in the bending area BA can be composed of a conductive material having excellent ductility, such as gold (Au), silver (Ag), or aluminum (Al). For another example, the plurality of line connection patterns LCP and the plurality of pad connection patterns PCP can be composed of molybdenum (Mo), chromium (Cr), titanium (Ti), nickel (Ni), neodymium (Nd), copper (Cu), silver (Ag), magnesium (Mg), or an alloy thereof.

A third insulating layer 1515c can be disposed on the plurality of line connection patterns LCP and the plurality of pad connection patterns PCP. The third insulating layer 1515c is disposed in the display area DA, the first non-display area NDA1, and the second non-display area NDA2, and can be disposed in all or part of the bending area BA. In the bending area BA, a part of the third insulating layer 1515c can be removed. The third insulating layer 1515c can be composed of an organic insulating material. For example, the third insulating layer 1515c can be composed of a photo resist, a polyimide (PI), or a photo acryl-based material.

A plurality of banks BNK can be disposed on the third insulating layer 1515c in the display area DA. The plurality of banks BNKs can be arranged to overlap with at least a portion of each of the plurality of sub-pixels SPa, SPb and SPc. For example, the first sub-pixel SPa can include a first light emitting device EDa that emits a first color light, the second sub-pixel SPb can include a second light emitting device EDb that emits a second color light, and the third sub-pixel SPc can include a third light emitting device EDc that emits a third color light.

As an example, one light emitting device ED can be arranged on top of each of the plurality of banks BNK. As another example, two or more light emitting devices ED can be arranged on top of each of the plurality of banks BNK. The two or more light emitting devices EDs arranged on top of each of the plurality of banks BNK can be light emitting devices of the same type. For example, the light emitting devices of the same type can be light emitting devices that emit the same color light. For example, the two or more light emitting devices ED arranged on top of each of the plurality of banks BNK can include a main light emitting device and a redundancy light emitting device.

In the display area DA, a plurality of row connection electrodes RCE can be arranged on the third insulating layer 1515c. The plurality of row connection electrodes RCE can transfer a low-potential voltage VSS output from the driver DRV to the row line RL.

In the display area DA, a plurality of column lines CL can be arranged on the third insulating layer 1515c. The plurality of column lines CL can be arranged in an area between the plurality of banks BNK. For example, the plurality of column lines CL can be arranged adjacent to one of the plurality of banks BNK.

Each of the plurality of column lines CL can include a wiring portion and a column connection electrode CCE protruding from the wiring portion. The wiring portion and the column connection electrode CCE included in each of the plurality of column lines CL can be formed integrally or can be different metals that are electrically connected.

For example, each of the plurality of column lines CL can include a column connection electrode CCE that is a portion protruding above an adjacent bank BNK among the plurality of banks BNK. The column connection electrode CCE of each of the plurality of column lines CL can be arranged to extend along the side and upper surface of the bank BNK. The column connection electrode CCE can be an electrode electrically connected to each of the plurality of column lines CL or can be a portion protruding from each of the plurality of column lines CL.

Referring to FIG. 16, the column connection electrode CCE of the column line CL can be composed of one conductive layer or multiple conductive layers. For example, a column connection electrode CCE electrically connected to a column line CL or protruding from the column line CL can include a first conductive layer 1601, a second conductive layer 1602, a third conductive layer 1603, and a fourth conductive layer 1604.

The first conductive layer 1601 can be disposed on a bank BNK. The second conductive layer 1602 can be disposed on the first conductive layer 1601. The third conductive layer 1603 can be disposed on the second conductive layer 1602, and the fourth conductive layer 1604 can be disposed on the third conductive layer 1603. For example, each of the first conductive layer 1601, the second conductive layer 1602, the third conductive layer 1603, and the fourth conductive layer 1604 can be composed of titanium (Ti), molybdenum (Mo), aluminum (Al), or titanium (Ti) and indium tin oxide (ITO).

According to the embodiments of the present disclosure, among the plurality of conductive layers constituting the column connection electrode CCE, some conductive layers having good reflection efficiency can be configured as an alignment key and/or a reflector for aligning the light emitting devices ED. For example, among the plurality of conductive layers constituting the column connection electrode CCE, the second conductive layer 1602 can include a reflective material. For example, the second conductive layer 1602 can include aluminum (Al). Accordingly, the second conductive layer 1602 can be configured as a reflector. In addition, due to the high reflection efficiency of the second conductive layer 1602, it can be easily identified in the manufacturing process, and thus the position or transfer position of the light emitting device ED can be aligned based on the second conductive layer 1602.

For example, in order to configure the second conductive layer 1602 as a reflector, the third conductive layer 1603 and the fourth conductive layer 1604 disposed on the second conductive layer 1602 can be partially removed or etched. For example, a portion of the third conductive layer 1603 and the fourth conductive layer 1604 disposed on the bank BNK can be removed or etched to expose the upper surface of the second conductive layer 1602. For example, the openings of the third conductive layer 1603 and the fourth conductive layer 1604 can overlap with a portion of the upper surface of the second conductive layer 1602. For example, in the third conductive layer 1603 and the fourth conductive layer 1604, the central portion and the edge portion where a solder pattern SDP is arranged can remain, and the remaining portions excluding this portion (e.g., the central portion, the edge portion) can be removed. For example, the edge portion of each of the third conductive layer 1603 made of titanium (Ti) and the fourth conductive layer 1604 made of indium tin oxide (ITO) may not be etched. Accordingly, it is possible to prevent other conductive layers of the column connection electrode CCE of the column line CL from being corroded by the TMAH (Tetra Methyl Ammonium Hydroxide) solution used in the mask process of the column connection electrode CCE.

According to the embodiments of the present disclosure, the first conductive layer 1601 and the third conductive layer 1603 can include titanium (Ti) or molybdenum (Mo). The second conductive layer 1602 can include aluminum (Al). The fourth conductive layer 1604 can include a transparent conductive oxide layer such as indium tin oxide (ITO) or indium zinc oxide (IZO) that has good adhesion to the solder pattern SDP and corrosion resistance and acid resistance. However, the embodiments of the present disclosure are not limited thereto.

The first conductive layer 1601, the second conductive layer 1602, the third conductive layer 1603, and the fourth conductive layer 1604 can be sequentially deposited and then patterned by performing a photolithography process and an etching process.

According to embodiments of the present disclosure, two or more of the column connection electrode CCE, the column line CL, the row connection electrode RCE, and the pad PD can be arranged on the same layer. The column connection electrode CCE, the column line CL, the row connection electrode RCE, and the pad PD can be composed of a single layer or multiple layers of a conductive material. For example, two or more of the column connection electrode CCE, the column line CL, the row connection electrode RCE, and the pad PD can be composed of a multiple layer of indium tin oxide (ITO)/titanium (Ti)/aluminum (Al)/titanium (Ti).

According to embodiments of the present disclosure, a solder pattern SDP can be arranged on the column connection electrode CCE in each of a plurality of sub-pixels. The solder pattern SDP can bond the light emitting device ED to the column connection electrode CCE. The column connection electrode CCE and the light emitting device ED can be electrically connected through eutectic bonding using the solder pattern SDP. For example, if the solder pattern SDP is composed of indium (In) and the first electrode Ecl of the light emitting device ED is composed of gold (Au), the solder pattern SDP and the first electrode Ecl of the light emitting device ED can be bonded by applying heat and pressure in a transfer process of the light emitting device ED. Through eutectic bonding, the light emitting device ED can be bonded to the solder pattern SDP and the column connection electrode CCE without a separate adhesive. For example, the solder pattern SDP can be composed of indium (In), tin (Sn), or an alloy thereof. For example, the solder pattern SDP can be a bonding pad.

According to the embodiments of the present disclosure, the passivation layer 1516 can be disposed on a plurality of column lines CL, a plurality of column connection electrodes CCE, a plurality of row connection electrodes RCE, and a third insulating layer 1515c.

For example, the passivation layer 1516 can be disposed on a display area DA, a first non-display area NDA1, and a second non-display area NDA2. In the entirety or a portion of the bending area BA, at least a portion of the passivation layer 1516 covering the plurality of pads PD can be removed. A portion of the passivation layer 1516 covering the plurality of pads PD in the second non-display area NDA2 can be removed. In addition, as illustrated in FIG. 16, the passivation layer 1516 can be removed from the area where the solder pattern SDP is arranged.

Since the passivation layer 1516 is arranged to cover the remaining area except for the bending area BA, the plurality of pad PD, and the area where the solder pattern SDP is arranged, the penetration of moisture or impurities into the light emitting device ED can be reduced. For example, the passivation layer 1516 can be composed of a single layer or multiple layers of silicon oxide (SiOx) or silicon nitride (SiNx). For example, the passivation layer 1516 can be a protection layer or an insulating layer. For example, as illustrated in FIG. 16, the passivation layer 1516 can include a hole through which the solder pattern SDP is exposed. For example, the hole of the passivation layer 1516 can overlap with the solder pattern SDP.

Referring to FIG. 16, a light emitting device ED can be arranged on the solder pattern SDP in each of a plurality of sub-pixels SP. The light emitting device ED can be formed on a silicon wafer by a method such as Metal Organic Chemical Vapor Deposition (MOCVD), Chemical Vapor Deposition (CVD), Plasma-Enhanced Chemical Vapor Deposition (PDCVD), Molecular Beam Epitaxy (MBE), Hydride Vapor Phase Epitaxy (HVPD), or Sputtering.

The light emitting device ED can include a first electrode Ecl, a first semiconductor layer 1611, an active layer 1612, a second semiconductor layer 1613, a second electrode Erl, and an encapsulation film 1614. For example, the encapsulation film 1614 may not be included in the light emitting device ED.

The first semiconductor layer 1611 can be disposed on the solder pattern SDP. The second semiconductor layer 1613 can be disposed on the first semiconductor layer 1611.

For example, one of the first semiconductor layer 1611 and the second semiconductor layer 1613 can be implemented as a compound semiconductor of group III-V, group II-VI, and can be doped with an impurity (or dopant). For example, one of the first semiconductor layer 1611 and the second semiconductor layer 1613 can be a semiconductor layer doped with an n-type impurity, and the other can be a semiconductor layer doped with a p-type impurity. For example, at least one of the first semiconductor layer 1611 and the second semiconductor layer 1613 can be a layer doped with an n-type or p-type impurity in a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). For example, the n-type impurity can be silicon (Si), germanium (Ge), selenium (Se), carbon (C), tellurium (Te), or tin (Sn). For example, the p-type impurity can be magnesium (Mg), zinc (Zn), calcium (Ca), strontium (Sr), barium (Ba), or beryllium (Be).

For example, the first semiconductor layer 1611 and the second semiconductor layer 1613 can be a nitride semiconductor including an n-type impurity and a nitride semiconductor including a p-type impurity, respectively. For example, the first semiconductor layer 1611 can be a nitride semiconductor containing a p-type impurity, and the second semiconductor layer 1613 can be a nitride semiconductor containing an n-type impurity.

The active layer 1612 can be arranged between the first semiconductor layer 1611 and the second semiconductor layer 1613. The active layer 1612 can receive holes and electrons from the first semiconductor layer 1611 and the second semiconductor layer1613 to emit light. For example, the active layer 1612 can be configured as one of a single well structure, a multi-well structure, a single quantum well structure, a multi-quantum well (MQW) structure, a quantum dot structure, and a quantum wire structure. For example, the active layer 1612 can be configured as indium gallium nitride (InGaN) or gallium nitride (GaN).

For another example, the active layer 1612 can include a multi-quantum well (MQW) structure having a well layer and a barrier layer having a higher band gap than the well layer. For example, the active layer 1612 can be formed of InGaN layer as a well layer and an AlGaN layer as a barrier layer.

The first electrode Ecl of the light emitting device ED can be arranged between the first semiconductor layer 1611 and the solder pattern SDP. For example, the first electrode Ecl of the light emitting device ED can electrically connect the first semiconductor layer 1611 and the column connection electrode CCE. The column line voltage (e.g., the anode voltage) output from the driver DRV can be applied to the first semiconductor layer 1611 through the column line CL, the column connection electrode CCE, and the first electrode Ecl. For example, the first electrode Ecl can be composed of a conductive material capable of eutectic bonding with the solder pattern SDP. For example, the first electrode Ecl of the light emitting device ED can be composed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof.

The second electrode Erl of the light emitting device ED can be disposed on the second semiconductor layer 1613. For example, the second electrode Erl of the light emitting device ED can electrically connect the second semiconductor layer 1613 and the row line RL. A row line voltage (e.g., referred to as a low-potential voltage VSS as a cathode voltage) output from the driver DRV can be applied to the second semiconductor layer 1613 through the row connection electrode RCE, the row line RL, and the second electrode Erl. The second electrode Erl of the light emitting device ED can be made of a transparent conductive material so that light emitted from the light emitting device ED can be directed to the upper portion of the light emitting device ED. For example, the second electrode Erl can be made of a material such as indium tin oxide (ITO), indium zinc oxide (IZO), or indium gallium zinc oxide (IGZO).

The encapsulation film 1614 can be disposed on at least a portion of the first semiconductor layer 1611, the active layer 1612, the second semiconductor layer 1613, the first electrode Ecl, and the second electrode Erl. For example, the encapsulation film 1614 can surround at least a portion of the first semiconductor layer 1611, the active layer 1612, the second semiconductor layer 1613, the first electrode Ecl, and the second electrode Erl.

For example, the encapsulation film 1614 can protect the first semiconductor layer 1611, the active layer 1612, and the second semiconductor layer 1613. For example, the encapsulation film 1614 can be disposed on a side surface of the first semiconductor layer 1611, a side surface of the active layer 1612, and a side surface of the second semiconductor layer 1613.

For example, the encapsulation film 1614 can be disposed on at least a portion of the first electrode Ecl and the second electrode Erl of the light emitting device ED. For example, the encapsulation film 1614 can be disposed on an edge portion (or one side) of the first electrode Ecl of the light emitting device ED and an edge portion (or one side) of the second electrode Erl of the light emitting device ED. At least a portion of the first electrode Ecl can be exposed from the encapsulation film 1614 so that the first electrode Ecl can be connected to the solder pattern SDP. For example, at least a portion of the second electrode Erl can be exposed from the encapsulation film 1614 so that the second electrode Erl can be connected to the row line RL. For example, the encapsulation film 1614 can be made of an insulating material such as silicon nitride (SiNx) or silicon oxide (SiOx).

For another example, the encapsulation film 1614 can have a structure in which a reflective material is dispersed in a resin layer, but the embodiments of the present disclosure are not limited thereto. For example, the encapsulation film 1614 can be manufactured as a reflector of various structures. Light emitted from the active layer 1612 can be reflected upward by the encapsulation film 1614, thereby improving light extraction efficiency. For example, the encapsulation film 1614 can be a reflective layer.

According to the embodiments of the present disclosure, the light emitting device ED is described as having a vertical structure, but the embodiments of the present disclosure are not limited thereto. For example, the light emitting device ED can have a lateral structure or a flip chip structure.

The structure of the light emitting device ED illustrated in FIG. 16 can be substantially equally applied to all of the first light emitting device EDa, the second light emitting device EDb, and the third light emitting device EDc. According to embodiments of the present disclosure, a first optical layer 1517a can be arranged to surround a plurality of light emitting devices ED in the display area DA. For example, the first optical layer 1517a can be arranged to cover a plurality of light emitting devices ED and the bank BNK in the area of a plurality of sub-pixels SP. For example, the first optical layer 1517a can cover a bank BNK, a portion of the passivation layer 1516, and an area between the plurality of light emitting devices ED. The first optical layer 1517a can be arranged or covered between a plurality of light emitting devices ED included in one pixel and between a plurality of banks BNK. For example, the first optical layer 1517a can be arranged to extend in the first direction X and be spaced apart from each other in the second direction Y. For example, the first optical layer 1517a can be arranged to surround the side of the light emitting devices ED and the banks BNK between the passivation layer 1516 and the row line RL. For example, the first optical layer 1517a can be a diffusion layer or a sidewall diffusion layer.

The first optical layer 1517a can include an organic insulating material having fine particles dispersed therein. For example, the first optical layer 1517a can be composed of siloxane having fine metal particles, such as titanium dioxide (TiO₂) particles, dispersed therein. Light from a plurality of light emitting devices ED can be scattered by the fine particles dispersed in the first optical layer 1517a and emitted to the outside of the display device 100. Accordingly, the first optical layer 1517a can improve the extraction efficiency of light emitted from the plurality of light emitting devices ED.

For example, the first optical layer 1517a can be arranged on each of a plurality of pixels, or can be arranged together on some pixels arranged in the same row. For example, the first optical layer 1517a can be arranged on each of a plurality of pixels, or the plurality of pixels can share one first optical layer 1517a. For another example, each of the plurality of sub-pixels can separately include a first optical layer 1517a.

According to the embodiments of the present disclosure, in the display area DA, a second optical layer 1517b can be arranged on the passivation layer 1516. For example, the second optical layer 1517b can be arranged to surround the first optical layer 1517a. For example, the second optical layer 1517b can be in contact with a side surface of the first optical layer 1517a. For example, the second optical layer 1517b can be arranged in an area between the plurality of pixels. However, the embodiments of the present disclosure are not limited thereto. For example, the second optical layer 1517b can be a diffusion layer, a diffusion layer window, or a window diffusion layer.

The second optical layer 1517b can be composed of an organic insulating material. The second optical layer 1517b can be composed of the same material as the first optical layer 1517a. For example, the first optical layer 1517a can include fine particles, and the second optical layer 1517b may not include fine particles. For example, the second optical layer 1517b can be composed of siloxane.

For example, the thickness of the first optical layer 1517a can be smaller than the thickness of the second optical layer 1517b. Accordingly, when viewed from a planar view, the area where the first optical layer 1517a is disposed can include a concave portion that is sunken inwardly from the upper surface of the second optical layer 1517b.

According to the embodiments of the present disclosure, a row line RL can be disposed on the first optical layer 1517a and the second optical layer 1517b. For example, the row line RL can be electrically connected to a plurality of row connection electrodes RCE through contact holes of the second optical layer 1517b. For example, the row line RL can be disposed on a plurality of light emitting devices ED. For example, the row line RL can include a transparent conductive oxide such as indium tin oxide (ITO) or indium zinc oxide (IZO). For example, the row line RL can be arranged to be in contact with the second electrode Erl of the light emitting device ED. For example, the row line RL can overlap with the first optical layer 1517a. For example, the row line RL can cover a plane on the outside of the first optical layer 1517a.

The row line RL can extend continuously in the first direction X of the substrate 210. Accordingly, the row line RL can be commonly connected to a plurality of pixels arranged in the first direction X of the substrate 210. For example, the row line RL can be commonly connected to a plurality of pixels.

According to the embodiments of the present disclosure, the row line RL can be continuously extended on the first optical layer 1517a, the second optical layer 1517b, and the light emitting device ED. The area where the first optical layer 1517a is disposed can include a concave portion that is sunken inwardly from the upper surface of the second optical layer 1517b. Accordingly, the first part of the row line RL disposed on the first optical layer 1517a can be disposed along the concave portion, and thus can be disposed at a lower position than the second part of the row line RL disposed on the second optical layer 1517b.

A third optical layer 1517c can be disposed on the row line RL. The third optical layer 1517c can be disposed so as to overlap with a plurality of light emitting devices ED and the first optical layer 1517a. Since the third optical layer 1517c is arranged on the row line RL and the plurality of light emitting devices ED, it is possible to improve a mura that can occur in some of the plurality of light emitting devices ED. For example, when transferring a plurality of light emitting devices ED onto the substrate 210 of the display panel 110, there can occur an area where the spacing between the plurality of light emitting devices ED is not uniform due to process deviation. If the spacing between the plurality of light emitting devices ED is not uniform, emission areas of each of the plurality of light emitting devices ED can be arranged unevenly, and thus a mura can be visible to the user. Accordingly, since the third optical layer 1517c is arranged to uniformly diffuse light over the plurality of light emitting devices ED, it is possible to reduce light emitted from some of the light emitting devices ED from being visible as a mura. Accordingly, since the light emitted from the plurality of light emitting devices EDs is evenly diffused by the third optical layer 1517c and extracted to the outside of the display device 100, the luminance uniformity of the display device 100 can be improved.

The third optical layer 1517c can be composed of an organic insulating material in which fine particles are dispersed. For example, the third optical layer 1517c can be composed of siloxane in which fine metal particles such as titanium dioxide (TiO₂) particles are dispersed. For example, the third optical layer 1517c can be composed of the same material as the first optical layer 1517a. For example, the third optical layer 1517c can be a diffusion layer or an upper diffusion layer.

According to the embodiments of the present disclosure, light from a plurality of light emitting devices ED can be scattered by fine particles dispersed in a third optical layer 1517c and emitted to the outside of the display device 100. The third optical layer 1517c can evenly mix light emitted from a plurality of light emitting devices ED, thereby further improving the luminance uniformity of the display device 100. In addition, the light extraction efficiency of the display device 100 can be improved by the light scattered from the plurality of fine particles, thereby enabling the display device 100 to be driven at low power.

A black matrix BM can be arranged on the row line RL, the first optical layer 1517a, the second optical layer 1517b, and the third optical layer 1517c in the display area DA. For example, the black matrix BM can fill a contact hole of the second optical layer 1517b. The black matrix BM can be configured to cover the display area DA, so that the color mixing of light and external light reflection of the plurality of sub-pixels can be reduced. For example, the black matrix BM can also be arranged in the contact hole where the row line RL and the row connection electrode RCE are connected, so that light leakage between the neighboring plurality of sub-pixels can be prevented.

For example, the black matrix BM can be composed of an opaque material. For example, the black matrix BM can be an organic insulating material to which a black pigment or a black dye is added.

A cover layer 1518 can be arranged on the black matrix BM in the display area DA. The cover layer 1518 can protect a configuration under the cover layer 1518. For example, the cover layer 1518 can be composed of an organic insulating material. For example, the cover layer 1518 can be composed of a photo resist, polyimide (PI), or photo acryl-based material. For example, the cover layer 1518 can be an overcoating layer or an insulating layer.

A polarizing layer 114 can be arranged on the cover layer 1518 via a first adhesive layer 112. A cover member 118 can be arranged on the polarizing layer 114 via a second adhesive layer 116. For example, the first adhesive layer 112 and the second adhesive layer 116 can include an optically clear adhesive (OCA), an optically clear resin (OCR), or a pressure sensitive adhesive (PSA).

According to embodiments of the present disclosure, a plurality of pads PD can be arranged on a third insulating layer 1515c in a second non-display area NDA2. For example, at least a portion of the plurality of pads PD can be exposed from a passivation layer 1516. For example, the plurality of pads PD can be electrically connected to a fourth pad connection pattern PCP4 through a contact hole of the third insulating layer 1515c.

An adhesive layer ACF can be arranged on the plurality of pads PD. The adhesive layer ACF can be an adhesive layer in which conductive balls are dispersed in an insulating material. When heat or pressure is applied to the adhesive layer ACF, the conductive balls can be electrically connected at a portion where the heat or pressure is applied, thereby having conductive properties. The adhesive layer ACF can be disposed between a plurality of pads PD and a flexible printed circuit 102, so that the flexible printed circuit 102 can be attached or bonded to the plurality of pads PD. For example, the adhesive layer ACF can be an anisotropic conductive film ACF.

A flexible printed circuit 102 can be disposed on the adhesive layer ACF. The flexible printed circuit 102 can be electrically connected to the plurality of pads PD through the adhesive layer ACF. Accordingly, a signal supplied from the flexible printed circuit 102 can be transmitted to a driver DRV of a display area DA through the plurality of pads PD, the fourth pad connection pattern PCP4, the third pad connection pattern PCP3, the second pad connection pattern PCP2, and the first pad connection pattern PCP1.

Referring to FIG. 15, the display panel 110 according to the embodiments of the present disclosure can include a substrate 210, a layer stack 1410 on a plurality of drivers DRV disposed on the substrate 210, an optical layer 1517a disposed between a plurality of light emitting devices EDa, EDb and EDc on the layer stack 1410, an adhesive layer 116 disposed on the plurality of light emitting devices EDa, EDb and EDc and the optical layer 1517a, and a cover member 118 disposed on the adhesive layer 116.

A plurality of column lines CL can be disposed between the layer stack 1410 and the plurality of light emitting devices EDa, EDb and EDc.

A plurality of row lines RL can be arranged on a plurality of light emitting devices EDa, EDb and EDc and an optical layer 1517a. A plurality of row lines RL can be arranged between a plurality of light emitting devices EDa, EDb and EDc, an optical layer 1517a, and an adhesive layer 116.

A layer stack 1410 can include a plurality of protection layers 1513a, 1513b and 1514 arranged on the side and upper surface of each of a plurality of drivers DRV, a plurality of insulating layers 1515a, 1515b and 1515c arranged on the plurality of protection layers 1513a, 1513b and 1514, and a bank BNK arranged on the plurality of insulating layers.

The plurality of protection layers 1513a, 1513b and 1514 can further include a side protection layer 1513 disposed on each side of the plurality of drivers DRV and an upper protection layer 1514 disposed on the upper surface of each of the plurality of drivers DR.

The side protection layer 1513 can include a first protection layer 1513a disposed on the substrate 210 and a second protection layer 1513b disposed on the first protection layer 1513a.

The upper protection layer 1514 can include a third protection layer 1514 disposed on the plurality of drivers DRV and the second protection layer 1513b.

The plurality of insulating layers 1515a, 1515b and 1515c can include a first insulating layer 1515a disposed on the upper protection layer 1514, and a second insulating layer 1515b disposed on the first insulating layer 1515a. The plurality of insulating layers 1515a, 1515b and 1515c can further include a third insulating layer 1515c disposed on the second insulating layer 1515b.

Each of the plurality of light emitting devices EDa, EDb and EDc can be disposed on the bank BNK and positioned in an opening of the optical layer 1517a.

At least a portion of each of the plurality of column lines CL can extend onto the bank BNK on the plurality of insulating layers 1515a, 1515b and 1515c. Each of the plurality of row lines RL can be arranged on the optical layer 1517a and the plurality of light emitting devices EDa, EDb and EDc.

A first electrode Ecl of each of the plurality of light emitting devices EDa, EDb and EDc can be electrically connected to at least a portion of a column line CL extending onto the bank BNK among the plurality of column lines CL. A second electrode Erl of each of the plurality of light emitting devices EDa, EDb and EDc can be electrically connected to one of the plurality of row lines RL.

Referring to FIG. 15, the display panel 110 according to the embodiments of the present disclosure can include a plurality of line connection patterns LCP that connect each of a plurality of lines including a plurality of row lines RL and/or a plurality of column lines CL to a plurality of drivers DRV.

The plurality of line connection patterns LCP can include a first line connection pattern LCP1 disposed on a side protection layer 1513, a second line connection pattern LCP2 disposed on an upper protection layer 1514 and electrically connected to the first line connection pattern LCP1 through a hole in the upper protection layer 1514, a third line connection pattern LCP3 disposed on a first insulating layer 1515a and electrically connected to the second line connection pattern LCP2 through a hole in the first insulating layer 1515a, and a fourth line connection pattern LCP4 disposed on a second insulating layer 1515b and electrically connected to the third line connection pattern LCP3 through a hole in the second insulating layer 1515b.

The first line connection pattern LCP1 can be electrically connected to one of the plurality of drivers DRV. The fourth line connection pattern LCP4 can be electrically connected to at least one second electrode Erl of the plurality of light emitting devices EDa, EDb and EDc, or can be electrically connected to at least one first electrode Ecl of the plurality of light emitting devices EDa, EDb and EDc.

The side protection layer 1513 arranged on each side of the plurality of drivers DRV can include two or more organic layers.

The first and second protection layers 1513a and 1513b as the side protection layer 1513, the third protection layer 1514 as the upper protection layer 1514, and the first to third insulating layers 1515a, 1515b and 1515c can each be composed of organic layers.

In the above, there have been described the structure and operation related to the display function of the display device 100 according to the embodiments of the present disclosure.

The display device 100 according to the embodiments of the present disclosure can provide not only a display function but also a touch sensing function. Accordingly, hereinafter, it will be described a structure and an operation related to the touch sensing function of the display device 100 according to the embodiments of the present disclosure.

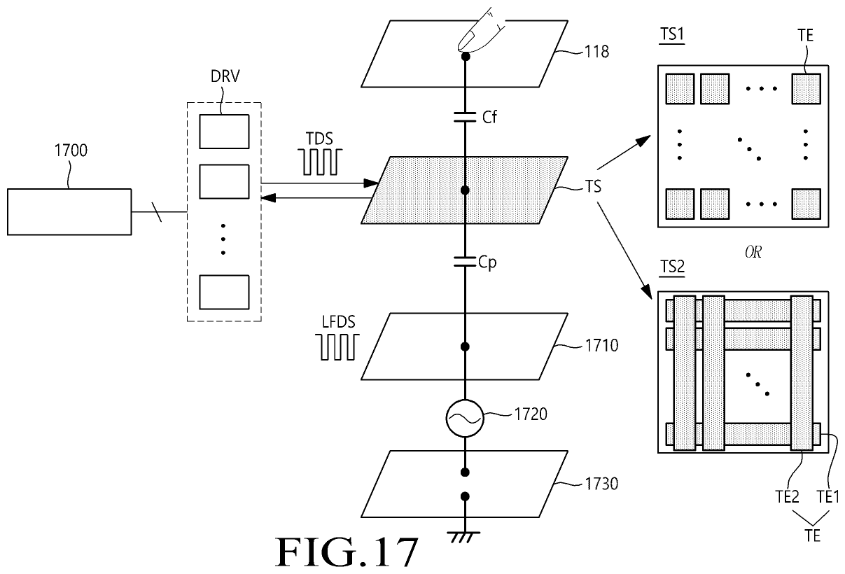

FIG. 17 is a diagram briefly illustrating the touch sensing structure of the display device 100 according to the embodiments of the present disclosure.

Referring to FIG. 17, the display device 100 according to the embodiments of the present disclosure can include, for performing the touch sensing, a touch sensor TS, a plurality of drivers DRV for driving and sensing the touch sensor TS, and a touch control circuit 1700 that controls the plurality of drivers DRV. The touch sensor TS can include a plurality of touch electrodes TE.

The plurality of drivers DRV can supply a touch driving signal TDS having a variable voltage level to the touch sensor TS. The touch driving signal TDS is a signal whose voltage level fluctuates, and can also be referred to as an AC signal or a pulse signal. For example, the touch driving signal TDS can have a signal waveform such as a square wave, a sine wave, or a triangular wave. For example, the frequency of the touch driving signal TDS can be constant. For another example, the frequency of the touch driving signal TDS can be variable. If the frequency of the touch driving signal TDS is variable according to the touch driving period T or time, it is possible to prevent the touch sensitivity degradation due to noise generated during the touch driving.

A plurality of drivers DRV can sense or detect an electrical state (e.g., a capacitance change) in the touch sensor TS to generate sensing data, and output the generated sensing data. Here, the sensing data can include digital sensing values.

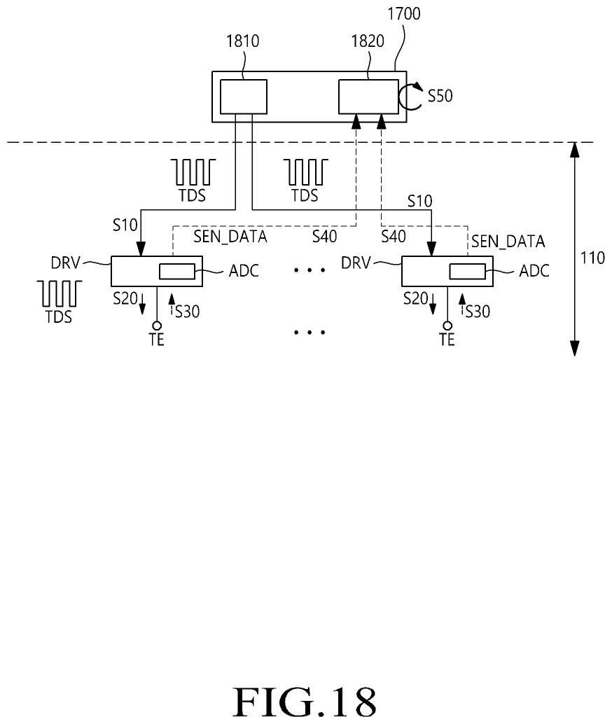

The plurality of drivers DRV can include at least one analog-to-digital converter ADC (see FIG. 18) to sense an electrical state in at least one of the plurality of row lines RL to obtain digital sensing values.

For example, the electrical state of at least one of a plurality of touch electrodes TE included in a touch sensor TS can include a capacitance Cf (e.g., self-capacitance) between a touch object such as a finger or a pen and the touch electrode TE. For another example, the electrical state of at least one of a plurality of touch electrodes TE included in a touch sensor TS can include capacitance (e.g., mutual capacitance) between two touch electrodes TE.

The touch control circuit 1700 can supply a touch driving signal TDS or a signal as a base of the touch driving signal TDS to each of the plurality of drivers DRV, and determine an occurrence of a touch or a touch position based on sensing data provided from each of the plurality of drivers DRV. For example, the touch control circuit 1700 can include a timing controller or a micro-control unit. The touch control circuit 1700 can further include a power management integrated circuit PMIC.

The display device 100 according to the embodiments of the present disclosure can perform self-capacitance-based touch sensing and/or mutual-capacitance-based touch sensing.

If a touch driving signal TDS is applied to at least one of a plurality of touch electrodes TE included in a touch sensor TS for touch sensing, an unwanted parasitic capacitance Cp can be formed between at least one touch electrode TE supplied with the touch driving signal TDS and other electrodes or other wirings in the vicinity. Parasitic capacitance Cp can be a factor that deteriorates touch sensitivity.

The display device 100 according to the embodiments of the present disclosure can further include a load-free driving electrode 1710 disposed around the touch sensor TS. The load-free driving electrode 1710 can correspond to an electrode arranged at a position where the parasitic capacitance Cp can be formed with the touch electrode TE. For example, the load-free driving electrode 1710 can include a plurality of row lines RL, a plurality of column lines CL, and a touch ground that vertically overlap with the touch electrode TE supplied with the touch driving signal TDS. Here, the touch ground can serve as a ground related to the touch sensing operation. The load-free driving electrode 1710 can further include another touch electrode TE to which the touch driving signal TDS is not applied.

The display device 100 according to the embodiments of the present disclosure can further include a guard driver 1720 that supplies a load-free driving signal LFDS whose signal characteristics correspond to the touch driving signal TDS to the load-free driving electrode 1710 in order to prevent unwanted parasitic capacitance Cp from being formed between the touch sensor TS and the load-free driving electrode 1710.

The load-free driving signal LFDS output from the guard driver 1720 to the load-free driving electrode 1710 can be a signal whose signal characteristics are similar to the touch driving signal TDS applied to the touch sensor TS. For example, the signal characteristics can include frequency, amplitude, and phase.

For example, the load-free driving signal LFDS can have the same frequency as the frequency of the touch driving signal TDS. The load-free driving signal LFDS can have the same amplitude as the touch driving signal TDS. The load-free driving signal LFDS can have the same phase as the touch driving signal TDS.

The display device 100 according to the embodiments of the present disclosure can further include a system ground 1730 that serves as a ground for the entire system.

The touch sensor TS can include a plurality of touch electrodes TE. For example, the touch sensor TS can be a first type touch sensor TS1 or a second type touch sensor TS2.

If the touch sensor TS is a first type touch sensor TS1, the plurality of touch electrodes TE can be arranged to be spaced apart from each other. For example, the first type touch sensor TS1 can be a touch sensor for self-capacitance-based touch sensing. In this case, each of the plurality of touch electrodes TE can function as both a driving electrode to which a touch driving signal TDS is applied and a sensing electrode sensed by the touch driving circuit.

If the touch sensor TS is a second type touch sensor TS2, the plurality of touch electrodes TE can include a plurality of first touch electrodes TE1 arranged in a first direction and a plurality of second touch electrodes TE2 arranged in a second direction different from the first direction. For example, the second type touch sensor TS2 can be a touch sensor for mutual-capacitance-based touch sensing. In this case, as an example, each of the plurality of first touch electrodes TE1 can function as a driving electrode to which a touch driving signal TDS is applied, and the plurality of second touch electrodes TE2 can function as a sensing electrode sensed by the touch driving circuit. As another example, each of the plurality of second touch electrodes TE2 can function as a driving electrode to which a touch driving signal TDS is applied, and the plurality of first touch electrodes TE1 can function as a sensing electrode sensed by the driver DRV.

Hereinafter, for the convenience of explanation, it will be described a case in which the touch sensor TS is a first type touch sensor TS1 as an example. However, it is not limited thereto.

Hereinafter, the touch sensing system and touch sensing operation of the display device 100 according to the embodiments of the present disclosure will be described in more detail.

FIG. 18 illustrates the touch sensing system of the display device 100 according to the embodiments of the present disclosure.

Referring to FIG. 18, the display device 100 according to the embodiments of the present disclosure can include a touch sensor TS including one or more touch electrodes TE, a plurality of drivers DRV for driving and sensing the touch electrodes TE, and a touch control circuit 1700 for controlling the plurality of drivers DRV.

The touch control circuit 1700 can include a signal supply circuit 1810 for supplying a touch driving signal TDS to at least one of the plurality of drivers DRV, and a touch sensing circuit 1820 for receiving sensing data SEN_DATA from at least one of the plurality of drivers DRV to determine an occurrence of a touch and/or a touch location (or touch coordinates).

Each of the plurality of drivers DRV can include an analog-to-digital converter ADC for converting a signal (e.g., analog signal) sensed through a corresponding touch electrode TE into a digital sensing value. In this way, since an analog-to-digital converter ADC exists in the display panel 110, among the various signals existing in the display panel 110, a digital signal (e.g., a digital sensing value) can exist. For example, the display panel 110 can be a unique panel having an analog domain in which an analog signal exists and a digital domain in which a digital signal exists.

The signal supply circuit 1810 of the touch control circuit 1700 can supply a touch driving signal TDS or a signal that is the basis of the touch driving signal TDS to each of a plurality of drivers DRV (S10).

Each of the plurality of drivers DRV can receive a touch driving signal TDS or a signal that is the basis of the touch driving signal TDS from a signal supply circuit 1810 of a touch control circuit 1700 (S10), and output a touch driving signal TDS to a touch electrode TE or a segmented electrode thereof (hereinafter, also referred to as a sub-touch electrode) arranged in a corresponding unit driving area UDA (S20).

Each of the plurality of drivers DRV can sense a touch electrode TE or a segmented electrode thereof arranged in a corresponding unit driving area UDA (S30). Each of the plurality of drivers DRV can sense a touch electrode TE or a segmented electrode thereof, convert a sensing signal obtained according to a sensing result into a digital sensing value using an analog-to-digital converter ADC, and generate sensing data SEN_DATA including the converted digital sensing values.

Each of the plurality of drivers DRV can provide sensing data SEN_DATA to the touch sensing circuit 1820 of the touch control circuit 1700 (S40).

The touch control circuit 1700 can determine whether a touch has occurred or a touch location based on the sensing data SEN_DATA provided from each of the plurality of drivers DRV (S50).

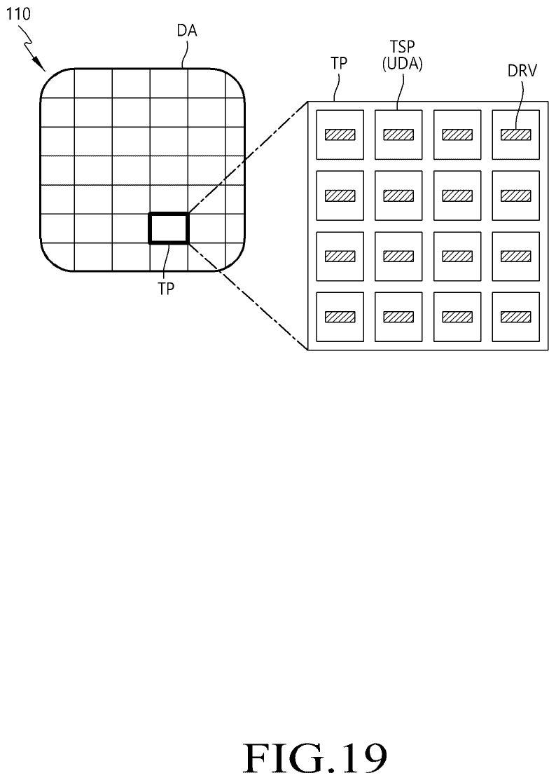

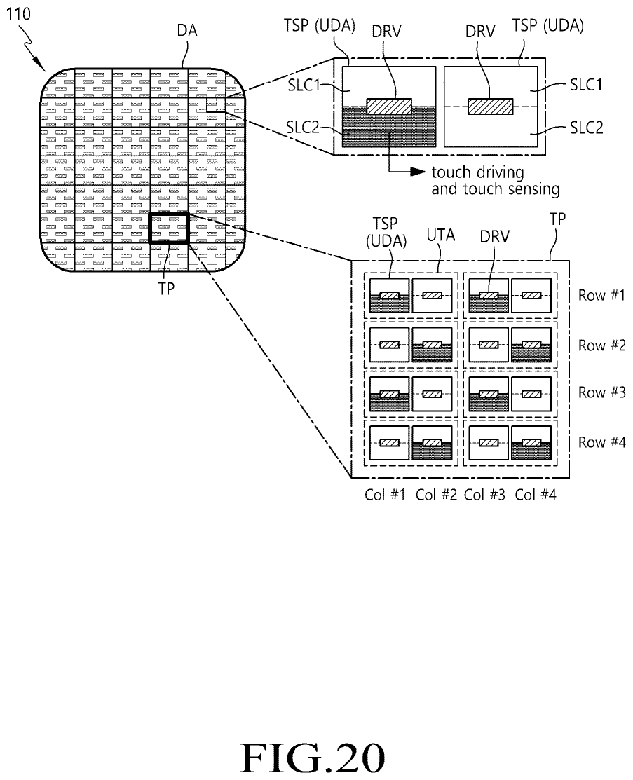

FIG. 19 and FIG. 20 illustrate a touch driving structure of a display panel 110 according to embodiments of the present disclosure. In the following description, FIG. 4, FIG. 6, FIG. 11, FIG. 17, and FIG. 18 can be also referred to together.

Referring to FIGS. 19 and 20, the display area DA of the display panel 110 can include a plurality of touch pixel areas TP. Each of the plurality of touch pixel areas TP can be an area corresponding to one touch electrode TE. One touch electrode TE can be one unit electrode (e.g., one unit touch sensor) for touch sensing.

Each of the plurality of touch pixel areas TP can include a plurality of touch sub-pixel areas TSP. Each of the plurality of touch sub-pixel areas TSP can be an area corresponding to one driver DRV. Each of the plurality of touch sub-pixel areas TSP can correspond to one unit driving area UDA for display driving.

One touch electrode TE can be disposed in each touch pixel area TP.

As an example, one touch electrode TE disposed in each touch pixel area TP can be formed of a metal formed integrally.

As another example, as illustrated in FIG. 19, one touch electrode TE disposed in each touch pixel area TP can be composed of a plurality of sub-touch electrodes. At least one sub-touch electrode can be disposed in each of the plurality of touch sub-pixel areas TSP. The plurality of sub-touch electrodes disposed in the entire multiple touch sub-pixel areas TSP can be driven or sensed by the plurality of drivers DRV. For example, at least one first sub-touch electrode among the plurality of sub-touch electrodes can be driven or sensed by a first driver DRV among the plurality of drivers DRV.

Even if the plurality of sub-touch electrodes constituting one touch electrode TE are driven and sensed by the plurality of drivers DRV, the touch control circuit 1700 can integrate sensing data received from the plurality of drivers DRV included in one touch pixel area TP to perform a touch algorithm. Accordingly, the plurality of sub-touch electrodes arranged in one touch pixel area TP can be processed as one touch electrode TE.

For example, the plurality of drivers DRV arranged in one touch pixel area TP can drive and sense the plurality of sub-touch electrodes simultaneously or at different timings, and supply sensing data SEN_DATA to the touch control circuit 1700. The touch control circuit 1700 can consider the combined sensing data SEN_DATA received from the plurality of drivers DRV as sensing data obtained from one touch electrode TE, and determine whether a touch has occurred and/or the touch coordinates based on the sensing data for the plurality of touch electrodes TE.

For example, each of the plurality of touch pixel areas TP can include 16 touch sub-pixel areas TSP. The 16 touch sub-pixel areas TSP can be arranged in 4 rows and 4 columns. Each of the 16 touch sub-pixel areas TSP can include one driver DRV. For example, each of the 16 touch sub-pixel areas TSP can have two or more sub-touch electrodes arranged. A plurality of sub-touch electrodes arranged throughout the 16 touch sub-pixel areas TSP can form one touch electrode corresponding to one touch pixel area TP.

Each of the plurality of touch sub-pixel areas TSP can include two or more row lines RL and two or more column lines CL. Each of the plurality of touch sub-pixel areas TSP can include two or more sub-pixels SP. Each of the plurality of touch sub-pixel areas TSP can include two or more light emitting devices ED.

Meanwhile, referring to FIG. 20, each of the plurality of touch pixel areas TP can include two or more unit touch driving areas UTA. Each of the two or more unit touch driving areas UTA can include at least one touch sub-pixel area TSP. According to the example of FIG. 20, each of the two or more unit touch driving areas UTA can include two touch sub-pixel areas TSP. Here, the unit touch driving area UTA is an area that becomes a basic unit of a touch driving pattern.

One touch sub-pixel area TSP can include two sub-touch driving areas SLC1 and SLC2. The two sub-touch driving areas can include a first sub-touch driving area SLC1 and a second sub-touch driving area SLC2. For example, the first sub-touch driving area SLC1 can correspond to an upper area in one touch sub-pixel area TSP, and the second sub-touch driving area SLC2 can correspond to a lower area in one touch sub-pixel area TSP. However, embodiments of the present disclosure are not limited thereto. The touch sub-pixel area TSP can correspond to the unit driving area UDA for driving the display of FIGS. 4, 6, and 11. The first sub-touch driving area SLC1 and the second sub-touch driving area SLC2 can correspond to the first sub-driving area SDA1 and the second sub-driving area SDA2 for driving the display of FIGS. 4, 6, and 11, respectively.

At least one sub-touch electrode separated from each other can be arranged in each of the first sub-touch driving area SLC1 and the second sub-touch driving area SLC2. Each of the first sub-touch driving area SLC1 and the second sub-touch driving area SLC2 can include two or more light emitting devices ED.

The sub-touch electrodes arranged in the first sub-touch driving area SLC1 and the sub-touch electrodes arranged in the second sub-touch driving area SLC2 can be arranged separately from each other without being connected to each other.

One unit touch driving area UTA can include two touch sub-pixel areas TSP. One unit touch driving area UTA can include two sub-touch driving areas SLC1 and SLC2 included in each of two touch sub-pixel areas TSP. For example, one unit touch driving area UTA can include four sub-touch driving areas. One unit touch driving area UTA can include two drivers DRV.

For example, a touch pixel area TP can include 16 touch sub-pixel areas TSP arranged in four rows and four columns. Each of the 16 touch sub-pixel areas TSP can include one driver DRV and two sub-touch driving areas SLC1 and SLC2.

As an example, during a touch driving period for touch sensing, all four sub-touch driving areas included in one unit touch driving area UTA can be driven and sensed. Accordingly, during a touch driving period for touch sensing, each of the two drivers DRV included in one unit touch driving area UTA can drive and sense all two sub-touch driving areas SLC1 and SLC2 included in the corresponding touch sub-pixel area TSP.

As another example, during a touch driving period for touch sensing, only some of the four sub-touch driving areas included in one unit touch driving area UTA can be driven and sensed.

According to the example of FIG. 20, during the touch driving period for touch sensing, only one sub-touch driving area among four sub-touch driving areas included in one unit touch driving area UTA can be driven and sensed. Accordingly, during the touch driving period for touch sensing, only one driver DRV among two drivers DRV included in one unit touch driving area UTA can drive and sense one of two sub-touch driving areas SLC1 and SLC2 included in the corresponding touch sub-pixel area TSP.

Unlike the example of FIG. 20, during the touch driving period for touch sensing, only two sub-touch driving areas among four sub-touch driving areas included in one unit touch driving area UTA can be driven and sensed. Accordingly, during the touch driving period for touch sensing, each of the two drivers DRV included in one unit touch driving area UTA can drive and sense one of the two sub-touch driving areas SLC1 and SLC2 included in the corresponding touch sub-pixel area TSP.

According to the embodiments of the present disclosure, the fact that the sub-touch driving area SLC1 and SLC2 is driven and sensed can mean that at least one sub-touch electrode disposed in the sub-touch driving area is driven (e.g., touch driven) and sensed.

The fact that at least one sub-touch electrode disposed in the sub-touch driving area is driven (e.g., touch driven) and sensed can mean that a touch driving signal TDS having a variable voltage level is applied to at least one sub-touch electrode disposed in the sub-touch driving area.

In the touch pixel area TP, the sub-touch driving area where touch driving and touch sensing are performed can be arranged in a zigzag shape. For example, if a touch pixel area TP includes 16 touch sub-pixel areas TSP arranged in four rows and four columns, in each of the first touch sub-pixel row Row #1 and the third touch sub-pixel row Row #3, the second sub-touch driving area SLC2 among the two sub-touch driving areas SLC1 and SLC2 included in the touch sub-pixel area TSP located in the first column Col #1 can be driven and sensed, the two sub-touch driving areas SLC1 and SLC2 included in the touch sub-pixel area TSP located in the second column Col #2 can be not driven and sensed. In addition, the second sub-touch driving area SLC2 among the two sub-touch driving areas SLC1 and SLC2 included in the touch sub-pixel area TSP located in the third column Col #3 can be driven and sensed, and the two sub-touch driving areas SLC1 and SLC2 included in the touch sub-pixel area TSP located in the fourth column Col #4 may not be driven and sensed.

In the second touch sub-pixel row Row #2 and the fourth touch sub-pixel row Row #4, the two sub-touch driving areas SLC1 and SLC2 included in the touch sub-pixel area TSP located in the first column Col #1 may not be driven and sensed, and the second sub-touch driving area SLC2 among the two sub-touch driving areas SLC1 and SLC2 included in the touch sub-pixel area TSP located in the second column Col #2 can be driven and sensed. In addition, the two sub-touch driving areas SLC1 and SLC2 included in the touch sub-pixel area TSP located in the third column Col #3 may not be driven and sensed, and the second sub-touch driving area SLC2 among the two sub-touch driving areas SLC1 and SLC2 included in the touch sub-pixel area TSP located in the fourth column Col #4 can be driven and sensed.

According to the above, the display panel 110 of the display device 100 according to the embodiments of the present disclosure can include a plurality of touch electrodes TE and a plurality of touch pixel areas TP corresponding to each other. Each of the plurality of touch sub-pixel areas TSP can include one driver DRV.

As described above, one touch pixel area TP can be an area where one touch electrode TE is arranged, and one touch sub-pixel area TSP can be an area where one driver DRV is arranged. For example, one touch electrode can be formed of one integrated metal. Alternatively, one touch electrode can be formed of a plurality of electrically connected metals.

The plurality of drivers DRV can be disposed on the substrate 210 and can be located in the display area DA. In addition, the plurality of drivers DRV can be disposed in each of the plurality of touch sub-pixel areas TSP. For example, one driver DRV can be disposed in one touch sub-pixel area TSP.

The plurality of drivers DRV can include a first driver DRV and a second driver DRV, and the plurality of light emitting devices ED driven by the first driver DRV and the plurality of light emitting devices ED driven by the second driver DRV can be different from each other.

The touch sensor TS can include a plurality of touch electrodes TE.

The unit driving area UDA driven by one driver DRV can be a touch sub-pixel area TSP, and can have an area smaller than the area of one touch pixel area TP corresponding to one touch electrode TE.

A plurality of drivers DRV can be disposed in one touch pixel area TP corresponding to one touch electrode TE. According to the examples of FIGS. 19 and 20, 16 drivers DRV can be arranged in one touch pixel area TP corresponding to one touch electrode TE.

The plurality of touch pixel areas TP can include a first touch pixel area TP in which a first touch electrode TE among the plurality of touch electrodes is disposed. The first driver DRV and the second driver DRV can be disposed in the first touch pixel area TP which is an area in which one of the plurality of touch electrodes TE is disposed.

As illustrated in FIG. 19, the plurality of touch sub-pixel areas TSP included in the first touch pixel area TP corresponding to one first touch electrode TE can each include a plurality of sub-touch electrodes. For example, at least one sub-touch electrode can be disposed in one touch sub-pixel area TSP. As another example, if one touch sub-pixel area TSP is divided into two sub-touch driving areas SLC1 and SLC2 (see FIG. 20), at least two sub-touch electrodes can be disposed in one touch sub-pixel area TSP.

For example, referring to FIG. 19, a plurality of touch sub-pixel areas TSP included in a first touch pixel area TP corresponding to one first touch electrode TE can include a first touch sub-pixel area TSP in which a first driver DRV is disposed and a second touch sub-pixel area TSP in which a second driver DRV is disposed. The first touch sub-pixel area TSP can include at least one first sub-touch electrode, and the second touch sub-pixel area TSP can include at least one second sub-touch electrode.

At least one first sub-touch electrode disposed in a first touch sub-pixel area TSP can bedriven by a first driver DRV disposed in the first touch sub-pixel area TSP, and at least one second sub-touch electrode disposed in a second touch sub-pixel area TSP can bedriven by a second driver DRV disposed in the second touch sub-pixel area TSP. However, at least one first sub-touch electrode disposed in the first touch sub-pixel area TSP and at least one second sub-touch electrode disposed in the second touch sub-pixel area TSP can be included in the sub-touch electrodes constituting one first touch electrode TE.

For example, the first touch electrode TE can include at least one first sub-touch electrode disposed in the first touch sub-pixel area TSP and at least one second sub-touch electrode disposed in the second touch sub-pixel area TSP.

Hereinafter, the touch sensor structure of the display panel 110 according to the embodiments of the present disclosure will be described in detail. In the following description, reference is also made to FIGS. 1 to 20.

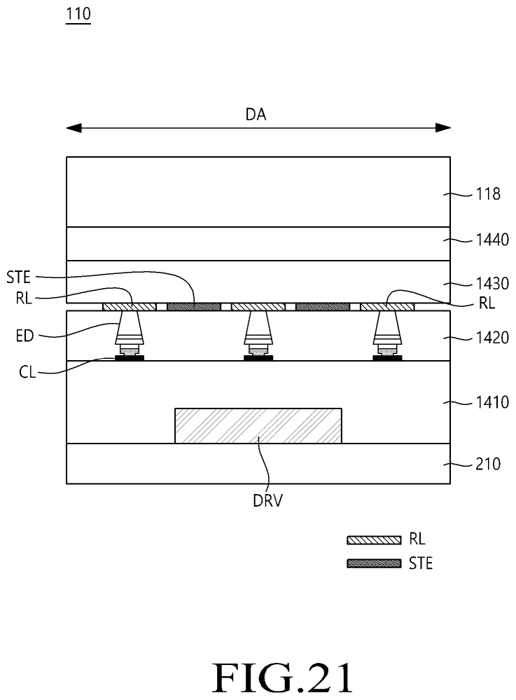

FIG. 21 is a cross-sectional view of the display panel 110 according to the embodiments of the present disclosure.

Referring to FIG. 21, the display panel 110 according to the embodiments of the present disclosure can include a substrate 210, a layer stack 1410 disposed on the substrate 210, a plurality of light emitting devices ED disposed on the layer stack 1410 and positioned in a display area DA, a plurality of column lines CL electrically connected to a first electrode of each of the plurality of light emitting devices ED, a plurality of row lines RL electrically connected to a second electrode of each of the plurality of light emitting devices ED, a touch sensor TS including a plurality of sub-touch electrodes STE disposed in the same metal layer as the plurality of row lines RL, and an overcoat layer 1430 disposed on the plurality of row lines RL and the touch sensor TS.

The touch sensor TS can be disposed in the same metal layer as the row lines RL connected to the light emitting devices ED. Such a touch sensor structure can be referred to as an in-cell type touch sensor structure.

The display panel 110 can further include a plurality of drivers DRV. The plurality of drivers DRV can be disposed on the substrate 210, and can drive a plurality of light emitting devices ED and drive or sense a plurality of sub-touch electrodes STE included in the touch sensor TS.

The touch sensor TS can include sub-touch electrodes STE. In addition, among the sub-touch electrodes STE included in the touch sensor TS, a plurality of sub-touch electrodes STE can form one touch electrode TE. For example, the touch sensor TS can include a plurality of touch electrodes TE, and each of the plurality of touch electrodes TE can include a plurality of sub-touch electrodes STE.

The plurality of drivers DRV can be disposed in the display area DA. The plurality of drivers DRV can be disposed between the substrate 210 and the plurality of light emitting devices ED.

The display panel 110 can further include an adhesive layer 1440 disposed on the overcoat layer 1430, and a cover member 118 disposed on the adhesive layer 1440. The display panel 110 can further include an optical layer 1420 surrounding a plurality of light emitting devices ED.

A plurality of row lines RL and a plurality of sub-touch electrodes STE can be disposed on the optical layer 1420. For example, the plurality of row lines RL and the plurality of sub-touch electrodes STE can be disposed within the same metal layer on the optical layer 1420. For example, the plurality of row lines RL and the plurality of sub-touch electrodes STE can include the same metal.

Each of the plurality of row lines RL can overlap with two or more of the plurality of light emitting devices ED, and the touch sensor TS or the plurality of sub-touch electrodes STE included in the touch sensor TS may not overlap with the plurality of light emitting devices ED.

The overcoat layer 1430 can be disposed on the plurality of light emitting devices ED, the plurality of row lines RL, and the plurality of sub-touch electrodes STE. For example, the overcoat layer 1430 can be a planarization layer including a transparent insulating material. Here, the transparent insulating material can be an organic insulating material.

For example, the overcoat layer 1430 can be composed of an insulating material, thereby protecting the plurality of light emitting devices ED, the plurality of row lines RL, and the plurality of sub-touch electrodes STE, while at the same time preventing short-circuiting between adjacent row lines RL and sub-touch electrodes STE.

For example, the overcoat layer 1430 can be composed of a transparent insulating material, so that light emitted from a plurality of light emitting devices ED can be well transmitted upward. For example, accordingly, light emitted from a plurality of light emitting devices ED can pass through the overcoat layer 1430 and be emitted to the outside without significant loss.

For example, the optical layer 1420 can be composed of a planarization layer including an organic insulating material. Accordingly, a distance between the viewing surface (or touch surface) and the light emitting devices ED can be maintained constant at any position, so that the light-emitting characteristics can be uniform, and the distance between the touch pointer (e.g., finger, pen, etc.) and the touch sensor TS can be maintained constant at any position, so that the accuracy of touch sensing can also be increased.

Each of the plurality of light emitting devices ED can be a vertical light emitting device in which a first electrode (e.g., an anode electrode or a cathode electrode) and a second electrode (e.g., a cathode electrode or an anode electrode) are positioned vertically. For example, the plurality of column lines CL can be arranged below the plurality of light emitting devices ED, and the plurality of row lines RL can be arranged above the plurality of light emitting devices ED. In another example, the plurality of column lines CL can be arranged above the plurality of light emitting devices ED, and the plurality of row lines RL can be arranged below the plurality of light emitting devices ED.

As described above, each of the plurality of column lines CL can be electrically connected in common with a first electrode of each of two or more light emitting devices ED arranged in the same column among the plurality of light emitting devices ED. Each of the plurality of row lines RL can be electrically connected in common with a second electrode of each of two or more light emitting devices ED arranged in the same row among the plurality of light emitting devices ED.

As described above, the plurality of row lines RL can be driven sequentially. For example, at any point in time, a first low-potential voltage VSS1 can be applied to one row line RL among the plurality of row lines RL, and a second low-potential voltage VSS2 higher than the first low-potential voltage VSS1 can be applied to the remaining row lines RL.

As described above, the display device 100 according to the embodiments of the present disclosure can include a plurality of unit driving areas UDA included in the display area DA, a plurality of light emitting devices ED arranged in each of the plurality of unit driving areas UDA, a plurality of column lines CL arranged in each of the plurality of unit driving areas UDA and electrically connected to a first electrode of each of the plurality of light emitting devices ED, a plurality of row lines RL arranged in each of the plurality of unit driving areas UDA and electrically connected to a second electrode of each of the plurality of light emitting devices ED, and a touch sensor TS including the same metal as the plurality of row lines RL.

The display device 100 can further include an overcoat layer 1430 disposed on the plurality of row lines RL and the touch sensor TS. The overcoat layer 1430 can be a planarization layer including a transparent insulating material. The display device 100 can further include a driver DRV disposed in each of a plurality of unit driving areas UDA, and driving a plurality of light emitting devices ED and driving or sensing a touch sensor TS.

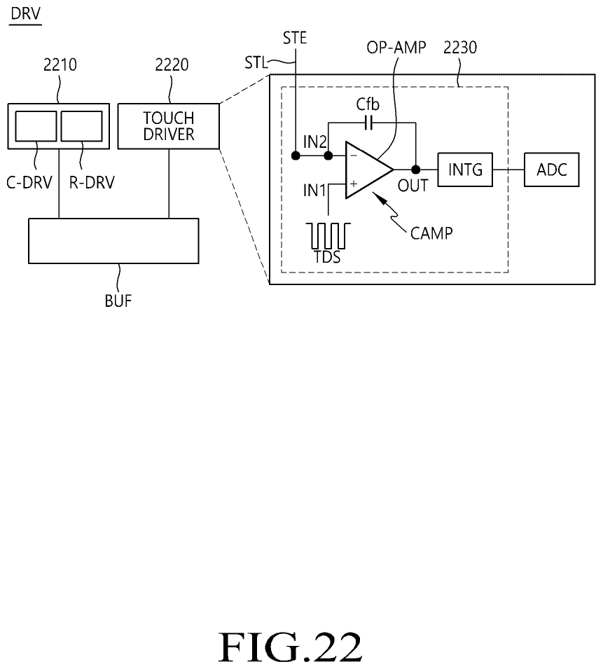

FIG. 22 is a block diagram of a driver DRV according to embodiments of the present disclosure.

Referring to FIG. 22, each of the plurality of drivers DRV included in the display panel 110 according to embodiments of the present disclosure can include a display driver 2210 for driving two or more light emitting devices ED disposed in a corresponding touch sub-pixel area TSP among a plurality of light emitting devices ED, and a touch driver 2220 for sensing two or more sub-touch electrodes STE disposed in a corresponding touch sub-pixel area TSP among a plurality of sub-touch electrodes STE included in a touch sensor TS.

The display driver 2210 can include a column driver C-DRV electrically connected to the first electrode of each of two or more light emitting devices ED disposed in the corresponding touch sub-pixel area TSP among the plurality of light emitting devices ED, and a row driver R-DRV electrically connected to the second electrode of each of two or more light emitting devices ED disposed in the corresponding touch sub-pixel area TSP among the plurality of light emitting devices ED.

The touch driver 2220 can include a sensing unit 2230 electrically connected to two or more sub-touch electrodes STE arranged in the corresponding touch sub-pixel area TSP, and an analog-to-digital converter ADC that converts an output value of the sensing unit 2230 into a sensing value corresponding to a digital value (e.g., digital sensing value) and outputs the converted sensing value.

At least one of the plurality of drivers DRV can include a signal amplification circuit BUF that amplifies and outputs a received signal. Here, the signal amplification circuit BUF can include at least one buffer.

As an example, each of the plurality of drivers DRV included in the display panel 110 according to the embodiments of the present disclosure can include a signal amplification circuit BUF, and the signal amplification circuit BUF of each of the plurality of drivers DRV can operate.

As another example, some of the drivers DRV included in the display panel 110 according to the embodiments of the present disclosure can include a signal amplification circuit BUF, and the signal amplification circuit BUF of some of the drivers DRV can operate.

As another example, each of the plurality of drivers DRV included in the display panel 110 according to the embodiments of the present disclosure can include a signal amplification circuit BUF. The signal amplification circuit BUF of some selected drivers DRV among the plurality of drivers DRV can be activated and operated. The signal amplification circuit BUF of the unselected driver DRV among the plurality of drivers DRV can be deactivated and may not operate.

For example, the sensing unit 2230 can include a charge amplifier CAMP. The charge amplifier CAMP can include an operational amplifier OP-AMP and a feedback capacitor Cfb. The operational amplifier OP-AMP can include a first input terminal IN1 into which a touch driving signal TDS is input, a second input terminal IN2 electrically connected to a selected sub-touch electrode STE among a plurality of sub-touch electrodes STE arranged in a corresponding touch sub-pixel area TSP, and an output terminal OUT from which an output signal is output. The first input terminal IN1 can be a non-inverting input terminal (or an inverting input terminal), and the second input terminal IN2 can be an inverting input terminal (or a non-inverting input terminal). The feedback capacitor Cfb can be connected between the second input terminal IN2 and the output terminal OUT.

The second input terminal IN2 can be electrically connected to a selected sub-touch electrode STE among a plurality of sub-touch electrodes STE arranged in the corresponding touch sub-pixel area TSP through the corresponding sub-touch line STL.

For example, the sensing unit 2230 can further include an integrator INTG that integrates an output signal of a charge amplifier CAMP and outputs an integral value. The integral value output from the integrator INTG can be an output value of the sensing unit 2230. An analog-to-digital converter ADC can convert an output value of the sensing unit 2230 into a sensing value corresponding to a digital value and output sensing data including the sensing value.

The sensing unit 2230 can further include a switching circuit (also referred to as a multiplexing circuit) that selects one of a plurality of sub-touch electrodes STE arranged in the corresponding touch sub-pixel area TSP and electrically connects the selected sub-touch electrode to a second input terminal INT2 of a charge amplifier CAMP.

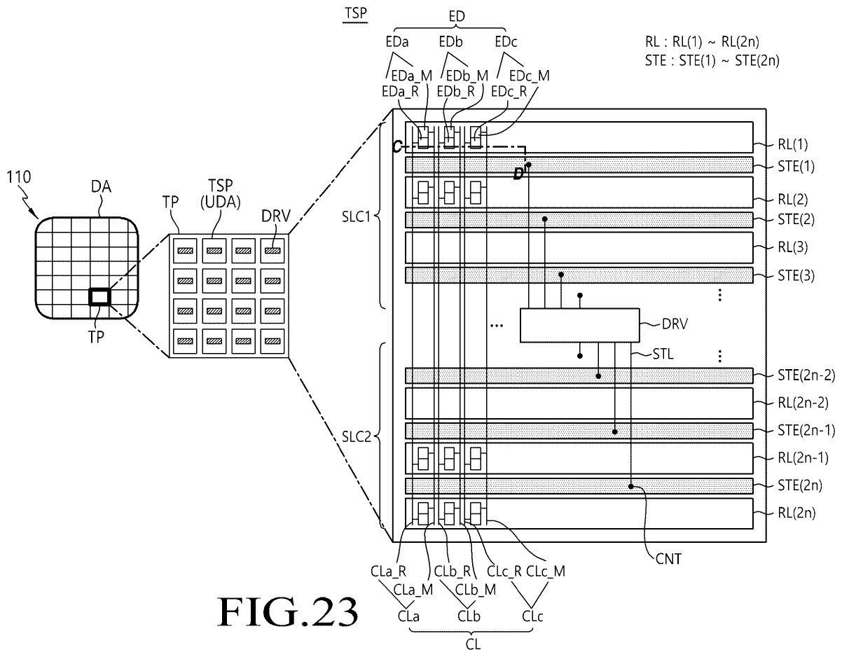

Hereinafter, with reference to FIGS. 23 to 25, the touch sensor structure of the display panel 110 according to the embodiments of the present disclosure will be described in more detail. In the following description, FIGS. 1 to 22 are also referred to.

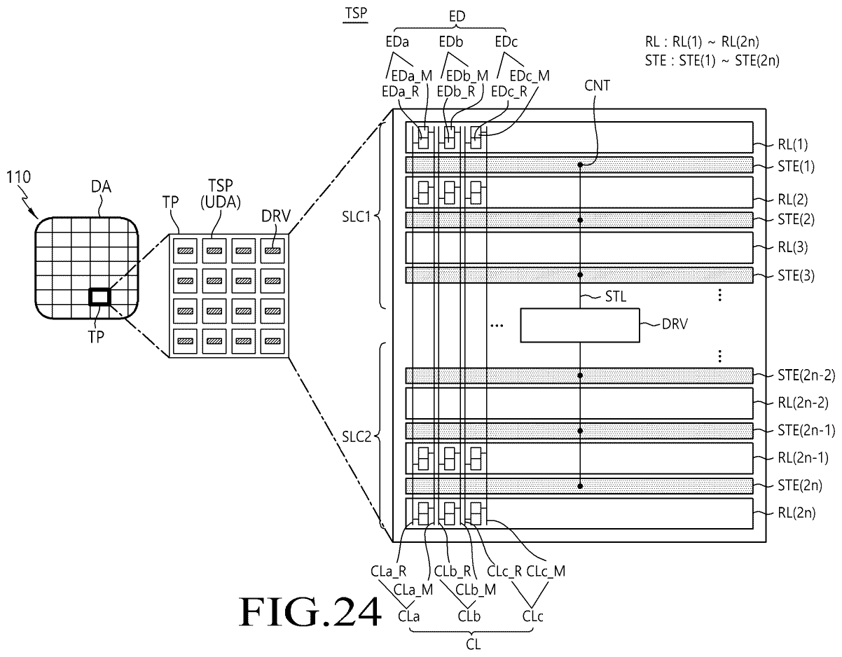

FIGS. 23 and 24 are plan views illustrating the touch sensor structure of the display panel 110 according to the embodiments of the present disclosure.

Referring to FIGS. 23 and 24, the display area DA can include a plurality of touch pixel areas TP.

Each of the plurality of touch pixel areas TP can be an area where one touch electrode TE is formed. Each of the plurality of touch pixel areas TP can be referred to as a unit touch sensing area, and one touch electrode TE formed in each of the plurality of touch pixel areas TP can be referred to as one unit touch sensor.

Each of the plurality of touch pixel areas TP can include a plurality of touch sub-pixel areas TSP.

Each of the plurality of touch sub-pixel areas TSP can be an area where one driver DRV is disposed. Each of the plurality of touch sub-pixel areas TSP can be an area where touch driving is performed by one driver DRV.

Each of the plurality of touch sub-pixel areas TSP can be provided with a plurality of sub-touch electrodes STE(1) to STE(2n) (where n is a natural number greater than or equal to 1) driven (i.e., touch driven) by one driver DRV.

The sub-touch electrodes STE disposed throughout a plurality of touch sub-pixel areas TSP included in each of a plurality of touch pixel areas TP can form one touch electrode TE.

The sub-touch electrodes STE disposed in a first touch pixel area TP among a plurality of touch pixel areas TP can form one touch electrode TE corresponding to the first touch pixel area TP.

For example, one touch pixel area TP can include 16 touch sub-pixel areas TSP arranged in 4 rows and 4 columns, and each of the 16 touch sub-pixel areas TSP can include 2n sub-touch electrodes STE(1) to STE(2n). One touch pixel area TP can include (16×2n) sub-touch electrodes STE. The (16×2n) sub-touch electrodes STE included in one touch pixel area TP can form one touch electrode TE.

According to one of the hardware-based integration method, the software-based integration method, and the hybrid integration method (i.e., an integration method that mixes the hardware-based integration method and the software-based integration method), the sub-touch electrodes arranged in one touch pixel area TP can form one touch electrode TE.

According to the hardware-based integration method, the sub-touch electrodes STE arranged in one touch pixel area TP can be electrically connected by at least one connection pattern arranged on the substrate. In this case, one sensing data for the sub-touch electrodes STE arranged in one touch pixel area TP can be generated as sensing data for one touch electrode TE by one of the plurality of drivers DRV arranged in one touch pixel area TP, and can be supplied to the touch control circuit (see FIG. 17). The touch control circuit can perform a touch algorithm based on the sensing data for each touch electrode TE. Here, at least one connection pattern can exist outside the plurality of drivers DRV disposed in one touch pixel area TP.

According to the hardware-based integration method, sensing data for one touch sub-pixel area TSP is not generated separately, and sensing data for one touch electrode (i.e., sensing data for one touch pixel area TP) can be generated by one of the plurality of drivers DRV disposed in one touch pixel area TP.

According to the software-based integration method, each of the plurality of drivers DRV arranged in one touch pixel area TP can sense the sub-touch electrodes STE(1) to STE(2n) arranged in one touch pixel area TP to generate sensing data, and supply the sensing data to the touch control circuit. The touch control circuit can integrate the plurality of sensing data supplied for each touch pixel area TP, generate sensing data for each touch electrode TE, and perform a touch algorithm based on the sensing data for each touch electrode TE.

According to the software-based integration method, sensing data for one touch sub-pixel area TSP is not generated separately, and sensing data for one touch electrode TE (i.e., sensing data for one touch pixel area TP) can be generated at once by the touch control circuit according to the data integration method. Here, the software-based integration method can also be referred to as a full data integration method.

According to the hybrid integration method, the sub-touch electrodes STE(1) to STE(2n) arranged in each of the plurality of touch sub-pixel areas TSP included in one touch pixel area TP can be electrically connected by at least one connection pattern. The driver DRV of each of the plurality of touch sub-pixel areas TSP can generate one sensing data (i.e., sensing data for the touch sub-pixel area TSP) for the sub-touch electrodes STE(1) to STE(2n) arranged in the corresponding touch sub-pixel area TSP, and supply it to the touch control circuit (e.g., hardware method). The touch control circuit can integrate sensing data for each touch sub-pixel area TSP to generate sensing data for each touch pixel area TP.

According to the hybrid integration method, sensing data for one touch sub-pixel area TSP can be generated once by the driver DRV of one touch sub-pixel area TSP according to the hardware method, and sensing data for one touch electrode TE (i.e., sensing data for one touch pixel area TP) can be generated by the touch control circuit according to the data integration method. Here, the hybrid integration method can be referred to as a half data integration method. At least one connection pattern can exist outside of a plurality of drivers DRV disposed in one touch pixel area TP.

Referring to FIG. 23 and FIG. 24, the display driving structure and the touch sensor structure (e.g., touch driving structure) included in the display panel 110 can be associated with each other.

For display driving, the display area DA of the display panel 110 can include a plurality of unit driving areas UDA corresponding to a plurality of drivers DRV. The plurality of unit driving areas UDA can correspond to a plurality of touch sub-pixel areas TSP for touch driving.

The plurality of unit driving areas UDA can include a first unit driving area UDA corresponding to a first driver DRV among the plurality of drivers DRV. The plurality of unit driving areas UDA can correspond to a plurality of touch sub-pixel areas TSP, and a first unit driving area UDA can be a first touch sub-pixel area TSP.

The first unit driving area UDA can include two or more row lines RL(1) to RL(2n) electrically connected to the first driver DRV among the plurality of row lines RL, and two or more column lines CLa_M, CLa_R, CLb_M, CLb_R, CLc_M and CLc_R electrically connected to the first driver DRV among the plurality of column lines CL. Here, the two or more column lines CLa_M, CLa_R, CLb_M, CLb_R, CLc_M and CLc_R can be column lines according to the redundancy structure illustrated in FIG. 11.

The first unit driving area UDA can include a plurality of light emitting devices EDa_M, EDa_R, EDb_M, EDb_R, EDc_M and EDc_R connected to two or more row lines RL(1) to RL(2n) and two or more column lines CLa_M, CLa_R, CLb_M, CLb_R, CLc_M and CLc_R. Here, the plurality of light emitting devices EDa_M, EDa_R, EDb_M, EDb_R, EDc_M and EDc_R can be light emitting devices according to the redundancy structure illustrated in FIG. 11.

Each of two or more column lines CLa_M, CLa_R, CLb_M, CLb_R, CLc_M and CLc_R arranged in the first unit driving area UDA can be electrically connected in common with a first electrode (e.g., an anode electrode or a cathode electrode) of two or more light emitting devices EDa_M, EDa_R, EDb_M, EDb_R, EDc_M and EDc_R arranged in the same column among the plurality of light emitting devices ED.

Each of two or more row lines RL(1) to RL(2n) arranged in the first unit driving area UDA can be electrically connected in common with a second electrode (e.g., a cathode electrode or an anode electrode) of two or more light emitting devices EDa_M, EDa_R, EDb_M, EDb_R, EDc_M and EDc_R arranged in the same row among the plurality of light emitting devices ED.

The touch sensor TS can include a plurality of touch electrodes TE. Each of the plurality of touch electrodes TE can include a plurality of sub-touch electrodes STE. The first unit driving area UDA can further include two or more sub-touch electrodes STE(1) to STE(2n) electrically connected to the first driver DRV among the plurality of sub-touch electrodes STE. Here, two or more sub-touch electrodes STE(1) to STE(2n) electrically connected to the first driver DRV can be disposed in the first unit driving area UDA where the first driver DRV is disposed.

In the first unit driving area UDA, two or more sub-touch electrodes STE(1) to STE(2n) and two or more row lines RL(1) to RL(2n) can be arranged alternately. Accordingly, in the first touch sub-pixel area TSP which is the first unit driving area UDA, two or more sub-touch electrodes STE(1) to STE(2n) can be evenly arranged, so that the touch sensitivity can be improved.

For example, in the first unit driving area UDA, the shape of each of the two or more sub-touch electrodes STE(1) to STE(2n) and the shape of each of the two or more row lines RL(1) to RL(2n) can correspond. For example, in the first unit driving area UDA, the shape of each of the two or more sub-touch electrodes STE(1) to STE(2n) and the shape of each of the two or more row lines RL(1) to RL(2n) can be a bar shape.

In the first unit driving area UDA, a length of each of the two or more sub-touch electrodes STE(1) to STE(2n) can correspond to a length of each of the two or more row lines RL(1) to RL(2n).

In the first unit driving area UDA, each of two or more sub-touch electrodes STE(1) to STE(2n) can be arranged in parallel with each of two or more row lines RL(1) to RL(2n).

The display panel 110 can further include at least one sub-touch line STL arranged in each of a plurality of touch sub-pixel areas TSP.

As an example, the display panel 110 can include two or more sub-touch lines STL that electrically connect each of two or more sub-touch electrodes STE(1) to STE(2n) to the first driver DRV within one touch sub-pixel area TSP that is the first unit driving area UDA.

In this case, within one touch sub-pixel area TSP which is the first unit driving area UDA, each of two or more sub-touch lines STL can be electrically connected to one of two or more sub-touch electrodes STE(1) to STE(2n) through a contact hole CNT.

Referring to FIG. 23, within one touch sub-pixel area TSP which is the first unit driving area UDA, at least one of two or more sub-touch lines STL can overlap with at least one of two or more row lines RL(1) to RL(2n).

Referring to FIG. 24, within one touch sub-pixel area TSP which is the first unit driving area UDA, at least one of two or more sub-touch lines STL can overlap with at least one of two or more sub-touch electrodes STE(1) to STE(2n).

As another example, referring to FIG. 24, the display panel 110 according to the embodiments of the present disclosure can further include one sub-touch line STL that electrically connects two or more sub-touch electrodes STE(1) to STE(2n) to the first driver DRV.

In this case, within one touch sub-pixel area TSP which is the first unit driving area UDA, one sub-touch line STL can be electrically commonly connected to two or more sub-touch electrodes STE(1) to STE(2n) through two or more contact holes CNT.

Within one touch sub-pixel area TSP which is the first unit driving area UDA, one sub-touch line STL can overlap with at least one of two or more row lines RL(1) to RL(2n).

Within one touch sub-pixel area TSP which is a first unit driving area UDA, one sub-touch line STL can overlap with two or more sub-touch electrodes STE(1) to STE(2n).

Referring to FIGS. 23 and 24, one touch sub-pixel area TSP, which is a first unit driving area UDA, can include a first sub-touch driving area SLC1 and a second sub-touch driving area SLC2. For example, the first sub-touch driving area SLC1 can correspond to an upper area in one touch sub-pixel area TSP, and the second sub-touch driving area SLC2 can correspond to a lower area in one touch sub-pixel area TSP, but is not limited thereto.

For example, the first sub-touch driving area SLC1 can include n row lines RL(1) to RL(n) and n sub-touch electrodes STE(1) to STE(n), and the second sub-touch driving area SLC2 can include n row lines RL(n+1) to RL(2n) and n sub-touch electrodes STE(n+1) to STE(2n).

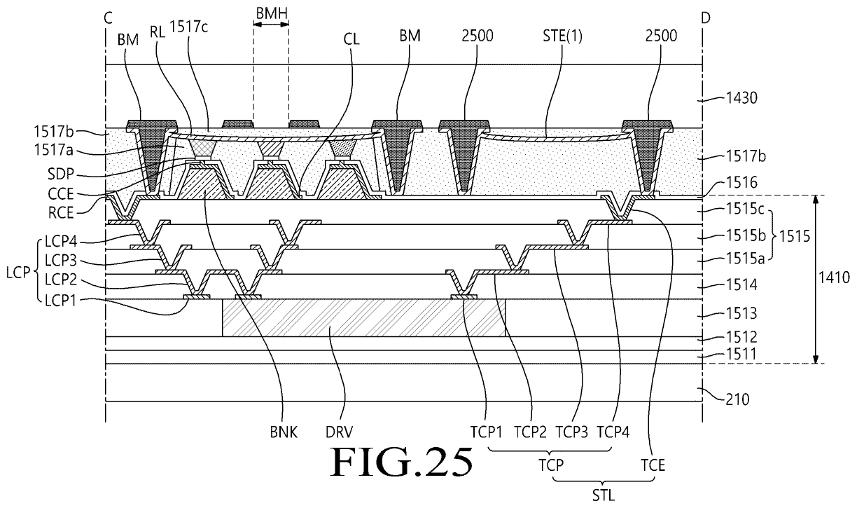

Hereinafter, the touch sensor structure according to the embodiments of the present disclosure described above will be described through a cross-sectional view of FIG. 25. FIG. 25 is a cross-sectional view taken along the line C-D of FIG. 23. In the following description, FIGS. 1 to 24 are also referred to together.

FIG. 25 is a cross-sectional view illustrating the touch sensor structure of the display panel 110 according to the embodiments of the present disclosure.

Referring to FIG. 25, the display panel 110 according to the embodiments of the present disclosure can include a substrate 210, a layer stack 1410 disposed on the substrate 210, a plurality of light emitting devices EDa, EDb and EDc disposed on the layer stack 1410, a row line RL disposed on the plurality of light emitting devices EDa, EDb and EDc, a sub-touch electrode STE(1) disposed within the same metal layer as the plurality of row lines RL, and an overcoat layer 1430 disposed on the row line RL and the sub-touch electrode STE(1).

The display panel 110 can further include a driver DRV disposed between the substrate 210 and the plurality of light emitting devices EDa, EDb and EDc.

The display panel 110 can further include an optical layer 1420 surrounding a plurality of light emitting devices EDa, EDb and EDc, an adhesive layer 1440 disposed on an overcoat layer 1430, and a cover member 118 disposed on the adhesive layer 1440.

The layer stack 1410 can further include a side protection layer 1513 disposed on each side of a plurality of drivers DRV, an upper protection layer 1514 disposed on the plurality of drivers DRV and the side protection layer 1513, an insulating layer 1515 disposed on the upper protection layer 1514, and a bank BNK disposed on the insulating layer 1515.

The plurality of light emitting devices EDa, EDb and EDc can be disposed on the bank BNK. For example, the bank BNK can correspond to the arrangement position of the plurality of light emitting devices EDa, EDb and EDc. In this way, since the upper surface of the bank BNK becomes the arrangement position (or settlement position) of the plurality of light emitting devices EDa, EDb and EDc, the plurality of light emitting devices ED can be accurately transferred to a desired position during the transfer process for panel manufacturing.

The side protection layer 1513 can include at least one organic layer. Accordingly, the driver DRV can be stably positioned at the correct position without falling over or moving.

The layer stack 1410 can further include a buffer layer 1511 disposed on the substrate 210 and an adhesive layer 1512 disposed on the buffer layer 1511. The driver DRV can be disposed on the adhesive layer 1512.

The optical layer 1420 can include a first optical layer 1517a surrounding a plurality of light emitting devices EDa, EDb and EDc and a bank BNK, and a second optical layer 1517b disposed on a side of the first optical layer 1517a.

The first optical layer 1517a can include light scattering particles. For example, the first optical layer 1517a can be composed of siloxane having fine metal particles, such as titanium dioxide (TiO₂) particles, dispersed therein. Light from a plurality of light emitting devices EDa, EDb and EDc can be scattered by fine particles dispersed in the first optical layer 1517a and emitted to the outside of the display device 100. Accordingly, the first optical layer 1517a can improve the extraction efficiency of light emitted from the plurality of light emitting devices EDa, EDb and EDc.

The plurality of row lines RL can be arranged on the first optical layer 1517a.

The optical layer 1420 can further include a third optical layer 1517c disposed on the plurality of row lines RL.

The third optical layer 1517c can overlap with the plurality of light emitting devices EDa, EDb and EDc, and can include light scattering particles. For example, the third optical layer 1517c can be composed of siloxane having fine metal particles, such as titanium dioxide (TiO₂) particles, dispersed therein. Light from the plurality of light emitting devices EDa, EDb and EDc can be scattered by the fine particles dispersed in the third optical layer 1517c and emitted to the outside of the display device 100. Accordingly, the third optical layer 1517c can improve the extraction efficiency of light emitted from the plurality of light emitting devices EDa, EDb and EDc.

Each of the plurality of column lines CL can be arranged on the insulating layer 1515 and can extend along the side of the bank BNK to the upper portion of the bank BNK.

The display panel 110 can further include a row connection electrode RCE disposed on an insulating layer 1515 and electrically connected to a row line RL, and a black matrix BM disposed on an optical layer 1420.

The black matrix BM can have a plurality of openings BMH overlapping with a plurality of light emitting devices EDa, EDb and EDc.

Each of the plurality of row lines RL can be electrically connected to the row connection electrode RCE through a contact hole of a second optical layer 1517b included in the optical layer 1420.

For example, at least a portion of the black matrix BM can be inserted into the contact hole of the second optical layer 1517b included in the optical layer 1420.

Each of the plurality of column lines CL can be arranged on the insulating layer 1515 and can extend along the side of the bank BNK and be electrically connected to the first electrode of the corresponding light emitting device EDa, EDb and EDc located on the upper side of the bank BNK.

Each of the plurality of column lines CL can be electrically connected to the first electrode of the plurality of light emitting devices EDa, EDb and EDc through a column connection electrode CCE. For example, the column connection electrode CCE can be formed integrally with the column line CL. For another example, the column connection electrode CCE can be electrically connected to the column line CL but can be a different electrode from the column line CL.

The column connection electrode CCE can include a reflective electrode or a reflective material. As a result, light emitted from the light emitting device EDa, EDb and EDc can be reflected by the column connection electrode CCE and emitted upward. Accordingly, the extraction efficiency of light emitted from the light emitting devices EDa, EDb and EDc can be improved.

Each of the first electrodes of the plurality of light emitting devices EDa, EDb and EDc can be electrically connected to the column connection electrode CCE through a solder pattern SDP. The solder pattern SDP can be located on the bank BNK, and can be located in the opening of a passivation layer 1516.

Each of the plurality of row lines RL can be arranged on the first optical layer 1517a and can be electrically connected to the second electrode of each of the plurality of light emitting devices ED exposed through the opening of the first optical layer 1517a. Each of the plurality of row lines RL can overlap with the plurality of light emitting devices EDa, EDb and EDc.

For example, the insulating layer 1515 can include first to third insulating layers 1515a, 1515b and 1515c. Various metal layers can be formed through the upper protection layer 1514 and the first to third insulating layers 1515a, 1515b and 1515c.

The layer stack 1410 can further include a passivation layer 1516 disposed on the insulating layer 1515 while covering the bank BNK.

The display panel 110 can further include a line connection pattern LCP that electrically connects each of the plurality of row lines RL to one of the plurality of drivers DRV or electrically connects each of the plurality of column lines CL to one of the plurality of drivers DRV. The line connection pattern LCP can include first to fourth line connection patterns LCP1 to LCP4. The configuration thereof has been described in FIG. 15.

The display panel 110 can further include a sub-touch line STL for connection between the sub-touch electrode STE(1) and the driver DRV.

The sub-touch line STL can include a touch connection electrode TCE electrically connected to a sub-touch electrode STE(1) included in a touch sensor TS and disposed on an insulating layer 1515, and a touch connection pattern TCP that electrically connects the touch connection electrode TCE to one of a plurality of drivers DRV.

For example, the touch connection pattern TCP can include a first touch connection pattern TCP1 disposed on a side protection layer 1513, a second touch connection pattern TCP2 disposed on an upper protection layer 1514 and electrically connected to the first touch connection pattern TCP1 through a hole in the upper protection layer 1514, a third touch connection pattern TCP3 disposed on a first insulating layer 1515a and electrically connected to the second touch connection pattern TCP2 through a hole in the first insulating layer 1515a, and a fourth touch connection pattern TCP4 disposed on a second insulating layer 1515b and electrically connected to the third touch connection pattern TCP3 through a hole in the second insulating layer 1515b.

The first touch connection pattern TCP1 can be electrically connected to a driver DRV. The fourth touch connection pattern TCP4 can be electrically connected to the touch connection electrode TCE.

The touch connection electrode TCE can be disposed on the third insulating layer 1515c and can be electrically connected to the fourth touch connection pattern TCP4 through a hole of the third insulating layer 1515c. For example, the touch connection electrode TCE can include the same material as the plurality of column lines CL.

The sub-touch electrode STE(1) can be disposed on the second optical layer 1517b and can be electrically connected to the touch connection electrode TCE through a hole of the second optical layer 1517b and the passivation layer 1516.

The black matrix BM can also be disposed in a contact hole area for connection between the sub-touch electrode STE(1) and the touch connection electrode TCE.

The display panel 110 can further include a partition 2500 disposed between the sub-touch electrode STE(1) included in the touch sensor TS and the plurality of light emitting devices EDa, EDb and EDc.

For example, the partition 2500 can be disposed by being inserted into a hole of the second optical layer 1517b. The partition 2500 can include the same material as the black matrix BM.

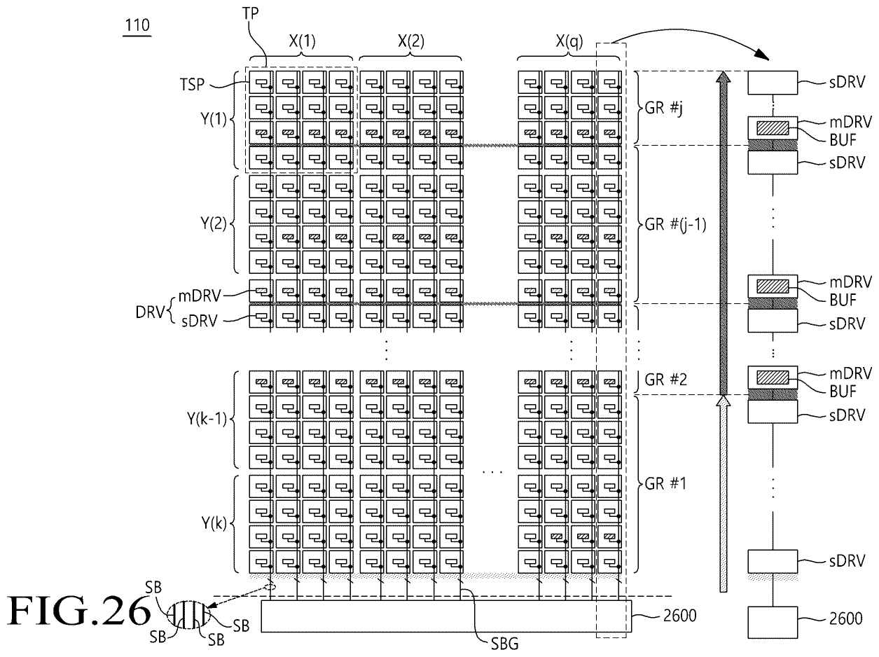

FIG. 26 illustrates a connection structure of drivers DRV in the display panel 110 according to embodiments of the present disclosure.

Referring to FIG. 26, the display panel 110 can include a plurality of touch pixel areas TP, and each of the plurality of touch pixel areas TP can include a plurality of touch sub-pixel areas TSP. Each of the plurality of touch sub-pixel areas TSP can include at least one driver DRV.

For example, the display panel 110 can include (k×q) touch pixel areas TP arranged in k rows Y(1) to Y(k) (where k is a natural number greater than or equal to 2) and q columns X(1) to X(q) (where q is a natural number greater than or equal to 2). Each of the (k×q) touch pixel areas TP can include 16 touch sub-pixel areas TSP arranged in 4 rows and 4 columns. Each of the 16 touch sub-pixel areas TSP can include one driver DRV.

The display device 100 can include a plurality of drivers DRV for driving a plurality of sub-touch electrodes STE and a plurality of light emitting devices ED, and a controller 2600 for controlling the plurality of drivers DRV. As an example, the controller 2600 can include the touch control circuit 1700 of FIG. 17. As another example, the controller 2600 can include a timing controller and can further include a power management integrated circuit.

As an example, for display driving, each of the plurality of drivers DRV can drive a plurality of light emitting devices ED arranged in a corresponding touch sub-pixel area TSP according to the control of the controller 2600. As another example, for touch driving, each of the plurality of drivers DRV can drive a plurality of sub-touch electrodes STE arranged in a corresponding touch sub-pixel area TSP according to the control of the controller 2600.

For display driving and/or touch driving, the controller 2600 can supply various signals to the plurality of drivers DRV. As an example, for display driving, the controller 2600 can supply voltages or control signals related to display driving to the plurality of drivers DRV. As another example, for touch driving, the controller 2600 can supply a touch driving signal or a touch control signal to a plurality of drivers DRV.

For display driving and/or touch driving, each of the plurality of drivers DRV can supply various signals to the controller 2600. As an example, for touch driving, each of the plurality of drivers DRV can supply a signal including sensing data to the controller 2600.

Signal transmission from the controller 2600 to the plurality of drivers DRV can be referred to as downward signal transmission, and signal transmission from the plurality of drivers DRV to the controller 2600 can be referred to as upward signal transmission. In this disclosure, signal transmission can also be referred to as signal sharing.

For display driving and/or touch driving, the display panel 110 according to the embodiments of the present disclosure can include a plurality of signal bus groups SBG for signal transmission between the controller 2600 and the plurality of drivers DRV.

Each of the plurality of signal bus groups SBG can include a plurality of signal buses SB. Each of the plurality of signal bus groups SBG can be arranged to correspond to one touch sub-pixel area column. For example, one signal bus group SBG can be arranged to correspond to one touch sub-pixel area column. Each of the plurality of signal bus groups SBG can be connected to a plurality of drivers DRV arranged in one touch sub-pixel area column.

For example, the display panel 110 can include (4×q) signal bus groups SBG. Each of the (4×q) signal bus groups SBG can include four signal buses SB. Each of the (4×q) signal bus groups SBG can be arranged to correspond to one touch sub-pixel area column. Each of the (4×q) signal bus groups SBG can be connected to (4×k) drivers DRV arranged in one touch sub-pixel area column.

The controller 2600 can supply various signals for touch driving to a plurality of drivers DRV arranged in one touch sub-pixel area column through each of a plurality of signal bus groups SBG. For example, the controller 2600 can supply a touch driving signal TDS to a plurality of drivers DRV disposed in one touch sub-pixel area column through each of a plurality of signal bus groups SBG.

A signal output from the controller 2600 can be transmitted to a plurality of drivers DRV connected to the signal bus SB via the signal bus SB. For example, a signal output from the controller 2600 can be transmitted to a plurality of drivers DRV according to a cascade method. A signal output from the controller 2600 can be first input to a first driver DRV closest to the controller 2600 via the signal bus SB. A signal input to the first driver DRV can be re-output from the first driver DRV and re-input to a second driver DRV second closest to the controller 2600 via the signal bus SB. A signal input to the second driver DRV can be re-output from the second driver DRV and re-input to a third driver DRV third closest to the controller 2600 via the signal bus SB. In this manner, a signal output from the controller 2600 can be transmitted to the last driver DRV.

A signal (e.g., sensing data) output from one of the plurality of drivers DRV can be transmitted to the controller 2600 via the signal bus SB. For example, a signal output from one of the plurality of drivers DRV can be directly input to the controller 2600 via the signal bus SB. For another example, a signal output from one of the plurality of drivers DRV can be input to the controller 2600 via the signal bus SB through at least one driver DRV.

If the length of one signal bus SB is large, the strength of the signal can be attenuated during the process of transmitting the signal via one signal bus SB. If signal attenuation occurs, touch sensing performance and/or display driving performance can be degraded.

Accordingly, all or some of the plurality of drivers DRV can include a signal amplification circuit BUF for amplifying the signal intensity. A driver DRV that performs a signal amplification function through a signal amplification circuit BUF can be referred to as a main driver mDRV, and a driver DRV that does not perform a signal amplification function can be referred to as a sub-driver sDRV.

As an example, signal amplification can be performed in all of the plurality of drivers DRV on the signal transmission path. As another example, signal amplification can be performed in only some of the plurality of drivers DRV on the signal transmission path. Hereinafter, a case in which signal amplification is performed in only some of the plurality of drivers DRV on the signal transmission path will be described in more detail.

A plurality of touch sub-pixel areas TSP arranged on the display panel 110 can be grouped into a plurality of groups GR #1 to GR #j (where j is a natural number greater than or equal to 2) based on signal amplification. In one touch sub-pixel area column, each of the plurality of groups GR #1 to GR #j can include a predetermined number of drivers DRV. For example, the predetermined number can mean the group size and can be a natural number greater than or equal to 2.

As an example, based on one touch sub-pixel area column, each of the plurality of groups GR #1 to GR #j can include the same number of drivers DRV. For example, each of the plurality of groups GR #1 to GR #j can include five drivers DRV.

As another example, based on one touch sub-pixel area column, at least one group among the plurality of groups GR #1 to GR #j can include a different number of drivers DRV from the remaining groups. For example, as in the example of FIG. 26, among the plurality of groups GR #1 to GR #j, a first group GR #1 that is closest to the controller 2600 among the plurality of groups GR #1 to GR #j can include seven drivers DRV, a (j−1)-th group GR #(j−1) can include six drivers DRV, and a j-th group GR #j that is located farthest from the controller 2600 among the plurality of groups GR #1 to GR #j can include three drivers DRV.

Among the drivers DRV included in each of the plurality of groups GR #1 to GR #j, the driver DRV that is closest to the controller 2600 can be a main driver mDRV that performs a signal amplification function, and the remaining drivers DRV can be sub-drivers sDRV that do not perform a signal amplification function.

All of the drivers DRV included in a first group GR #1 can be sub-drivers sDRV. In this case, the first group GR #1 can correspond to a path through which a signal that has not been amplified is transmitted, and a second group GR #2 to a j-th group GR #j can correspond to a path through which a signal that has been amplified is transmitted.

If the main driver mDRV receives a signal, the main driver mDRV can amplify the signal intensity of the input signal and output a signal having the amplified signal intensity to the sub-driver sDRV located in the next order on the signal transmission path. If the sub-driver sDRV receives a signal, the sub-driver sDRV can output the input signal to the sub-driver sDRV or the main driver mDRV located in the next order on the signal transmission path without a signal amplification operation.

According to the signal transmission and signal sharing utilizing the above-described signal bus structure, it is possible to significantly reduce the number of lines to be arranged on the display panel 110. As a result, the structure of the display panel 110 can be simplified, and the process of the display panel 110 can also be simplified.

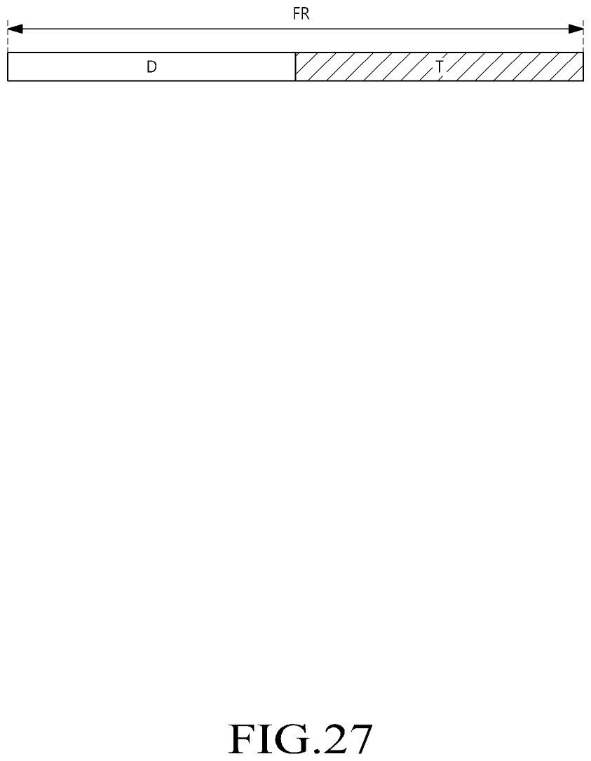

FIGS. 27 to 29 are driving timing diagrams of the display device 100 according to embodiments of the present disclosure.

Referring to FIGS. 27 to 29, the display device 100 according to the embodiments of the present disclosure can perform display driving for image display and touch driving (e.g., touch sensing driving) for touch sensing.

The display device 100 according to the embodiments of the present disclosure can allocate a display driving period D and a touch driving period T, perform display driving during the display driving period D, and perform touch driving during the touch driving period T.

The display driving period D and the touch driving period T can temporally overlap with each other or be separated from each other. For example, the display device 100 according to the embodiments of the present disclosure can perform display driving and touch driving according to a simultaneous driving method (or an independent driving method) or a time-division driving method.

As an example, the display device 100 according to the embodiments of the present disclosure can perform display driving and touch driving simultaneously or independently. This driving can be referred to as a simultaneous driving or an independent driving. In this case, the display device 100 according to the embodiments of the present disclosure can allocate the display driving period D and the touch driving period T to overlap in time or allocate the display driving period D and the touch driving period T independently in time, perform display driving during the display driving period D, and perform touch driving during the touch driving period T.

As another example, the display device 100 according to the embodiments of the present disclosure can perform display driving and touch driving at different time periods. Such driving can be referred to as time-division driving. In this case, the display device 100 according to the embodiments of the present disclosure can divide the entire driving time into the display driving period D and the touch driving period T, perform display driving during the display driving period D, and perform touch driving during the touch driving period T.

Referring to FIG. 27, as an example of the time-division driving method, one frame period FR can be divided into one display driving period D and one touch driving period T.

Within one frame period FR, the display device 100 can perform display driving for displaying an image (e.g., one frame or one frame image) on the entire area of the display panel 110 during one display driving period D, and can perform touch driving for sensing a touch on the entire area of the display panel 110 during one touch driving period T.

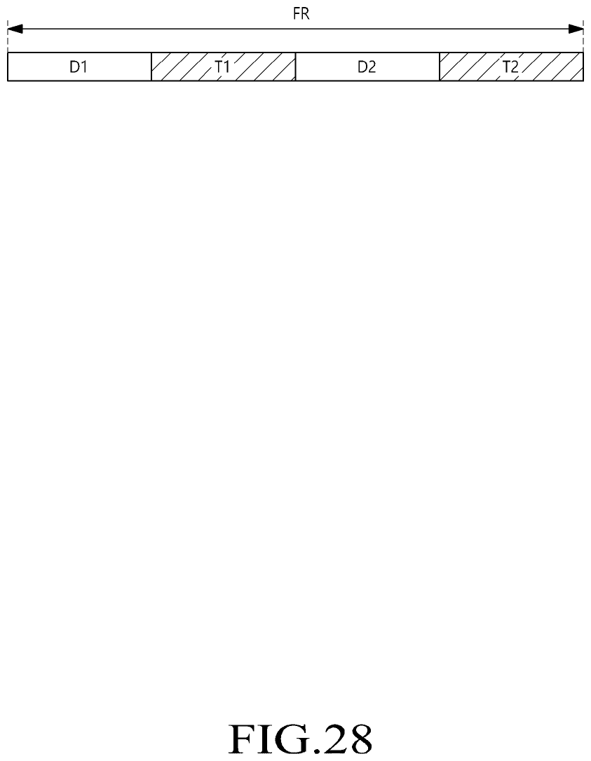

Referring to FIG. 28, as another example of a time-division driving method, one frame period FR can be divided into two display driving periods D1 and D2, and two touch driving periods T1 and T2. The display driving periods D1 and D2 and the touch driving periods T1 and T2 can be alternated. For example, a first display driving period D1, a first touch driving period T1, a second display driving period D2, and a second touch driving period T2 can be performed in that order.

The entire area of the display panel 110 can be divided into two divided areas. For example, both divided areas can have the same size (or area). For example, the area of each of the two divided areas can be ½ of the area of the entire area. The divided image displayed in each of the two divided areas can correspond to ½ of the entire image displayed in the entire area.

Within one frame period FR, the display device 100 can perform display driving for displaying a first segmented image (e.g., half of one frame or half of one frame image) in a first area (e.g., half of the entire area) of the entire area of the display panel 110 during a first display driving period D1, perform touch driving for sensing a touch in a first area (e.g., half of the entire area) of the entire area of the display panel 110 during a first touch driving period T1, perform display driving for displaying a second segmented image (e.g., the remaining half of one frame or the remaining half of one frame image) in a second area (e.g., the remaining half of the entire area) of the entire area of the display panel 110 during a second display driving period D2, and perform touch driving for sensing a touch in a second area (e.g., the remaining half of the entire area) of the entire area of the display panel 110 during a second touch driving period T2.

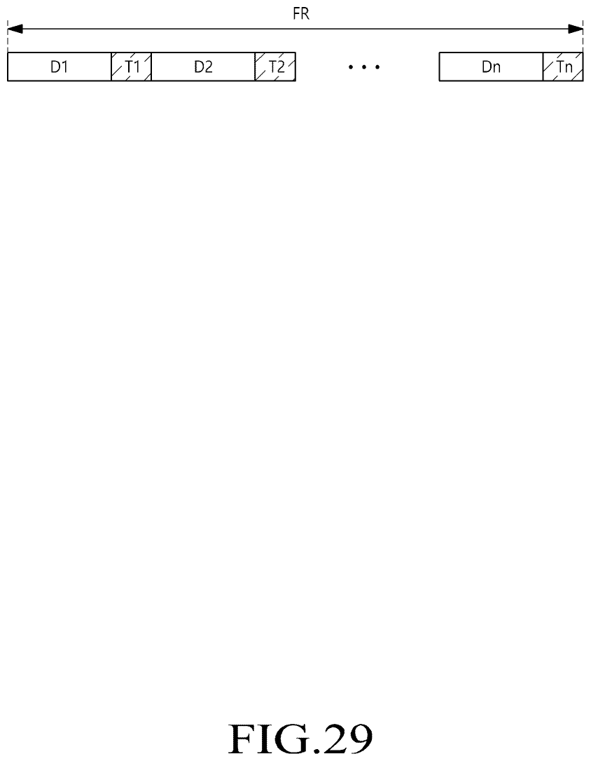

Referring to FIG. 29, as another example of the time-division driving method, one frame period FR can be divided into n display driving periods D1 to Dn (n is a natural number greater than or equal to 2) and n touch driving periods T1 to Tn (n is a natural number greater than or equal to 2). The display driving periods D1 to Dn and the touch driving periods T1 to Tn can be alternated. For example, the first display driving period D1, the first touch driving period T1, the second display driving period D2, the second touch driving period T2, . . . , the n-th display driving period Dn, and the n-th touch driving period Tn can be performed in this order.

The entire area of the display panel 110 can be divided into n divided areas. For example, all n divided areas can have the same size (or area). For example, the area of each of the n divided areas can be 1/n of the area of the entire area. The segmented image displayed in each of the n divided areas can correspond to 1/n of the total image displayed in the entire area.

Within one frame period FR, the display device 100 can perform display driving for displaying a first divided image in a first divided area of the entire area of the display panel 110 during a first display driving period D1, perform touch driving for sensing a touch in a first divided area (e.g., 1/n of the entire area) of the entire area of the display panel 110 during a first touch driving period T1, perform display driving for displaying a second divided image in a second divided area of the entire area of the display panel 110 during a second display driving period D2, perform touch driving for sensing a touch in a second divided area (e.g., 1/n of the total area) of the entire area of the display panel 110 during the second touch driving period T2, perform display driving for displaying an n-th divided image in an n-th divided area of the entire area of the display panel 110 during the n-th display driving period Dn, and perform touch driving for sensing a touch in an n-th divided area (e.g., 1/n of the total area) of the entire area of the display panel 110 during the n-th touch driving period Tn.

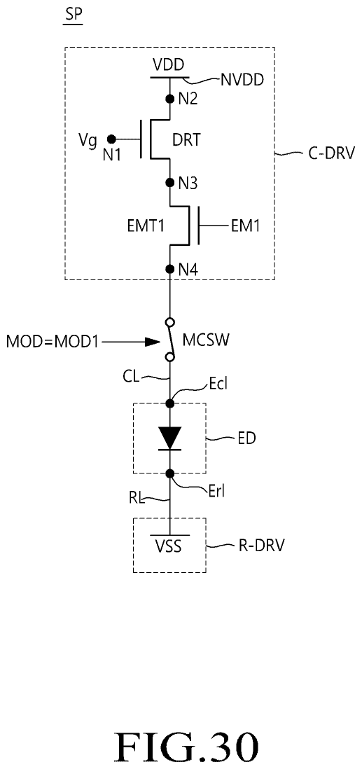

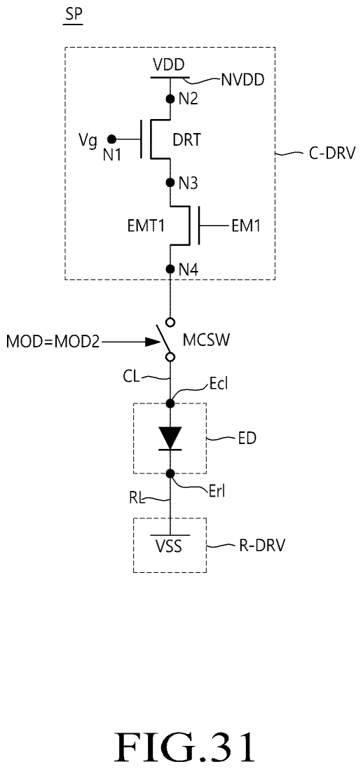

FIG. 30 and FIG. 31 illustrate the state of a sub-pixel according to the operation mode of the display device 100 according to the embodiments of the present disclosure.

Particularly, FIG. 30 illustrates the state of a sub-pixel when the display device 100 according to the embodiments of the present disclosure is in a display mode, and FIG. 31 illustrates the state of a sub-pixel when the display device 100 according to the embodiments of the present disclosure is in a touch mode. The equivalent circuits illustrated in FIG. 30 and FIG. 31 can correspond to the equivalent circuit of FIG. 5. Accordingly, the description of the equivalent circuit can be omitted or may be briefly provided. For example, the description of the internal circuit configuration of each of the column driver C-DRV and the row driver R-DRV can be omitted.

Referring to FIGS. 30 and 31, in the case that the display device 100 operates according to the time-division driving method, during the display driving period D, the operating mode of the display device 100 can be a first mode (e.g., display mode), and during the touch driving period T, the operating mode of the display device 100 can be a second mode (e.g., touch mode).

As described above, each of the plurality of sub-pixels SP can include a light emitting device ED.

In order to drive each of the plurality of light emitting devices ED, a first driver DRV can include a column driver C-DRV electrically connected to the first electrode of each of the plurality of light emitting devices ED, and a row driver R-DRV electrically connected to the second electrode of each of the plurality of light emitting devices ED. At least one of the column driver C-DRV and the row driver R-DRV can be circuit configurations included in the sub-pixel SP.

During touch driving, if the light emitting device ED is in a state capable of emitting light (e.g., on-state), the voltage state of the touch sensor TS can be affected by the voltage state of the display driving related configurations (e.g., the light emitting device, the row lines, the column lines, etc.). As a result, the touch sensitivity can be degraded.

Accordingly, the display device 100 according to the embodiments of the present disclosure can further include a mode control switch MCSW that controls the connection between the first electrode of each of the plurality of light emitting devices ED and the column driver C-DRV according to a mode control signal MOD.

Referring to FIG. 30, if the mode control signal MOD is a first mode control signal MOD1, the mode control switch MCSW can be turned on. Accordingly, during the display driving period D, the column driver C-DRV and the light emitting device ED can be connected to each other, so that the light emitting device ED can normally emit light.

Referring to FIG. 31, if the mode control signal MOD is a second mode control signal MOD2 different from the first mode control signal MOD1, the mode control switch MCSW can be turned off. Accordingly, during the touch driving period T, the connection between the column driver C-DRV and the light emitting device ED can be disconnected, so that the light emitting device ED can be in an off state (e.g., non-emission state) and does not affect the touch sensor TS.

Referring to FIGS. 30 and 31, the first mode control signal MOD1 can be a signal indicating that the operation mode is the first mode (e.g., display mode). The second mode control signal MOD2 can be a signal indicating that the operation mode is the second mode (e.g., touch mode). For example, the first mode control signal MOD1 and the second mode control signal MOD2 can be signals having different voltage levels.

Referring to FIG. 30, if the mode control switch MCSW is in a turn-on state, for example, if the mode control signal MOD is the first mode control signal MOD1, a signal having a constant voltage level can be applied to the touch sensor TS. For example, the touch sensor TS can be in a state in which the touch driving signal TDS is not applied.

Referring to FIG. 31, if the mode control switch MCSW is in a turn-off state, for example, if the mode control signal MOD is the second mode control signal MOD2, a signal having a variable voltage level can be applied to the touch sensor TS. For example, the touch sensor TS can be in a state in which the touch driving signal TDS is applied.

The display device 100 according to the embodiments of the present disclosure described above can be included in various devices or electronic devices. For example, various electronic devices can include wearable devices such as smart watches, mobile devices, laptops, and monitors or televisions (TV).

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present invention. The above description and the accompanying drawings provide an example of the technical idea of the present invention for illustrative purposes only. For example, the disclosed embodiments are intended to illustrate the scope of the technical idea of the present invention.

What is claimed is:

1. A display device comprising:
a substrate;
a plurality of light emitting devices disposed on the substrate and located in a display area;
a plurality of column lines electrically connected to a first electrode of each of the plurality of light emitting devices;
a plurality of row lines electrically connected to a second electrode of each of the plurality of light emitting devices;
a touch sensor disposed in a same metal layer as the plurality of row lines;
an overcoat layer disposed on the plurality of light emitting devices, the plurality of row lines, and the touch sensor; and
a plurality of drivers disposed on the substrate, and configured to drive the plurality of light emitting devices and drive or sense the touch sensor.

2. The display device of claim 1, wherein the plurality of drivers are disposed in the display area.

3. The display device of claim 1, wherein the plurality of drivers are disposed between the substrate and the plurality of light emitting devices.

4. The display device of claim 1, further comprising:
an adhesive layer disposed on the overcoat layer; and
a cover member disposed on the adhesive layer.

5. The display device of claim 1, wherein each of the plurality of row lines overlaps with two or more of the plurality of light emitting devices,
wherein the touch sensor does not overlap with the plurality of light emitting devices.

6. The display device of claim 1, wherein the display area includes a plurality of unit driving areas corresponding to the plurality of drivers,
wherein the plurality of unit driving areas include a first unit driving area corresponding to a first driver among the plurality of drivers,
wherein the first unit driving area comprises:
two or more row lines electrically connected to the first driver, among the plurality of row lines; and
two or more column lines electrically connected to the first driver, among the plurality of column lines,
wherein each of the two or more column lines is electrically connected to first electrodes of two or more light emitting devices arranged in a same column, among the plurality of light emitting devices, and
wherein each of the two or more row lines is electrically connected to second electrodes of two or more light emitting devices arranged in a same row, among the plurality of light emitting devices.

7. The display device of claim 6, wherein the touch sensor includes a plurality of touch electrodes,
wherein each of the plurality of touch electrodes includes a plurality of sub-touch electrodes,
wherein the first unit driving area further includes two or more sub-touch electrodes electrically connected to the first driver, among the plurality of sub-touch electrodes, and
wherein, in the first unit driving area, the two or more sub-touch electrodes and the two or more row lines are arranged alternately.

8. The display device of claim 7, wherein a length of each of the two or more sub-touch electrodes corresponds to a length of each of the two or more row lines.

9. The display device of claim 7, further comprising two or more sub-touch lines electrically connecting each of the two or more sub-touch electrodes to the first driver, and
wherein, in the first unit driving area, each of the two or more sub-touch lines is electrically connected to one of the two or more sub-touch electrodes.

10. The display device of claim 7, further comprising one sub-touch line electrically connecting the two or more sub-touch electrodes to the first driver,
wherein, in the first unit driving area, the one sub-touch line is electrically commonly connected to the two or more sub-touch electrodes.

11. The display device of claim 6, wherein, at any point in time, among the two or more row lines, a first low-potential voltage is applied to one row line, and a second low-potential voltage higher than the first low-potential voltage is applied to the remaining row line(s).

12. The display device of claim 1, wherein the display area includes a plurality of touch pixel areas,
wherein each of the plurality of touch pixel areas includes a plurality of touch sub-pixel areas,
wherein one touch electrode, which is a unit touch sensor, is formed in each of the plurality of touch pixel areas,
wherein one driver and a plurality of sub-touch electrodes are disposed in each of the plurality of touch sub-pixel areas, and
wherein the sub-touch electrodes arranged in a first touch pixel area among the plurality of touch pixel areas form one touch electrode corresponding to the first touch pixel area.

13. The display device of claim 1, wherein the plurality of column lines are arranged below the plurality of light emitting devices, and
wherein the plurality of row lines are arranged on the plurality of light emitting devices.

14. The display device of claim 1, wherein each of the plurality of drivers includes:
a display driver configured to drive two or more light emitting devices among the plurality of light emitting devices; and
a touch driver configured to sense two or more sub-touch electrodes included in the touch sensor, and
wherein the touch driver includes:
a sensing unit electrically connected to the two or more sub-touch electrodes; and
an analog-to-digital converter configured to convert an output value of the sensing unit into a sensing value corresponding to a digital value and output the sensing value.

15. The display device of claim 1, wherein at least one of the plurality of drivers includes a signal amplification circuit configured to amply and output a received signal.

16. The display device of claim 1, further comprising a layer stack disposed between the substrate and the plurality of light emitting devices,
wherein the layer stack includes:
a side protection layer disposed on each side of the plurality of drivers;
an upper protection layer disposed on the plurality of drivers and the side protection layer;
an insulating layer disposed on the upper protection layer;
a bank disposed on the insulating layer; and
an optical layer adjacent to the plurality of light emitting devices, and
wherein the plurality of light emitting devices are disposed on the bank.

17. The display device of claim 16, wherein the side protection layer includes at least one organic layer.

18. The display device of claim 16, wherein the optical layer includes a first optical layer surrounding the plurality of light emitting devices and the bank, and a second optical layer disposed on a side of the first optical layer,
wherein the first optical layer includes light scattering particles, and
wherein the plurality of row lines are arranged on the first optical layer.

19. The display device of claim 16, wherein each of the plurality of column lines is arranged on the insulating layer, and extends along a side of the bank to an upper portion of the bank.

20. The display device of claim 16, further comprising:
a row connection electrode disposed on the insulating layer;
a black matrix disposed on the optical layer, and having a plurality of openings overlapping with the plurality of light emitting devices; and
a partition disposed between the touch sensor and the plurality of light emitting devices,
wherein the partition includes a same material as the black matrix.

21. The display device of claim 16, further comprising:
a line connection pattern electrically connecting each of the plurality of row lines to one of the plurality of drivers, or electrically connecting each of the plurality of column lines to one of the plurality of drivers;
a touch connection electrode disposed on the insulating layer, and electrically connected to a sub-touch electrode included in the touch sensor; and
a touch connection pattern electrically connecting one of the plurality of drivers to the touch connection electrode,
wherein the touch connection electrode includes a same material as the plurality of column lines.

22. The display device of claim 1, further comprising:
a mode control switch configured to control a connection between the first electrode of each of the plurality of light emitting devices and a column driver according to a mode control signal,
wherein the mode control switch is configured to turn on when the mode control signal is a first mode control signal,
wherein the mode control switch is configured to turn off when the mode control signal is a second mode control signal different from the first mode control signal,
wherein a signal having a constant voltage level is applied to the touch sensor when the mode control switch is in a turned-on state, and
wherein a signal having a variable voltage level is applied to the touch sensor when the mode control switch is in a turned-off state.

23. A display device comprising:
a plurality of unit driving areas included in a display area;
a plurality of light emitting devices disposed in each of the plurality of unit driving areas;
a plurality of column lines arranged in each of the plurality of unit driving areas and electrically connected to a first electrode of each of the plurality of light emitting devices;
a plurality of row lines arranged in each of the plurality of unit driving areas and electrically connected to a second electrode of each of the plurality of light emitting devices; and
a touch sensor including a same metal as the plurality of row lines.

24. The display device of claim 23, further comprising:
a planarization layer disposed on the plurality of row lines and the touch sensor, and including a transparent insulating material.

25. The display device of claim 23, further comprising:
a driver disposed in each of the plurality of unit driving areas, and configured to drive the plurality of light emitting devices and drive and sense the touch sensor.
